(19) United States
(12) Patent Application Publication
(10) Pub. No.: US 2019/0196073 A1
(43) Pub. Date: Jun. 27, 2019

(54) COMPOSITION, FILM, NEAR INFRARED CUT FILTER, PATTERN FORMING METHOD, LAMINATE, SOLID IMAGE PICKUP ELEMENT, IMAGE DISPLAY DEVICE, CAMERA MODULE, AND INFRARED SENSOR

(71) Applicant: FUJIFILM Corporation, Tokyo (JP)

(72) Inventors: Suguru SAMEJIMA, Haibara-gun (JP); Tokihiko MATSUMURA, Haibara-gun (JP); Keisuke ARIMURA, Haibara-gun (JP); Shunsuke KITAJIMA, Haibara-gun (JP)

(73) Assignee: FUJIFILM Corporation, Tokyo (JP)

(21) Appl. No.: 16/287,263

(22) Filed: Feb. 27, 2019

Related U.S. Application Data
(63) Continuation of application No. PCT/JP2017/029832, filed on Aug. 22, 2017.

(30) Foreign Application Priority Data
Aug. 29, 2016 (JP) 2016-166802
Oct. 13, 2016 (JP) 2016-201807
Jul. 6, 2017 (JP) 2017-132541

(51) Int. Cl. G02B 5/28; H01L 27/146; H01L 31/0216; G02B 1/04

(52) U.S. Cl. CPC G02B 5/282; G02B 5/285; G02B 1/04; H01L 31/02162; H01L 27/14625

(57) ABSTRACT

Provided are a composition with which a film having excellent heat resistance and light fastness can be provided, the film, a near infrared cut filter, a pattern forming method, a laminate, a solid image pickup element, an image display device, a camera module, and an infrared sensor. The composition includes: a near infrared absorbing compound having an absorption maximum in a wavelength range of 650 to 1000 nm; an organic solvent; and a resin, in which the near infrared absorbing compound is at least one selected from the group consisting of a pyrrolopyrrole compound, a rylene compound, an oxonol compound, a squarylium compound, a croconium compound, a zinc phthalocyanine compound, a cobalt phthalocyanine compound, a vanadium phthalocyanine compound, a copper phthalocyanine compound, a magnesium phthalocyanine compound, a naphthalocyanine compound, a pyrylium compound, an azulenium compound, an indigo compound, and a pyrromethene compound, and a solubility of the near infrared absorbing compound in propylene glycol methyl ether acetate at 25° C. is 0.01 to 30 mg/L.

### CROSS-REFERENCE TO RELATED APPLICATIONS

This application is a Continuation of PCT International Application No. PCT/JP2017/029832 filed on Aug. 22, 2017, which claims priority under 35 U.S.C § 119(a) to Japanese Patent Application No. 2016-166802 filed on Aug. 29, 2016, Japanese Patent Application No. 2016-201807 filed on Oct. 13, 2016 and Japanese Patent Application No. 2017-132541 filed on Jul. 6, 2017. Each of the above application(s) is hereby expressly incorporated by reference, in its entirety, into the present application.

### BACKGROUND OF THE INVENTION

### 1. Field of the Invention

The present invention relates to a composition, a film, a near infrared cut filter, a pattern forming method, a laminate, a solid image pickup element, an image display device, a camera module, and an infrared sensor.

### 2. Description of the Related Art

In a video camera, a digital still camera, a mobile phone with a camera function, or the like, a charge coupled device (CCD) or a complementary metal-oxide semiconductor (CMOS), which is a solid image pickup element for a color image, is used. In a light receiving section of this solid image pickup element, a silicon photodiode having sensitivity to infrared light is used. Therefore, visibility may be corrected using a near infrared cut filter.

JP2010-160380A describes that a near infrared cut filter is manufactured using a photosensitive resin composition for a near infrared absorber including: a colorant (A) that includes a phthalocyanine compound having an absorption maximum in a near infrared range; a binder resin (B); a photopolymerizable compound (C); a photopolymerization initiator (D); and a solvent (E).

### SUMMARY OF THE INVENTION

A near infrared cut filter is desired to have excellent visible transparency and infrared shielding properties. However, the near infrared cut filter may be discolored by heating or light irradiation, and visible transparency or infrared shielding properties may deteriorate. Therefore, recently, further improvement of heat resistance and light fastness has been required for the near infrared cut filter.

In addition, even in the near infrared cut filter described in JP2010-160380A, heat resistance or light fastness is not sufficient.

Accordingly, an object of the present invention is to provide a composition with which a film having excellent heat resistance and light fastness can be formed. In addition, another object of the present invention is to provide a film having excellent heat resistance and light fastness, a near infrared cut filter, a pattern forming method, a laminate, a solid image pickup element, an image display device, a camera module, and an infrared sensor.

As a near infrared absorbing compound that is an organic colorant, a material having high solubility in propylene glycol methyl ether acetate is used in the related art. As a result of thorough investigation, the present inventors found that a film having excellent heat resistance and light fastness can be manufactured by using a near infrared absorbing compound that is an organic colorant having low solubility in propylene glycol methyl ether acetate, thereby completing the present invention. The present invention provides the following.

<1> A composition comprising:

a near infrared absorbing compound having an absorption maximum in a wavelength range of 650 to 1000 nm;

an organic solvent; and

a resin,

in which the near infrared absorbing compound is at least one selected from the group consisting of a pyrrolopyrrole compound, a rylene compound, an oxonol compound, a squarylium compound, a croconium compound, a zinc phthalocyanine compound, a cobalt phthalocyanine compound, a vanadium phthalocyanine compound, a copper phthalocyanine compound, a magnesium phthalocyanine compound, a naphthalocyanine compound, a pyrylium compound, an azulenium compound, an indigo compound, and a pyrromethene compound, and a solubility of the near infrared absorbing compound in propylene glycol methyl ether acetate at 25° C. is 0.01 to 30 mg/L.

<2> The composition according to <1>, further comprising:

a pigment derivative.

<3> The composition according to <1> or <2>, further comprising:

a curable compound.

<4> The composition according to <3>,

in which the curable compound is a polymerizable compound, and

the composition further comprises a photopolymerization initiator.

<5> The composition according to <3>,

in which the curable compound is a compound having an epoxy group.

<6> The composition according to any one of <1> to <5>, further comprising:

an alkali-soluble resin.

<7> The composition according to any one of <1> to <6>, further comprising:

a silane coupling agent.

<8> The composition according to <3>,

in which the curable compound is a compound having an epoxy group, and

the composition further comprises a silane coupling agent.

<9> A film which is formed using the composition according to any one of <1> to <8>.

<10> A near infrared cut filter comprising:

a film that is formed using the composition according to any one of <1> to <8>.

<11> The near infrared cut filter according to <10>, further comprising:

a glass substrate.

<12> The near infrared cut filter according to <11>,

wherein the film is a film that is formed using the composition according to <7> or <8>.

<13> A pattern forming method comprising:

a step of forming a composition layer on a support using the composition according to any one of <1> to <8>; and

a step of forming a pattern on the composition layer using a photolithography method or a dry etching method.

<14> A laminate comprising:

the film according to <9>; and

a color filter that includes a chromatic colorant.

<15> A solid image pickup element comprising:

the film according to <9>.

<16> An image display device comprising:

the film according to <9>.

<17> A camera module comprising:

the film according to <9>.

<18> An infrared sensor comprising:

the film according to <9>.

According to the present invention, a composition with which a film having excellent heat resistance and light fastness can be formed can be provided. In addition, a film having excellent heat resistance and light fastness, a near infrared cut filter, a pattern forming method, a laminate, a solid image pickup element, an image display device, a camera module, and an infrared sensor can be provided.

### BRIEF DESCRIPTION OF THE DRAWING

FIG. 1 is a schematic diagram showing an embodiment of an infrared sensor.

### DESCRIPTION OF THE PREFERRED EMBODIMENTS

Hereinafter, the details of the present invention will be described.

In this specification, numerical ranges represented by “to” include numerical values before and after “to” as lower limit values and upper limit values.

In this specification, unless specified as a substituted group or as an unsubstituted group, a group (atomic group) denotes not only a group (atomic group) having no substituent but also a group (atomic group) having a substituent. For example, “alkyl group” denotes not only an alkyl group having no substituent (unsubstituted alkyl group) but also an alkyl group having a substituent (substituted alkyl group).

In this specification, unless specified otherwise, “exposure” denotes not only exposure using light but also drawing using a corpuscular beam such as an electron beam or an ion beam. Examples of the light used for exposure include an actinic ray or radiation, for example, a bright light spectrum of a mercury lamp, a far ultraviolet ray represented by excimer laser, an extreme ultraviolet ray (EUV ray), an X-ray, or an electron beam.

In this specification, “(meth)allyl” denotes either or both of allyl and methallyl, “(meth)acrylate” denotes either or both of acrylate or methacrylate, “(meth)acryl” denotes either or both of acryl and methacryl, and “(meth)acryloyl” denotes either or both of acryloyl and methacryloyl.

In this specification, a weight-average molecular weight and a number-average molecular weight are defined as values in terms of polystyrene obtained by gel permeation chromatography (GPC). In this specification, an weight-average molecular weight (Mw) and a number-average molecular weight (Mn) can be obtained by using HLC-8220 (manufactured by Tosoh Corporation), using TSKgel Super AWM-H (manufactured by Tosoh Corporation; 6.0 mm ID (inner diameter)×15.0 cm) as a column, and using a 10 mmol/L lithium bromide N-methylpyrrolidinone (NMP) solution as an eluent.

In this specification, “near infrared light” denotes light (electromagnetic wave) in a wavelength range of 700 to 2500 nm.

In this specification, a total solid content denotes the total mass of all the components of the composition excluding a solvent.

In this specification, the term “step” denotes not only an individual step but also a step which is not clearly distinguishable from another step as long as an effect expected from the step can be achieved.

<Composition>

A composition according to an embodiment of the present invention includes: a near infrared absorbing compound having an absorption maximum in a wavelength range of 650 to 1000 nm; an organic solvent; and a resin.

The near infrared absorbing compound is at least one selected from the group consisting of a pyrrolopyrrole compound, a rylene compound, an oxonol compound, a squarylium compound, a croconium compound, a zinc phthalocyanine compound, a cobalt phthalocyanine compound, a vanadium phthalocyanine compound, a copper phthalocyanine compound, a magnesium phthalocyanine compound, a naphthalocyanine compound, a pyrylium compound, an azulenium compound, an indigo compound, and a pyrromethene compound, and a solubility of the near infrared absorbing compound in propylene glycol methyl ether acetate at 25° C. is 0.01 to 30 mg/L.

According to the present invention, a film having excellent heat resistance and light fastness can be formed by using the composition. As a near infrared absorbing compound that is an organic colorant, a compound having high solubility in propylene glycol methyl ether acetate is used in the related art from the viewpoints that the synthesis of the colorant is relatively easy and the handleability is excellent. However, by using the near infrared absorbing compound in which the solubility in propylene glycol methyl ether acetate at 25° C. is 0.01 to 30 mg/L, there are effects in that discoloration caused by heating or light irradiation can be suppressed and a film having excellent heat resistance and light fastness can be formed.

In addition, in the near infrared absorbing compound, the solubility is 0.01 to 30 mg/L, and thus dispersibility in the composition is excellent. The dispersibility of the near infrared absorbing compound in the composition is excellent, and thus there is an effect in that visible transmittance is high. The reason why the dispersibility in the composition can be improved when the solubility of the near infrared absorbing compound is 0.01 to 30 mg/L is presumed to be that, since the near infrared absorbing compound in the composition has appropriate affinity to a resin or an organic solvent, aggregation or the like of particles of the near infrared absorbing compound can be suppressed. On the other hand, it is presumed that, in a case where the solubility is excessively low, the affinity to a resin or an organic solvent is low, particles of the near infrared absorbing compound are likely to aggregate due to an interaction or the like therebetween, and the dispersibility is poor. In addition, it is presumed that, in a case where the solubility is excessively high, a balance of the interaction between the near infrared absorbing compound, the resin, and the organic solvent is lost, and thus the dispersibility is poor.

In the present invention, the solubility of the near infrared absorbing compound is a value measured using the following method. Under the atmospheric pressure, about 100 mg (a precisely weighed value is represented by X mg) of the near infrared absorbing compound is added to 1 L of propylene glycol methyl ether acetate at 25° C., and the components are stirred for 30 minutes. Next, the solution is left to stand for 5 minutes and then is filtered, and the filtrate is dried under reduced pressure at 80° C. for 2 hours is precisely weighed (a precisely weighed value is represented by Y mg). The solubility of the near infrared absorbing compound dissolved in propylene glycol methyl ether acetate is calculated from the following expression.

Solubility (mg/L)=X−Y

In addition, in the present invention, a case where the near infrared absorbing compound “has an absorption maximum in a wavelength range of 650 to 1000 nm” represents the near infrared absorbing compound has a maximum absorbance in a wavelength range of 650 to 1000 nm in an absorption spectrum of the near infrared absorbing compound in a solution. A measurement solvent used for measuring an absorption spectrum of the near infrared absorbing compound in the solution is not particularly limited as long as the near infrared absorbing compound is soluble therein. From the viewpoint of solubility, for example, chloroform, dimethylformamide, tetrahydrofuran, or methylene chloride can be used. For example, in the case of a compound which is soluble in chloroform, chloroform is used as the measurement solvent. In the case of a compound which is not soluble in chloroform, methylene chloride is used. In addition, in the case of a compound which is not soluble in chloroform and methylene chloride, dimethylformamide is used. In addition, in the case of a compound which is not soluble in chloroform, methylene chloride, and dimethylformamide, tetrahydrofuran is used.

Hereinafter, each component of the composition according to the embodiment of the present invention will be described.

<<Near Infrared Absorbing Compound>>

The composition according to the embodiment of the present invention includes a near infrared absorbing compound (hereinafter, also referred to as “near infrared absorbing compound A”) having an absorption maximum in a wavelength range of 650 to 1000 nm, in which the near infrared absorbing compound is at least one selected from the group consisting of a pyrrolopyrrole compound, a rylene compound, an oxonol compound, a squarylium compound, a croconium compound, a zinc phthalocyanine compound, a cobalt phthalocyanine compound, a vanadium phthalocyanine compound, a copper phthalocyanine compound, a magnesium phthalocyanine compound, a naphthalocyanine compound, a pyrylium compound, an azulenium compound, an indigo compound, and a pyrromethene compound, and a solubility of the near infrared absorbing compound in propylene glycol methyl ether acetate at 25° C. is 0.01 to 30 mg/L. The lower limit of the absorption maximum in the near infrared absorbing compound A is preferably 670 nm or longer and more preferably 700 nm or longer. The upper limit of the absorption maximum in the near infrared absorbing compound is preferably 950 nm or shorter, more preferably 900 nm or shorter, still more preferably 850 nm or shorter, and even still more preferably 800 nm or shorter.

The solubility of the near infrared absorbing compound A in propylene glycol methyl ether acetate at 25° C. is 0.01 to 30 mg/L and preferably 0.05 to 20 mg/L. The lower limit of the solubility is more preferably 0.1 mg/L or higher. The upper limit of the solubility is more preferably 15 mg/L or lower and more preferably 10 mg/L or lower. In a case where the solubility of the near infrared absorbing compound A is 0.01 to 30 mg/L, a film having excellent heat resistance and light fastness can be formed. Further, the dispersibility of the near infrared absorbing compound A in the composition is also excellent.

Examples of a method of reducing the solubility of the near infrared absorbing compound A include the following:

(1) a method of improving the leveling of the near infrared absorbing compound;

(2) a method of introducing a urea structure, a triazine structure, or a structure having a hydrogen-bonding group such as a hydroxyl group into the near infrared absorbing compound;

(3) a method of introducing a hydrophilic group such as a sulfo group, an amido group, an amino group, or a carboxyl group into the near infrared absorbing compound; and

(4) a method of using a compound having an internal salt structure (betaine structure).

In the present invention, the near infrared absorbing compound A is at least one selected from the group consisting of a pyrrolopyrrole compound, a rylene compound, an oxonol compound, a squarylium compound, a croconium compound, a zinc phthalocyanine compound, a cobalt phthalocyanine compound, a vanadium phthalocyanine compound, a copper phthalocyanine compound, a magnesium phthalocyanine compound, a naphthalocyanine compound, a pyrylium compound, an azulenium compound, an indigo compound, and a pyrromethene compound, and is preferably a pyrrolopyrrole compound, a rylene compound, an oxonol compound, a squarylium compound, a zinc phthalocyanine compound, or a naphthalocyanine compound, more preferably a pyrrolopyrrole compound, a rylene compound, an oxonol compound, a squarylium compound, or a naphthalocyanine compound, and still more preferably a pyrrolopyrrole compound, a rylene compound, an oxonol compound, or a squarylium compound.

In may cases, the pyrrolopyrrole compounds has excellent heat resistance, light fastness, visible transparency, and infrared shielding properties. The pyrrolopyrrole compound in which the solubility is 0.01 to 30 mg/L has more excellent heat resistance and light fastness.

In many cases, the rylene compound, the oxonol compound, and the squarylium compound have excellent visible transparency and infrared shielding properties but have slightly low heat resistance or light fastness. The rylene compound, the oxonol compound, and the squarylium compound in which the solubility is 0.01 to 30 mg/L have excellent visible transparency and infrared shielding properties and also have excellent heat resistance and light fastness. Therefore, the effects of the present invention tend to be obtained.

In many cases, the croconium compound has slightly low heat resistance or light fastness. However, the croconium compound in which the solubility is 0.01 to 30 mg/L has excellent heat resistance and light fastness.

The zinc phthalocyanine compound, the cobalt phthalocyanine compound, the vanadium phthalocyanine compound, the copper phthalocyanine compound, and the magnesium phthalocyanine compound have excellent infrared shielding properties. These phthalocyanine compounds can improve aggregation to improve heat resistance or light fastness, but has low solubility such that visible transparency tends to deteriorate. In a case where the solubility is 0.01 to 30 mg/L, excellent visible transparency is obtained, and excellent heat resistance and light fastness are also obtained.

In many cases, the naphthalocyanine compound has slightly low heat resistance. However, the naphthalocyanine compound in which the solubility is 0.01 to 30 mg/L has excellent heat resistance and light fastness.

In many cases, the pyrylium compound, the azulenium compound, the indigo compound, and the pyrromethene compound have slightly low heat resistance or light fastness. However, the compounds in which the solubility is 0.01 to 30 mg/L have excellent heat resistance and light fastness.

Specific examples of the near infrared absorbing compound A include compounds having the following structures. In the following structural formulae, Me represents a methyl group, and Ph represents a phenyl group. Among the following compounds, (A-1) and (A-7) to (A-22) represent pyrrolopyrrole compounds, (A-2) represents a rylene compound, (A-3) represents a naphthalocyanine compound, (A-4) represents an oxonol compound, (A-5) and (A-23) to (A-42) represent squarylium compounds, (A-6) represents a zinc phthalocyanine compound, (A-43) and (A-44) represent a croconium compound, (A-45) to (A-47) represent pyrromethene compounds, (A-48) and (A-49) represent indigo compounds, (A-50) and (A-51) represent pyrylium compounds, and (A-52) represents an azulenium compound.

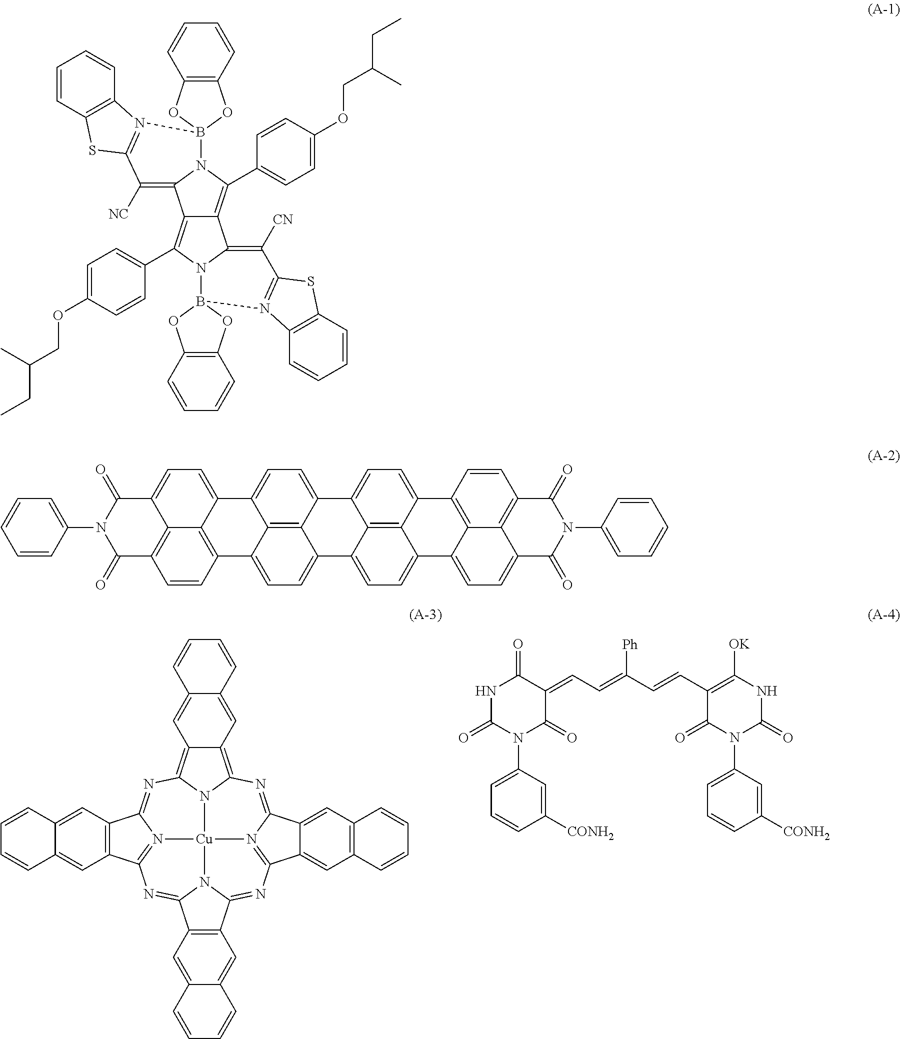

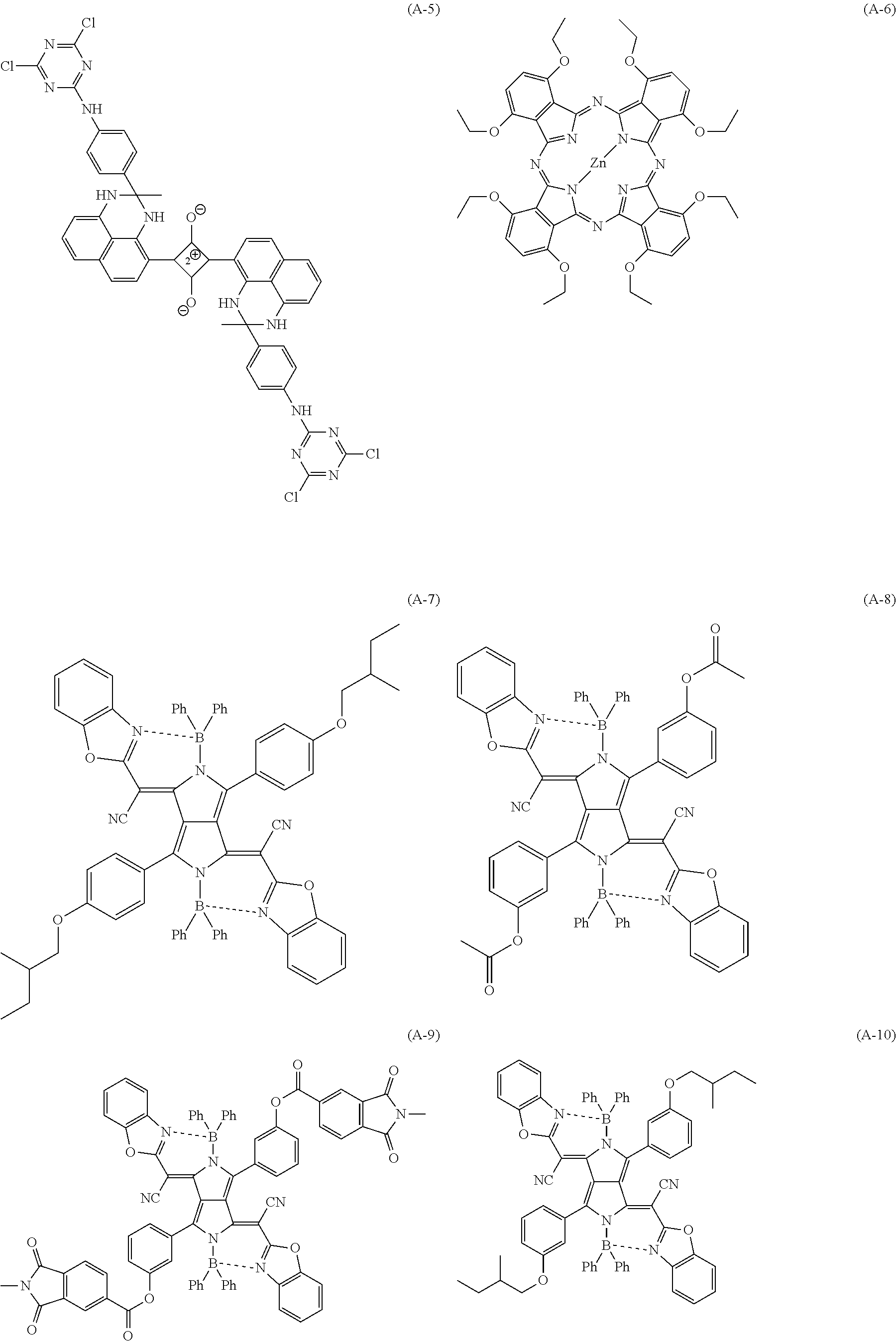

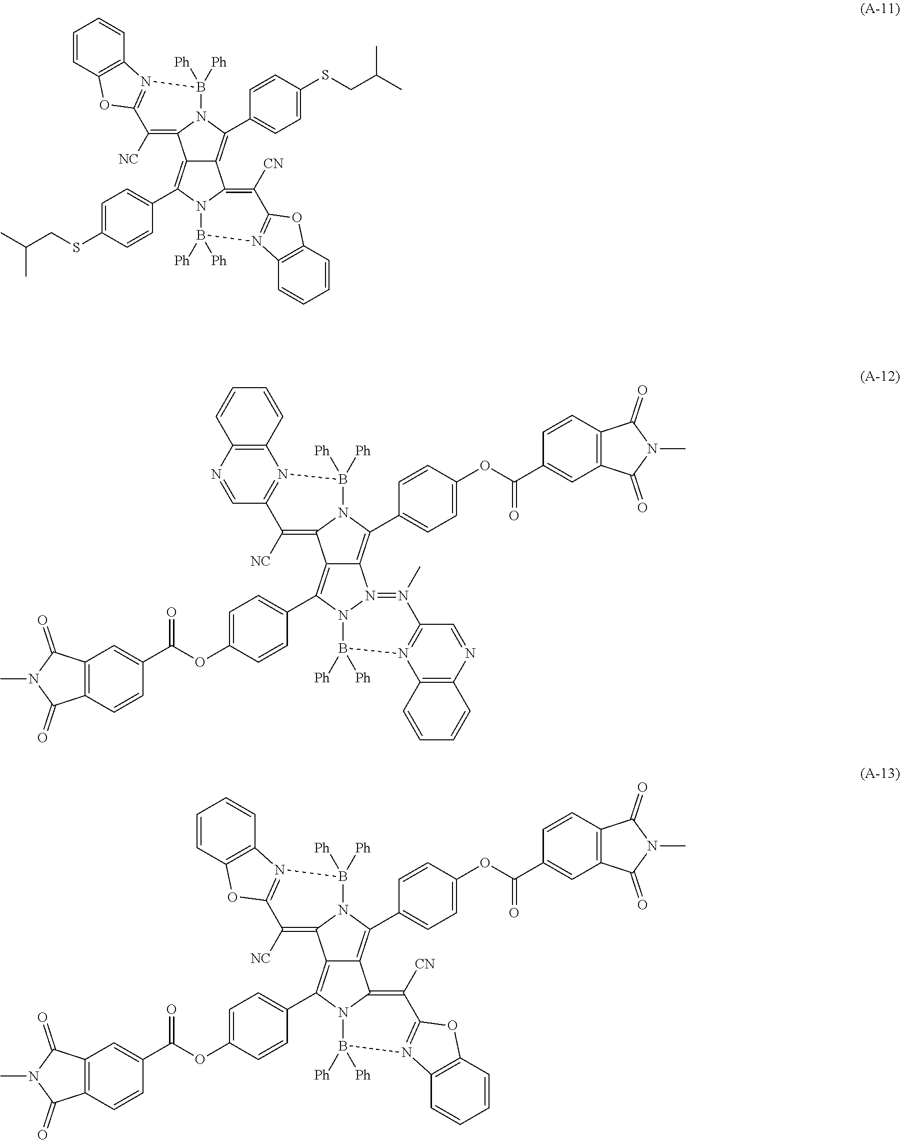

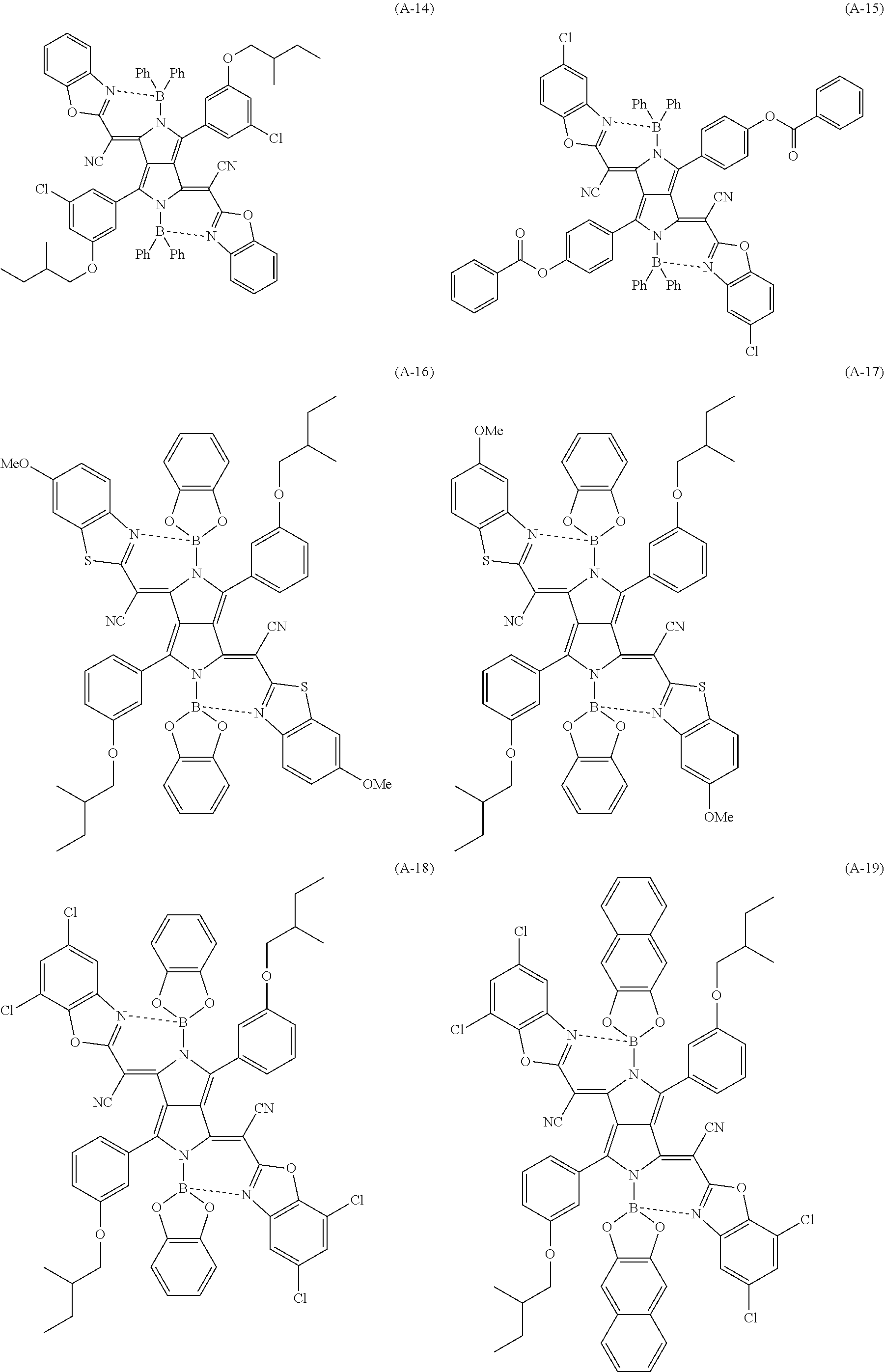

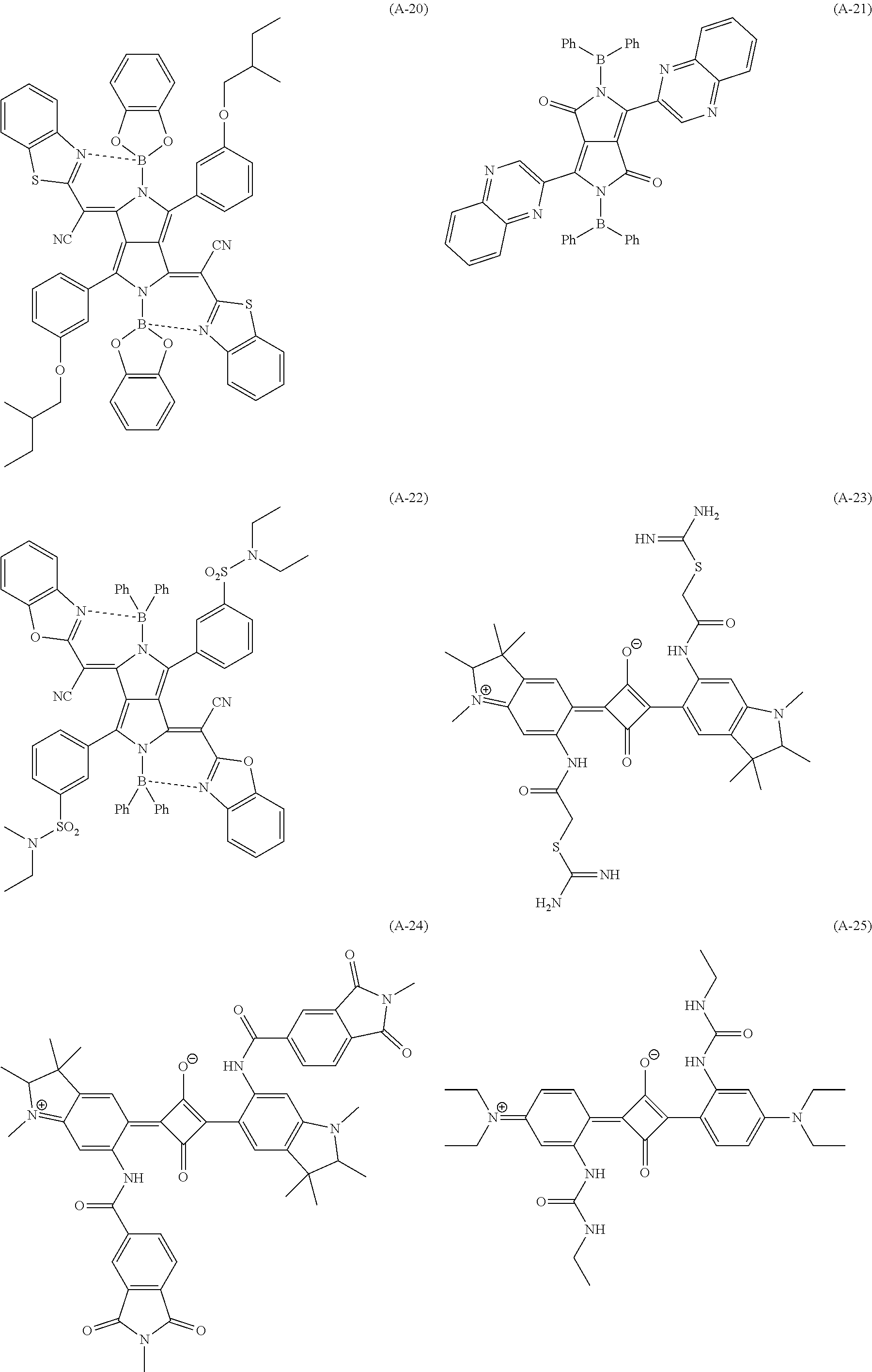

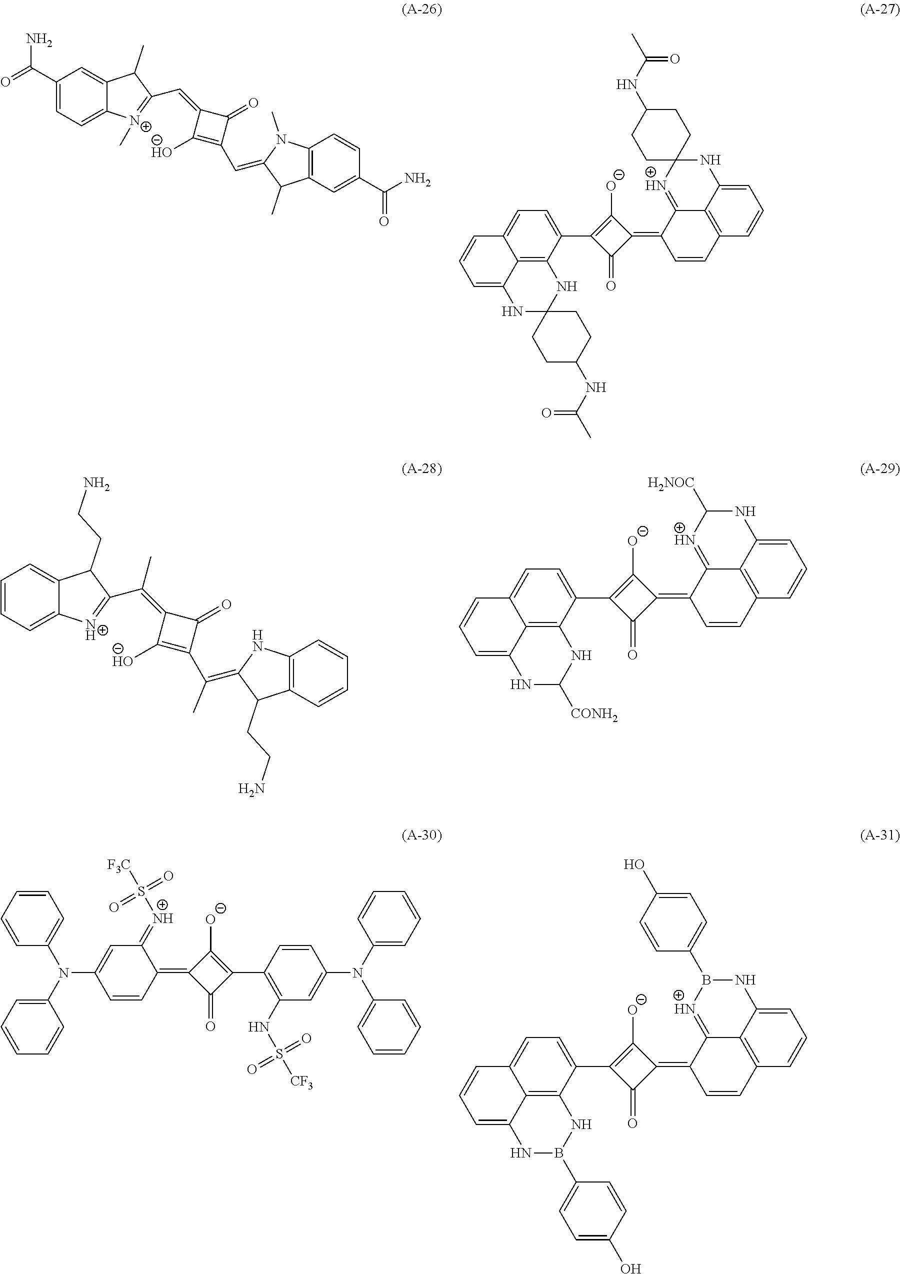

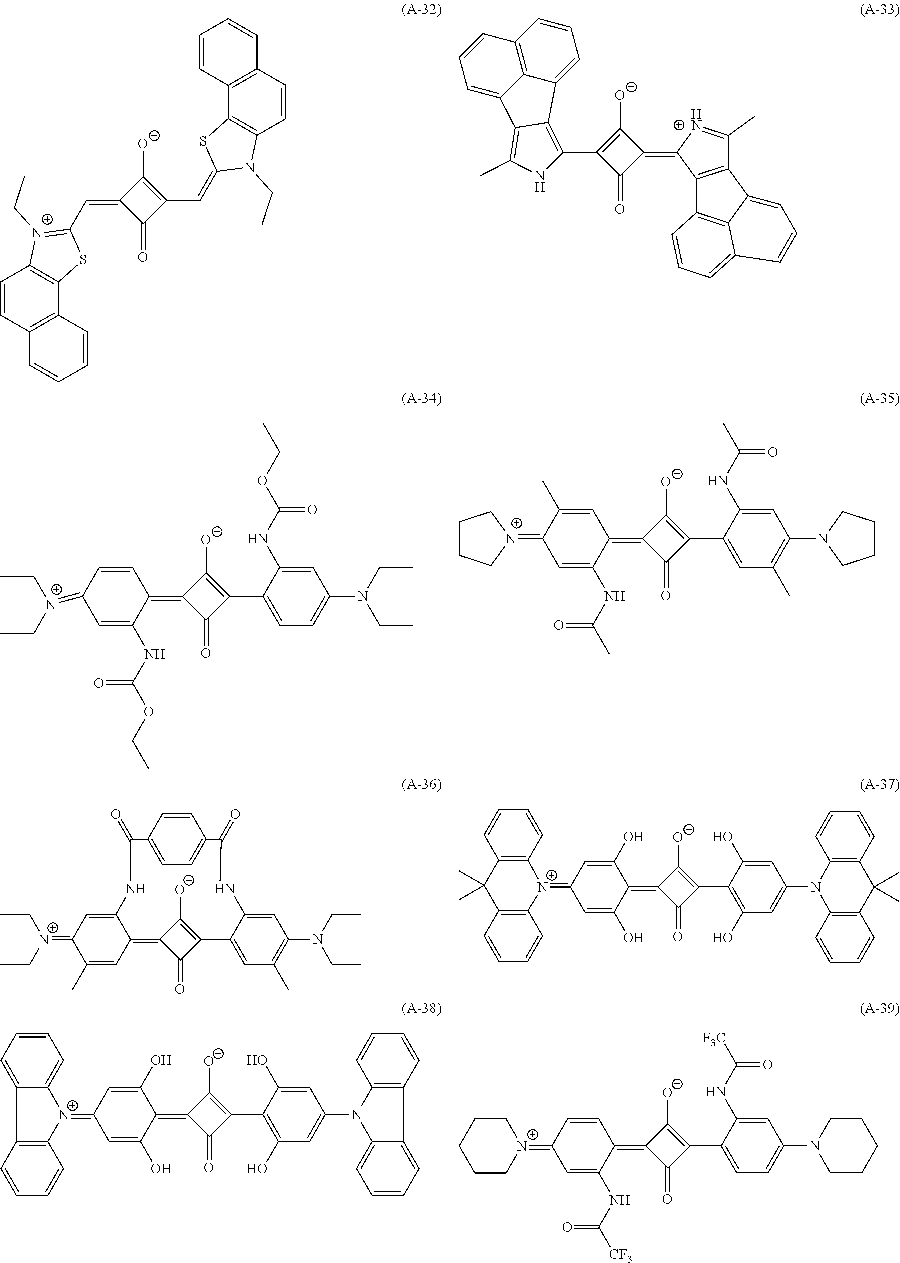

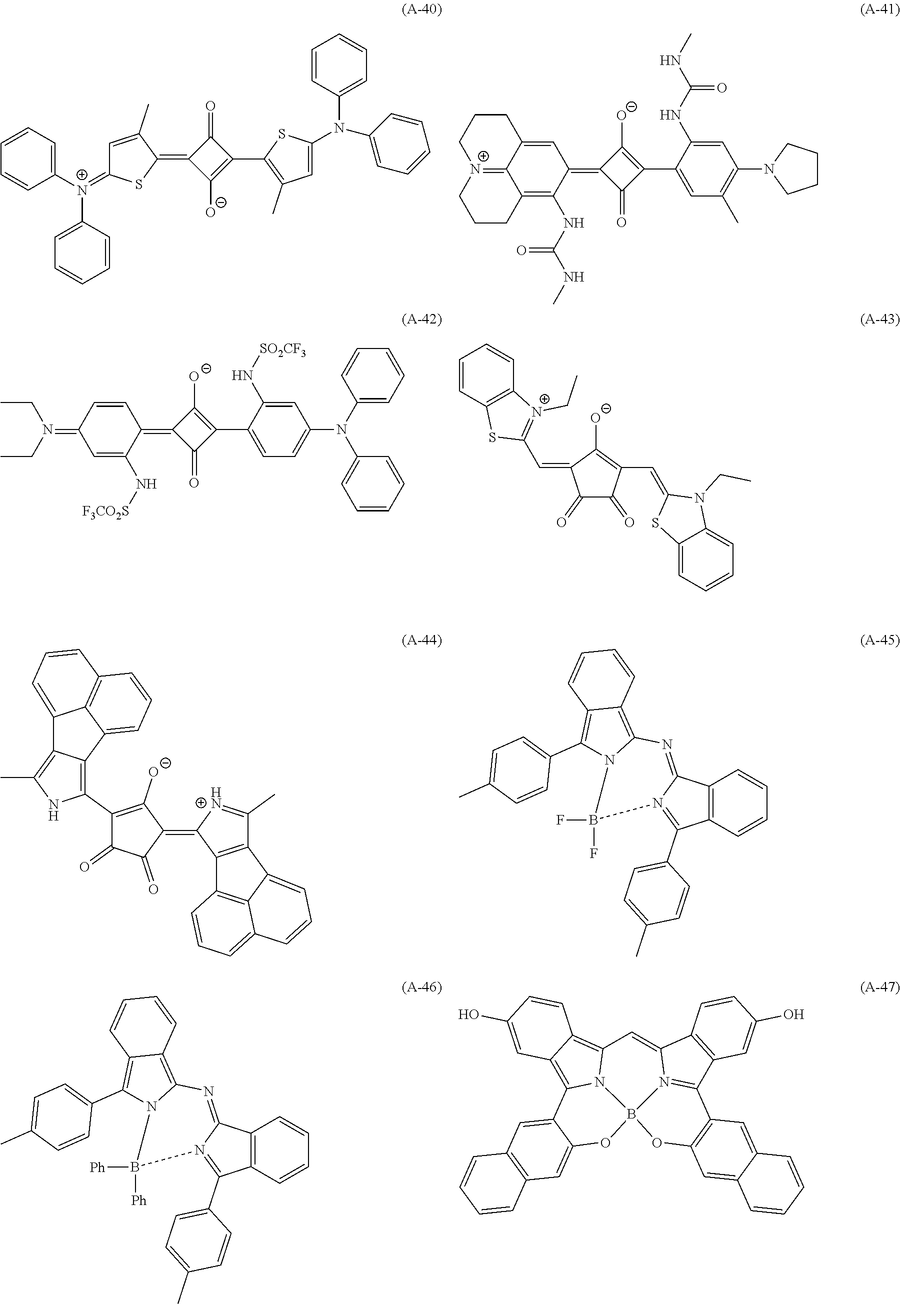

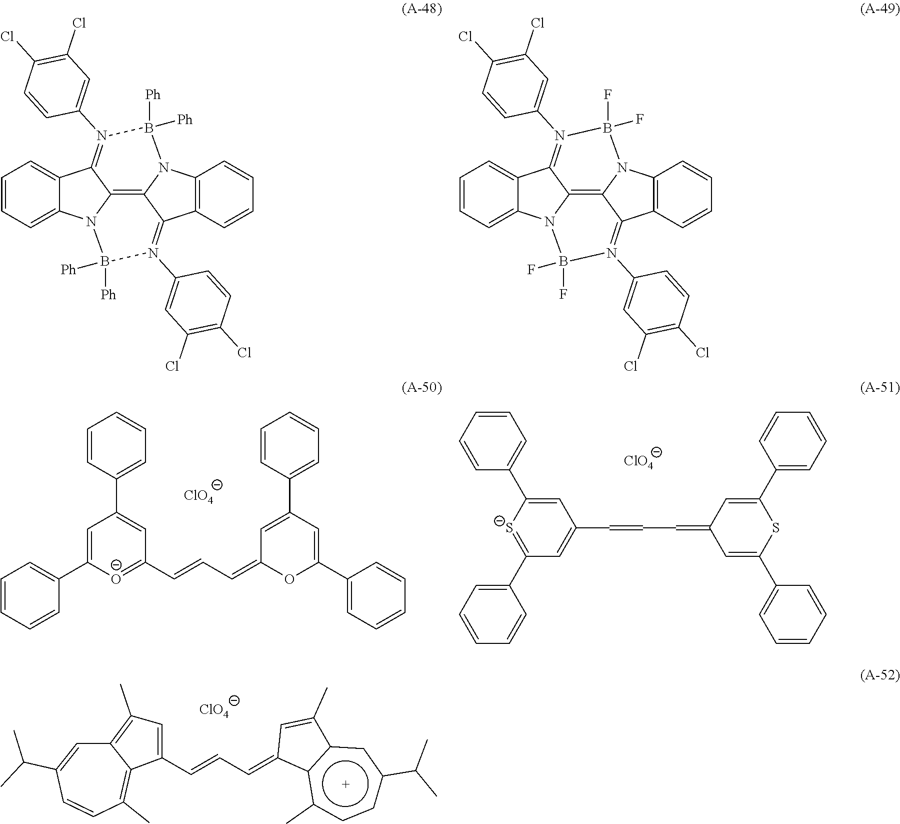

In the composition according to the embodiment of the present invention, the content of the near infrared absorbing compound A is preferably 0.01 to 50 mass % with respect to the total solid content of the composition according to the embodiment of the present invention. The lower limit is preferably 0.1 mass % or higher and more preferably 0.5 mass % or higher. The upper limit is preferably 30 mass % or lower, and more preferably 15 mass % or lower.

<<Other Near Infrared Absorbing Compounds>>

The composition according to the embodiment of the present invention may further include near infrared absorbing compounds (also referred to as “other near infrared absorbing compounds) other than the near infrared absorbing compound A. The other near infrared absorbing compounds may have different properties from the near infrared absorbing compound A regarding the solubility in propylene glycol methyl ether acetate at 25° C.

Examples of the other near infrared absorbing compounds include a pyrrolopyrrole compound, a cyanine compound, a squarylium compound, a phthalocyanine compound, a naphthalocyanine compound, a rylene compound, a merocyanine compound, a croconium compound, an oxonol compound, a diimmonium compound, a dithiol compound, a triarylmethane compound, a pyrromethene compound, an azomethine compound, an anthraquinone compound, a dibenzofuranone compound, and a copper compound. Examples of the pyrrolopyrrole compound include a compound described in paragraphs “0016” to “0058” of JP2009-263614A, a compound described in paragraphs “0037” to “0052” of JP2011-068731A, a compound described in paragraphs “0010” to “0033” of WO2015/166873A, the contents of which are incorporated herein by reference. Examples of the squarylium compound include a compound described in paragraphs “0044” to “0049” of JP2011-208101A, a compound described in JP2017-025311A, a compound described in WO2016/154782A, a compound described in JP6065169B, a compound described in JP5884953B, a compound described in JP6036689B, a compound described in JP5810604B, and a compound described in JP2017-068120A, the contents of which are incorporated herein by reference. Examples of the cyanine compound include a compound described in paragraphs “0044” and “0045” of JP2009-108267A, a compound described in paragraphs “0026” to “0030” of JP2002-194040A, and a compound described in JP2017-031394A, the contents of which are incorporated herein by reference. Examples of the diimmonium compound include a compound described in JP2008-528706A, the content of which is incorporated herein by reference. Examples of the phthalocyanine compound include a compound described in paragraph “0093” of JP2012-077153A, oxytitaniumphthalocyanine described in JP2006-343631A, a compound described in paragraphs “0013” to “0029” of JP2013-195480A, vanadium phthalocyanine described in JP6081771B, the contents of which are incorporated herein by reference. Examples of the naphthalocyanine compound include a compound described in paragraph “0093” of JP2012-077153A, the content of which is incorporated herein by reference. In addition, as the cyanine compound, the phthalocyanine compound, the naphthalocyanine compound, the diimmonium compound, or the squarylium compound, for example, one of the a compound described in paragraphs “0010” to “0081” of JP2010-111750A may be used, the content of which are incorporated in this specification. In addition, the details of the cyanine compound can be found in, for example, “Functional Colorants by Makoto Okawara, Masaru Matsuoka, Teijiro Kitao, and Tsuneoka Hirashima, published by Kodansha Scientific Ltd.”, the content of which is incorporated herein by reference. Examples of the copper compound include copper complexes described in paragraphs “0009” to “0049” of WO2016/068037A, copper phosphate complexes described in paragraphs “0022” to “0042” of JP2014-041318A, and copper sulfate complexes described in paragraphs “0021” to “0039” of JP2015-043063A, the contents of which are incorporated herein by reference.

In addition, as the other near infrared absorbing compound, inorganic particles can also be used. As the inorganic particles, metal oxide particles or metal particles are preferable from the viewpoint of further improving infrared shielding properties. Examples of the metal oxide particles include indium tin oxide (ITO) particles, antimony tin oxide (ATO) particles, zinc oxide (ZnO) particles, Al-doped zinc oxide (Al-doped ZnO) particles, fluorine-doped tin dioxide (F-doped SnO₂) particles, and niobium-doped titanium dioxide (Nb-doped TiO₂) particles. Examples of the metal particles include silver (Ag) particles, gold (Au) particles, copper (Cu) particles, and nickel (Ni) particles. In addition, as the inorganic particles, particles of a tungsten oxide compound can also be used. As the tungsten oxide compound, cesium tungsten oxide is preferable. The details of the tungsten oxide compound can be found in paragraph “0080” of JP2016-006476A, the content of which is incorporated herein by reference. The shape of the inorganic particles is not particularly limited and may have a sheet shape, a wire shape, or a tube shape irrespective of whether or not the shape is spherical or non-spherical.

The average particle size of the inorganic particles is preferably 800 nm or less, more preferably 400 nm or less, and still more preferably 200 nm or less. By adjusting the average particle size of the inorganic particles to be in the above-described range, visible transparency can be improved. From the viewpoint of avoiding light scattering, the less the average particle size, the better. However, due to the reason of handleability during manufacturing or the like, the average particle size of the inorganic particles is typically 1 nm or more.

In a case where the composition according to the embodiment of the present invention includes the other near infrared absorbing compounds, the content of the other near infrared absorbing compounds is preferably 0.01 to 50 mass % with respect to the total solid content of the composition according to the embodiment of the present invention. The lower limit is preferably 0.1 mass % or higher and more preferably 0.5 mass % or higher. The upper limit is preferably 30 mass % or lower, and more preferably 15 mass % or lower.

In addition, the total content of the near infrared absorbing compound A and the other near infrared absorbing compounds is preferably 0.01 to 50 mass % with respect to the total solid content of the composition according to the embodiment of the present invention. The lower limit is preferably 0.1 mass % or higher and more preferably 0.5 mass % or higher. The upper limit is preferably 30 mass % or lower, and more preferably 15 mass % or lower.

In addition, the content of the other near infrared absorbing compounds is preferably 1 to 99 mass % with respect to the total mass of the near infrared absorbing compound A and the other near infrared absorbing compounds. The upper limit is preferably 80 mass % or lower, more preferably 50 mass % or lower, and still more preferably 30 mass % or lower.

<<Chromatic Colorant>>

The composition according to the embodiment of the present invention may include a chromatic colorant. In the present invention, “chromatic colorant” denotes a colorant other than a white colorant and a black colorant. It is preferable that the chromatic colorant is a colorant having an absorption in a wavelength range of 400 nm or longer and shorter than 650 nm.

In the present invention, the chromatic colorant may be a pigment or a dye. As the pigment, an organic pigment is preferable. Examples of the organic pigment are as follows:

Color Index (C.I.) Pigment Yellow 1, 2, 3, 4, 5, 6, 10, 11, 12, 13, 14, 15, 16, 17, 18, 20, 24, 31, 32, 34, 35, 35:1, 36, 36:1, 37, 37:1, 40, 42, 43, 53, 55, 60, 61, 62, 63, 65, 73, 74, 77, 81, 83, 86, 93, 94, 95, 97, 98, 100, 101, 104, 106, 108, 109, 110, 113, 114, 115, 116, 117, 118, 119, 120, 123, 125, 126, 127, 128, 129, 137, 138, 139, 147, 148, 150, 151, 152, 153, 154, 155, 156, 161, 162, 164, 166, 167, 168, 169, 170, 171, 172, 173, 174, 175, 176, 177, 179, 180, 181, 182, 185, 187, 188, 193, 194, 199, 213, and 214 (all of which are yellow pigments);

C.I. Pigment Orange 2, 5, 13, 16, 17:1, 31, 34, 36, 38, 43, 46, 48, 49, 51, 52, 55, 59, 60, 61, 62, 64, 71, and 73 (all of which are orange pigments);

C.I. Pigment Red 1, 2, 3, 4, 5, 6, 7, 9, 10, 14, 17, 22, 23, 31, 38, 41, 48:1, 48:2, 48:3, 48:4, 49, 49:1, 49:2, 52:1, 52:2, 53:1, 57:1, 60:1, 63:1, 66, 67, 81:1, 81:2, 81:3, 83, 88, 90, 105, 112, 119, 122, 123, 144, 146, 149, 150, 155, 166, 168, 169, 170, 171, 172, 175, 176, 177, 178, 179, 184, 185, 187, 188, 190, 200, 202, 206, 207, 208, 209, 210, 216, 220, 224, 226, 242, 246, 254, 255, 264, 270, 272, and 279 (all of which are red pigments);

C.I. Pigment Green 7, 10, 36, 37, 58, and 59 (all of which are green pigments);

C.I. Pigment Violet 1, 19, 23, 27, 32, 37, and 42 (all of which are violet pigments); and

C.I. Pigment Blue 1, 2, 15, 15:1, 15:2, 15:3, 15:4, 15:6, 16, 22, 60, 64, 66, 79, and 80 (all of which are blue pigments).

Among these organic pigments, one kind may be used alone, or two or more kinds may be used in combination.

As the dye, well-known dyes can be used without any particular limitation. In terms of a chemical structure, a dye such as a pyrazole azo dye, an anilino azo dye, a triarylmethane dye, an anthraquinone dye, an anthrapyridone dye, a benzylidene dye, an oxonol dye, a pyrazolotriazole azo dye, a pyridone azo dye, a cyanine dye, a phenothiazine dye, a pyrrolopyrazole azomethine dye, a xanthene dye, a phthalocyanine dye, a benzopyran dye, an indigo dye, or a pyrromethene dye can be used. In addition, a polymer of the above-described dyes may be used. In addition, dyes described in JP2015-028144A and JP2015-034966A can also be used.

In a case where the composition according to the embodiment of the present invention includes a chromatic colorant, the content of the chromatic colorant is preferably 0.1 to 70 mass % with respect to the total solid content of the composition according to the embodiment of the present invention. The lower limit is preferably 0.5 mass % or higher and more preferably 1.0 mass % or higher. The upper limit is preferably 60 mass % or lower, and more preferably 50 mass % or lower.

The content of the chromatic colorant is preferably 10 to 1000 parts by mass and more preferably 50 to 800 parts by mass with respect to 100 parts by mass of the near infrared absorbing compound A (in a case where the composition further includes other near infrared absorbing compounds in addition to the near infrared absorbing compound A, with respect to the total mass of the near infrared absorbing compound A and the other near infrared absorbing compounds).

In addition, the total content of the total content of the chromatic colorant, the near infrared absorbing compound A, and the other near infrared absorbing compounds is preferably 1 to 80 mass % with respect to the total solid content of the composition according to the embodiment of the present invention. The lower limit is preferably 5 mass % or higher and more preferably 10 mass % or higher. The upper limit is preferably 70 mass % or lower, and more preferably 60 mass % or lower.

In a case where the composition according to the embodiment of the present invention includes two or more chromatic colorants, it is preferable that the total content of the two or more chromatic colorants is in the above-described range.

<<Coloring Material that Allows Transmission of Infrared Light and Shields Visible Light>>

The composition according to the embodiment of the present invention may also include the coloring material that allows transmission of infrared light and shields visible light (hereinafter, also referred to as “coloring material that shields visible light”).

In the present invention, it is preferable that the coloring material that shields visible light is a coloring material that absorbs light in a wavelength range of violet to red. In addition, in the present invention, it is preferable that the coloring material that shields visible light is a coloring material that shields light in a wavelength range of 450 to 650 nm. In addition, it is preferable that the coloring material that shields visible light is a coloring material that allows transmission of light in a wavelength range of 900 to 1300 nm.

In the present invention, it is preferable that the coloring material that shields visible light satisfies at least one of the following requirement (1) or (2).

(1): The coloring material that shields visible light includes two or more chromatic colorants, and a combination of the two or more chromatic colorants forms black

(2): The coloring material that shields visible light includes an organic black colorant

Examples of the organic black colorant include a bisbenzofuranone compound. The details of the bisbenzofuranone compound can be found in WO2014/208348A and JP2015-525260A, the contents of which are incorporated herein by reference.

In a case where the composition according to the embodiment of the present invention includes the coloring material that shields visible light, the content of the coloring material that shields visible light is preferably 30 mass % or lower, more preferably 20 mass % or lower, and still more preferably 15 mass % or lower with respect to the total solid content of the composition. The lower limit is, for example, 0.01 mass % or higher or 0.5 mass % or higher.

<<Pigment Derivative>>

The composition according to the embodiment of the present invention may further include a pigment derivative. Examples of the pigment derivative include a compound having a structure in which a portion of a pigment is substituted with an acidic group, a basic group, a group having a salt structure, or a phthalimidomethyl group. Among these, a pigment derivative represented by Formula (B1) is more preferable.

PL-(X)ₙ)ₘ (B1)

In Formula (B1), P represents a colorant structure, L represents a single bond or a linking group, X represents an acidic group, a basic group, a group having a salt structure, or a phthalimidomethyl group, m represents an integer of 1 or more, n represents an integer of 1 or more, in a case where m represents 2 or more, a plurality of L's and a plurality of X's may be different from each other, and in a case where n represents 2 or more, a plurality of X's may be different from each other.

In Formula (B1), P represents a colorant structure, preferably at least one selected from the group consisting of a pyrrolopyrrole colorant structure, a diketo pyrrolopyrrole colorant structure, a quinacridone colorant structure, an anthraquinone colorant structure, a dianthraquinone colorant structure, a benzoisoindole colorant structure, a thiazine indigo colorant structure, an azo colorant structure, a quinophthalone colorant structure, a phthalocyanine colorant structure, a naphthalocyanine colorant structure, a dioxazine colorant structure, a perylene colorant structure, a perinone colorant structure, a benzimidazolone colorant structure, a benzothiazole colorant structure, a benzimidazole colorant structure, and a benzoxazole colorant structure, and more preferably at least one selected from the group consisting of a pyrrolopyrrole colorant structure, a diketo pyrrolo pyrrolopyrrole colorant structure, a quinacridone colorant structure, and a benzimidazolone colorant structure.

In Formula (B1), L represents a single bond or a linking group. The linking group is preferably a group composed of 1 to 100 carbon atoms, 0 to 10 nitrogen atoms, 0 to 50 oxygen atoms, 1 to 200 hydrogen atoms, and 0 to 20 sulfur atoms, and may be unsubstituted or may further have a substituent.

In Formula (B1), X represents an acidic group, a basic group, a group having a salt structure, or a phthalimidomethyl group.

Specific examples of the pigment derivative include the following compounds. In addition, a pigment derivative described in JP529915B can also be used, the content of which is incorporated herein by reference.

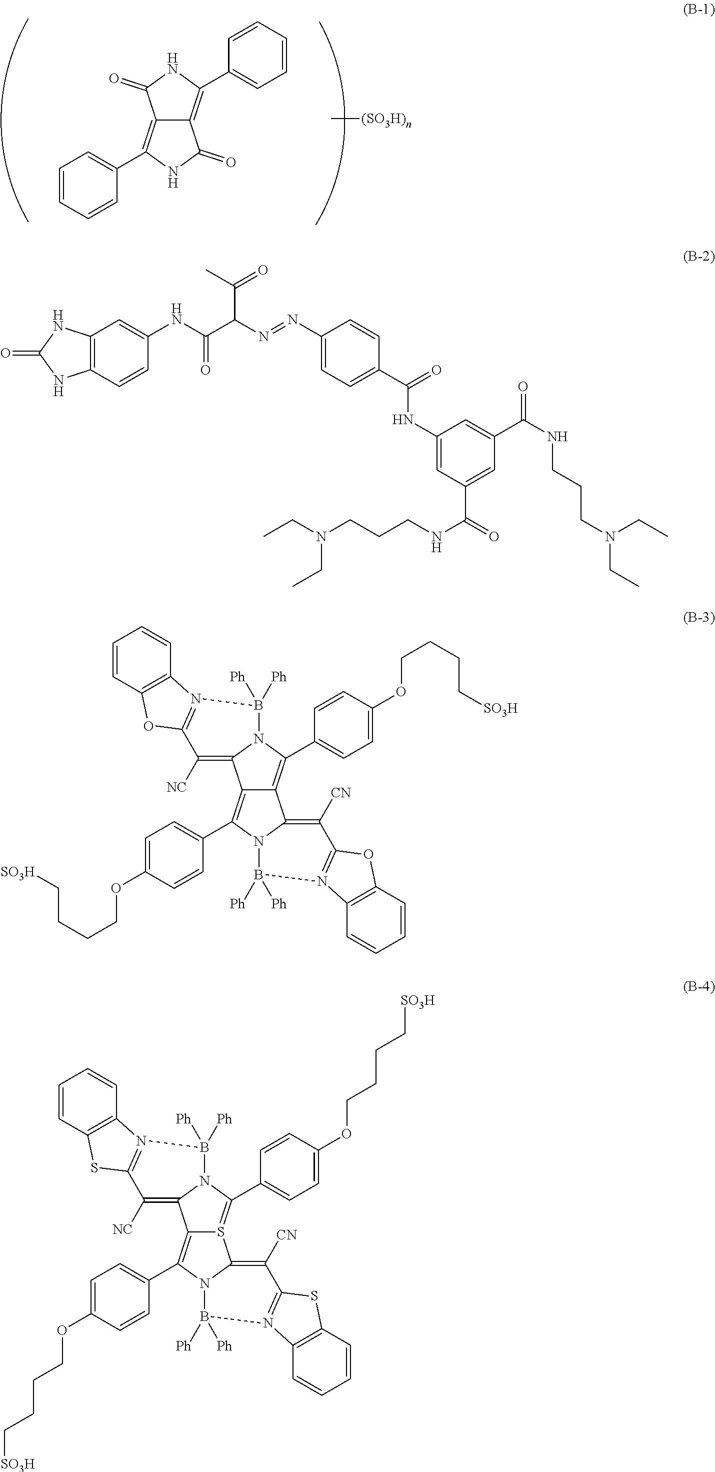

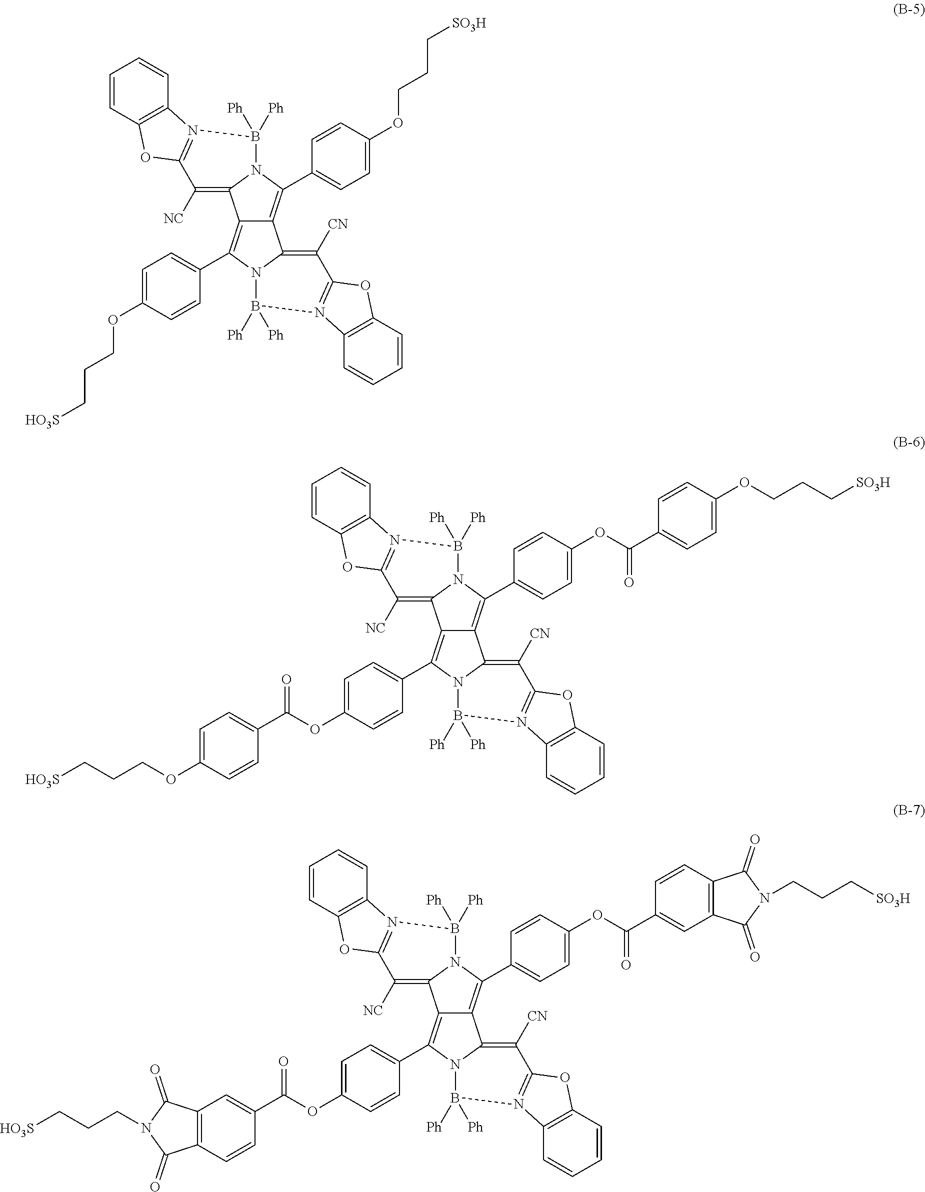

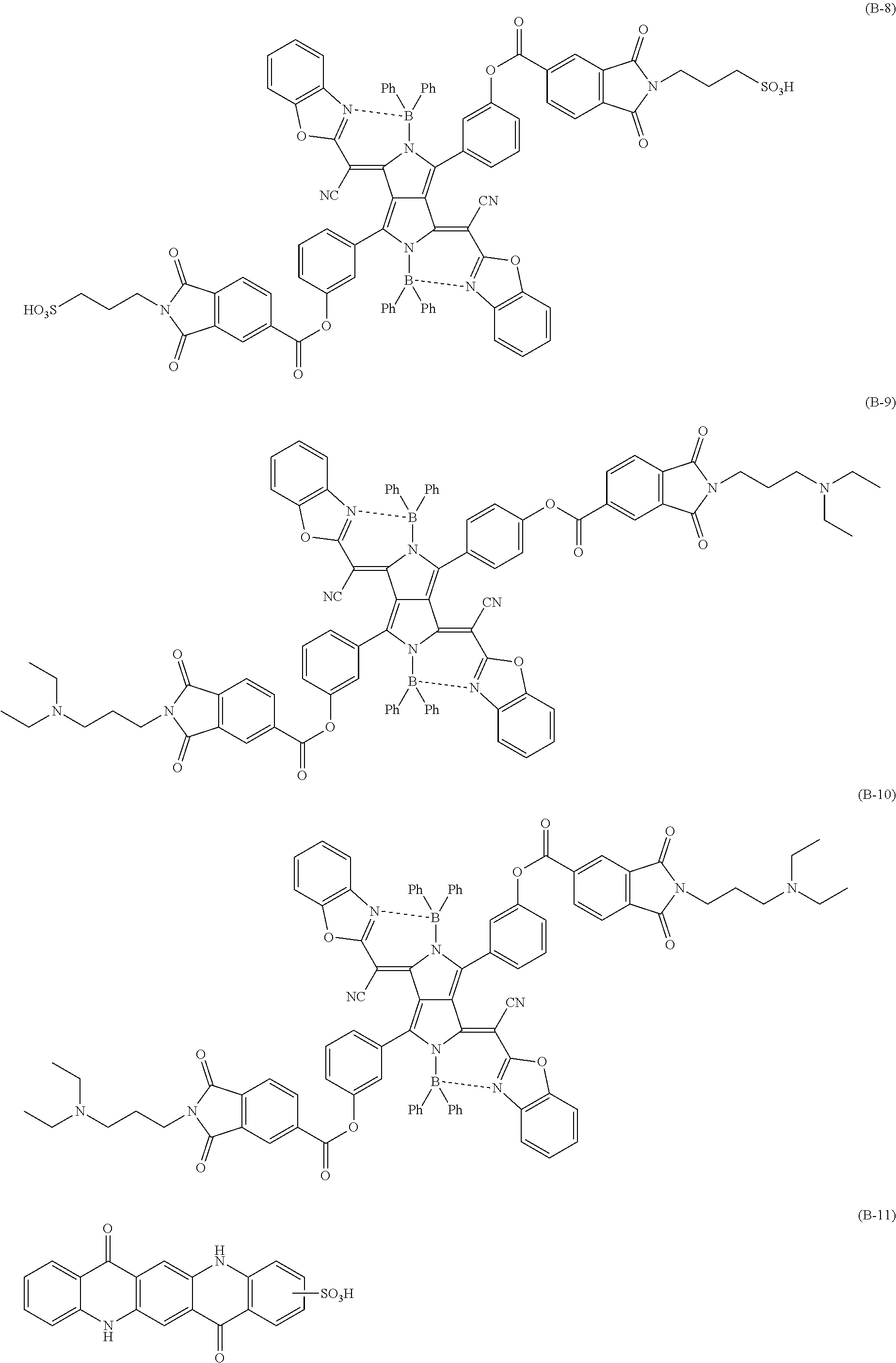

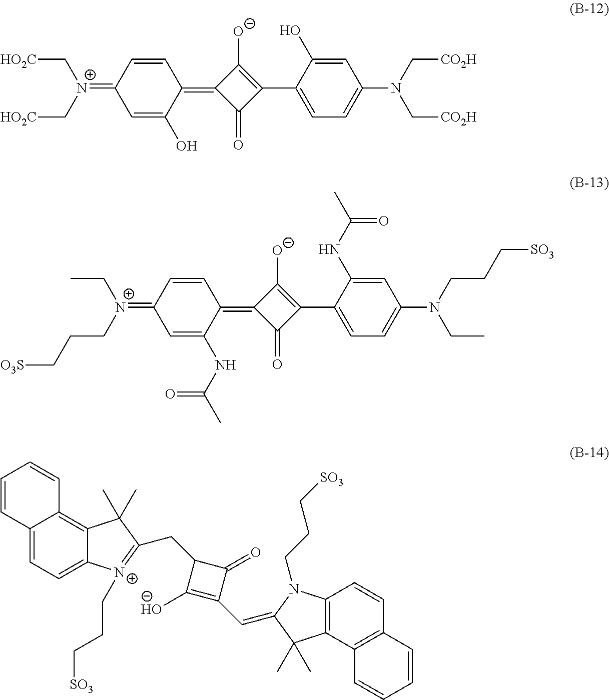

In a case where the composition according to the embodiment of the present invention includes the pigment derivative, the content of the pigment derivative is preferably 1 to 50 parts by mass with respect to 100 parts by mass of the near infrared absorbing compound A. The lower limit value is preferably 3 parts by mass or more and more preferably 5 parts by mass or more. The upper limit value is preferably 40 parts by mass or less and more preferably 30 parts by mass or less. In a case where the content of the pigment derivative is in the above-described range, the dispersibility of the near infrared absorbing compound A can be improved, and the aggregation of the near infrared absorbing compound A can be efficiently suppressed. As the pigment derivative, one kind or two or more kinds may be used. In a case where two or more pigment derivatives are used, it is preferable that the total content of the two or more pigment derivatives is in the above-described range.

<<Resin>>

In addition, the composition according to the embodiment of the present invention includes a resin. The resin is mixed, for example, in order to disperse the near infrared absorbing compound A, other pigments, and the like in the composition and to be used as a binder. The resin which is mainly used to disperse the near infrared absorbing compound A, other pigments, and the like will also be referred to as a dispersant. However, the above-described uses of the resin are merely exemplary, and the resin can be used for purposes other than the uses.

The weight-average molecular weight (Mw) of the resin is preferably 2000 to 2000000. The upper limit is preferably 1000000 or lower and more preferably 500000 or lower. The lower limit is preferably 3000 or higher and more preferably 5000 or higher.

Examples of the resin include a (meth)acrylic resin, an epoxy resin, an enethiol resin, a polycarbonate resin, a polyether resin, a polyarylate resin, a polysulfone resin, a polyethersulfone resin, a polyphenylene resin, a polyarylene ether phosphine oxide resin, a polyimide resin, a polyamide imide resin, a polyolefin resin, a cyclic olefin resin, a polyester resin, and a styrene resin. Among these resins, one kind may be used alone, or a mixture of two or more kinds may be used.

In the present invention, as the resin, resins described in JP2017-057265A, JP2017-032685A, JP2017-075248A, and JP2017-066240A can be used, the contents of which are incorporated herein by reference.

The resin used in the present invention may have an acid group. Examples of the acid group include a carboxyl group, a phosphate group, a sulfo group, and a phenolic hydroxyl group. Among these, a carboxyl group is preferable. Among these acid groups, one kind may be used alone, or two or more kinds may be used in combination. The resin having an acid group can also be used as an alkali-soluble resin.

As the resin having an acid group, a polymer having a carboxyl group at a side chain is preferable. Specific examples of the alkali-soluble resin include an alkali-soluble phenol resin such as a methacrylic acid copolymer, an acrylic acid copolymer, an itaconic acid copolymer, a crotonic acid copolymer, a maleic acid copolymer, a partially esterified maleic acid copolymer, or a novolac resin, an acidic cellulose derivative having a carboxyl group at a side chain thereof, and a resin obtained by adding an acid anhydride to a polymer having a hydroxyl group. In particular, a copolymer of (meth)acrylic acid and another monomer which is copolymerizable with the (meth)acrylic acid is preferable as the alkali-soluble resin. Examples of the monomer which is copolymerizable with the (meth)acrylic acid include an alkyl (meth)acrylate, an aryl (meth)acrylate, and a vinyl compound. Examples of the alkyl (meth)acrylate and the aryl (meth)acrylate include methyl (meth)acrylate, ethyl (meth)acrylate, propyl (meth)acrylate, butyl (meth)acrylate, isobutyl (meth)acrylate, pentyl (meth)acrylate, hexyl (meth)acrylate, octyl (meth)acrylate, phenyl (meth)acrylate, benzyl (meth)acrylate, tolyl (meth)acrylate, naphthyl (meth)acrylate, and cyclohexyl (meth)acrylate. Examples of the vinyl compound include styrene, α-methylstyrene, vinyl toluene, glycidyl methacrylate, acrylonitrile, vinyl acetate, N-vinylpyrrolidone, tetrahydrofurfuryl methacrylate, a polystyrene macromonomer, and a polymethyl methacrylate macromonomer. Examples of other monomers include a N-position-substituted maleimide monomer described in JP1998-300922A (H10-300922A) such as N-phenylmaleimide or N-cyclohexylmaleimide. Among these monomers which are copolymerizable with the (meth)acrylic acid, one kind may be used alone, or two or more kinds may be used in combination.

The resin having an acid group may further have a polymerizable group. Examples of the polymerizable group include a (meth)allyl group and a (meth)acryloyl group. Examples of a commercially available product of the resin include DIANAL NR series (manufactured by Mitsubishi Rayon Co., Ltd.), PHOTOMER 6173 (a COOH-containing polyurethane acrylic oligomer; manufactured by Diamond Shamrock Co., Ltd.), VISCOAT R-264 and KS Resist 106 (both of which are manufactured by Osaka Organic Chemical Industry Ltd.), CYCLOMER-P series (for example, ACA230AA) and PLAKCEL CF200 series (both of which manufactured by Daicel Corporation), EBECRYL 3800 (manufactured by Daicel-UCB Co., Ltd.), and ACRYCURE RD-F8 (manufactured by Nippon Shokubai Co., Ltd.).

As the resin having an acid group, a copolymer including benzyl (meth)acrylate and (meth)acrylic acid; a copolymer including benzyl (meth)acrylate, (meth)acrylic acid, and 2-hydroxyethyl (meth)acrylate; or a multi-component copolymer including benzyl (meth)acrylate, (meth)acrylic acid, and another monomer can be preferably used. In addition, copolymers described in JP1995-140654A (JP-H7-140654A) obtained by copolymerization of 2-hydroxyethyl (meth)acrylate can be preferably used, and examples thereof include: a copolymer including 2-hydroxypropyl (meth)acrylate, a polystyrene macromonomer, benzyl methacrylate, and methacrylic acid; a copolymer including 2-hydroxy-3-phenoxypropyl acrylate, a polymethyl methacrylate macromonomer, benzyl methacrylate, and methacrylic acid; a copolymer including 2-hydroxyethyl methacrylate, a polystyrene macromonomer, methyl methacrylate, and methacrylic acid; or a copolymer including 2-hydroxyethyl methacrylate, a polystyrene macromonomer, benzyl methacrylate, and methacrylic acid.

As the resin having an acid group, a polymer obtained by polymerization of monomer components including a compound represented by the following Formula (ED1) and/or a compound represented by the following Formula (ED2) (hereinafter, these compounds will also be referred to as “ether dimer”) is also preferable.

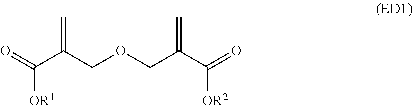

In Formula (ED1), R¹ and R² each independently represent a hydrogen atom or a hydrocarbon group having 1 to 25 carbon atoms which may have a substituent.

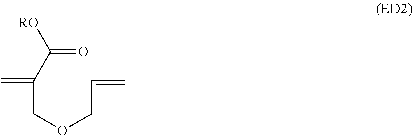

In Formula (ED2), R represents a hydrogen atom or an organic group having 1 to 30 carbon atoms. Specific examples of Formula (ED2) can be found in the description of JP2010-168539A.

Specific examples of the ether dimer can be found in paragraph “0317” of JP2013-029760A, the content of which is incorporated herein by reference. Among these ether dimers, one kind may be used alone, or two or more kinds may be used in combination.

The resin having an acid group may include a repeating unit which is derived from a compound represented by the following Formula (X).

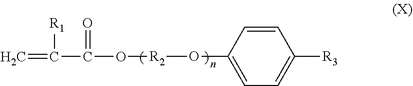

In Formula (X), R₁ represents a hydrogen atom or a methyl group, R₂ represents an alkylene group having 2 to 10 carbon atoms, and R₃ represents a hydrogen atom or an alkyl group having 1 to 20 carbon atoms which may have a benzene ring. n represents an integer of 1 to 15.

The details of the resin having an acid group can be found in paragraphs “0558” to “0571” of JP2012-208494A (corresponding to paragraphs “0685” to “0700” of US2012/0235099A) and paragraphs “0076” to “0099” of JP2012-198408A, the contents of which are incorporated herein by reference. In addition, as the resin having an acid group, a commercially available product may also be used. Examples of the commercially available product include ACRYBASE FF-426 (manufactured by Fujikura Kasei Co., Ltd.).

The acid value of the resin having an acid group is preferably 30 to 200 mgKOH/g. The lower limit is preferably 50 mgKOH/g or higher and more preferably 70 mgKOH/g or higher. The upper limit is preferably 150 mgKOH/g or lower and more preferably 120 mgKOH/g or lower.

In the composition according to the embodiment of the present invention, as the resin, a resin having a repeating unit represented by any one of Formulae (A3-1) to (A3-7) can also be used.

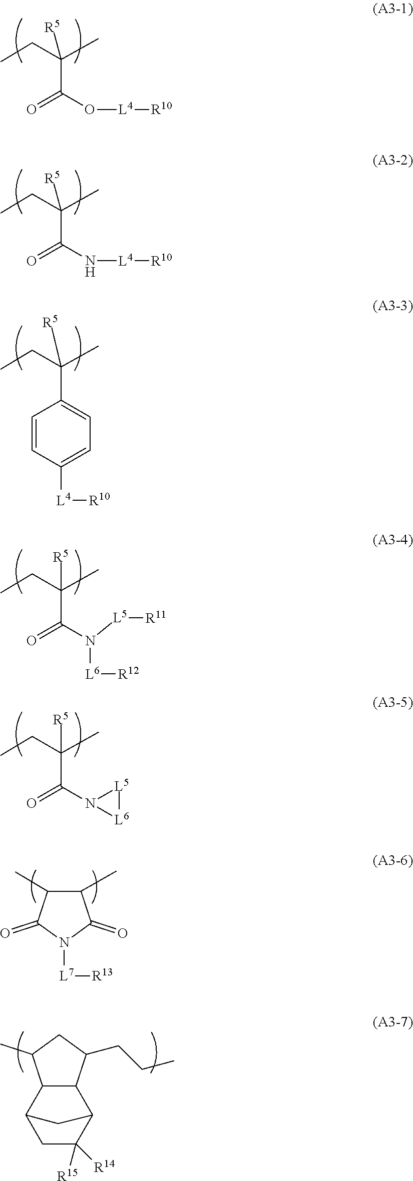

In the formulae, R⁵ represents a hydrogen atom or an alkyl group, L⁴ to L⁷ each independently represent a single bond or a divalent linking group, and R¹⁰ to R¹³ each independently represent an alkyl group or an aryl group. R¹⁴ and R¹⁵ each independently represent a hydrogen atom or a substituent.

R⁵ represents a hydrogen atom or an alkyl group. The number of carbon atoms in the alkyl group is preferably 1 to 5, more preferably 1 to 3, and still more preferably 1. It is preferable that R⁵ represents a hydrogen atom or a methyl group.

L⁴ to L⁷ each independently represent a single bond or a divalent linking group. Examples of the divalent linking group include an alkylene group, an arylene group, —O—, —S—, —CO—, —COO—, —OCO—, —SO₂—, —NR¹⁰-(R¹⁰ represents a hydrogen atom or an alkyl group and preferably a hydrogen atom), and a group including a combination thereof. Among these, a group including a combination —O— and at least one of an alkylene group, an arylene group, or an alkylene group is preferable. The number of carbon atoms in the alkylene group is preferably 1 to 30, more preferably 1 to 15, and still more preferably 1 to 10. The alkylene group may have a substituent but is preferably unsubstituted. The alkylene group may be linear, branched, or cyclic. In addition, the cyclic alkylene group may be monocyclic or polycyclic. The number of carbon atoms in the arylene group is preferably 6 to 18, more preferably 6 to 14, and still more preferably 6 to 10.

The alkyl group represented by R¹⁰ may be linear, branched, or cyclic and is preferably cyclic. The alkyl group may have a substituent or may be unsubstituted. The number of carbon atoms in the alkyl group is preferably 1 to 30, more preferably 1 to 20, and still more preferably 1 to 10. The number of carbon atoms in the aryl group represented by R¹⁰ is preferably 6 to 18, more preferably 6 to 12, and still more preferably 6. It is preferable that R¹⁰ represents a cyclic alkyl group or an aryl group.

The alkyl group represented by R¹¹ and R¹² may be linear, branched, or cyclic and is preferably linear or branched. The alkyl group may have a substituent or may be unsubstituted. The number of carbon atoms in the alkyl group is preferably 1 to 12, more preferably 1 to 6, and still more preferably 1 to 4. The number of carbon atoms in the aryl group represented by R¹¹ and R¹² is preferably 6 to 18, more preferably 6 to 12, and still more preferably 6. It is preferable that R¹¹ and R¹² represent a linear or branched alkyl group.

The alkyl group represented by R¹³ may be linear, branched, or cyclic and is preferably linear or branched. The alkyl group may have a substituent or may be unsubstituted. The number of carbon atoms in the alkyl group is preferably 1 to 12, more preferably 1 to 6, and still more preferably 1 to 4. The number of carbon atoms in the aryl group represented by R¹³ is preferably 6 to 18, more preferably 6 to 12, and still more preferably 6. It is preferable that R¹³ represents a linear or branched alkyl group or an aryl group.

Examples of the substituent represented by R¹⁴ and R¹⁵ include a halogen atom, a cyano group, a nitro group, an alkyl group, an alkenyl group, an alkynyl group, an aryl group, a heteroaryl group, an aralkyl group, an alkoxy group, an aryloxy group, a heteroaryloxy group, an alkylthio group, an arylthio group, a heteroarylthio group, —NR^{a1}R^{a2}, —COR^{a3}, —COOR^{a4}, —OCOR^{a5}, —NHCOR^{a6}, —CONR^{a7}R^{a8}, —NHCONR^{a9}R^{a10}, —NHCOOR^{a11}, —SO₂^{a12}, —SO₂OR^{a13}, —NHSO₂R^{a14}, and —SO₂NR^{a15}R^{a16}, R^{a1} to R^{a16} each independently represent a hydrogen atom, an alkyl group, an alkenyl group, an alkynyl group, an aryl group, or a heteroaryl group. In particular, it is preferable that at least one of R¹⁴ or R¹⁵ represents a cyano group or —COOR^{a4}. It is preferable that R^{a4} represents a hydrogen atom, an alkyl group, or an aryl group.

Examples of a commercially available product of the resin having a repeating unit represented by Formula (A3-7) include ARTON F4520 and D4540 (all of which are manufactured by JSR Corporation). In addition, the details of the resin having a repeating unit represented by Formula (A3-7) can be found in paragraphs “0053” to “0075” and “0127” to “0130” of JP2011-100084A, the content of which is incorporated herein by reference.

(Dispersant)

It is preferable that the composition according to the embodiment of the present invention includes a resin as a dispersant. The resin which functions as a dispersant is preferably an acidic resin and/or a basic resin.

Here, the acidic resin refers to a resin in which the amount of an acid group is more than the amount of a basic group. In a case where the sum of the amount of an acid group and the amount of a basic group in the acidic resin is represented by 100 mol %, the amount of the acid group in the acidic resin is preferably 70 mol % or higher and more preferably substantially 100 mol %. The acid group in the acidic resin is preferably a carboxyl group. An acid value of the acidic resin is preferably 40 to 105 mgKOH/g, more preferably 50 to 105 mgKOH/g, and still more preferably 60 to 105 mgKOH/g.

Here, the basic resin refers to a resin in which the amount of a basic group is more than the amount of an acid group. In a case where the sum of the amount of an acid group and the amount of a basic group in the basic resin is represented by 100 mol %, the amount of the basic group in the resin is preferably higher than 50 mol %. The basic group in the basic resin is preferably amine.

Examples of the dispersant include: a polymer dispersant such as a resin having an amine group (polyamideamine or a salt thereof), an oligo imine resin, a polycarboxylic acid or a salt thereof, a high-molecular-weight unsaturated acid ester, a modified polyurethane, a modified polyester, a modified poly(meth)acrylate, a (meth)acrylic copolymer, or a naphthalene sulfonic acid formalin condensate; In terms of a structure, the polymer dispersant can be further classified into a linear polymer, a terminal-modified polymer, a graft polymer, and a block polymer.

Examples of the terminal-modified polymer include a polymer having a phosphate group at a terminal thereof described in JP1991-112992A (JP-H3-112992A) or JP2003-533455A, a polymer having a sulfo group at a terminal thereof described in JP2002-273191A, and a polymer having a partial skeleton or a heterocycle of an organic colorant described in JP1997-077994A (JP-H9-077994A). In addition, polymers described in JP2007-277514A in which two or more anchor sites (for example, an acid group, a basic group, a partial skeleton or a heterocycle of an organic colorant) to a pigment surface are introduced into a terminal thereof are also preferable due to its dispersion stability.

Examples of the block polymer include a block polymer described in JP2003-049110A or JP2009-052010A.

Examples of the graft polymer include a reaction product of poly(low-alkylene imine) and polyester described in JP1979-037082A (JP-S54-037082A), JP1996-507960A (JP-H8-507960A), or JP2009-258668A, a reaction product of polyallylamine and polyester described in JP1997-169821A (JP-119-169821A), a copolymer of a macromonomer and a monomer having a nitrogen-containing group described in JP1998-339949A (JP-H10-339949A) or JP2004-037986A, a graft polymer having a partial skeleton or a heterocycle of an organic colorant described in JP2003-238837A, JP2008-009426A, or JP2008-081732A, and a copolymer of a macromonomer and an acid group-containing monomer described in JP2010-106268A.

In the present invention, as the resin (dispersant), a graft copolymer including a repeating unit represented by any one of the following Formulae (111) to (114) is preferably used.

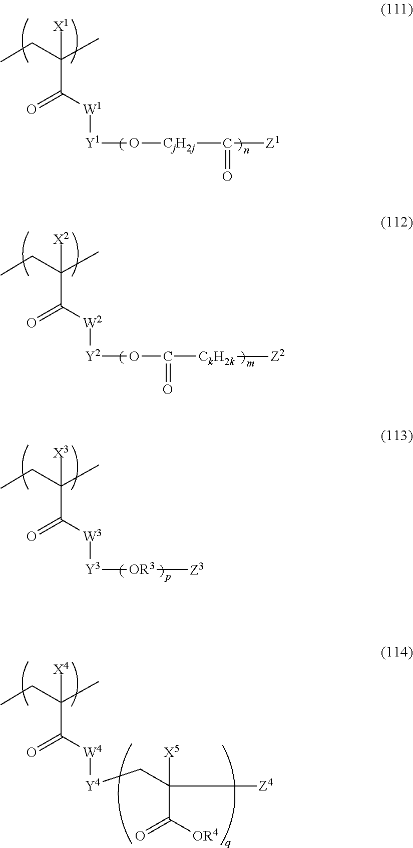

In Formulae (111) to (114), W¹, W², W³, and W⁴ each independently represent an oxygen atom or NH, X¹, X², X³, X⁴, and X⁵ each independently represent a hydrogen atom or a monovalent group, Y¹, Y², Y³, and Y⁴ each independently represent a divalent linking group, Z′, Z², Z³, and Z⁴ each independently represent a monovalent group, R³ represents an alkylene group, R⁴ represents a hydrogen atom or a monovalent group, n, m, p, and q each independently represent an integer of 1 to 500, and j and k each independently represent an integer of 2 to 8. In Formula (113), in a case where p represents 2 to 500, a plurality of R³'s may be the same as or different from each other. In Formula (114), in a case where q represents 2 to 500, a plurality of X⁵'s and a plurality of R⁴'s may be the same as or different from each other.

The details of the graft copolymer can be found in the description of paragraphs “0025” to “0094” of JP2012-255128A, the content of which is incorporated herein by reference. In addition, specific examples of the graft copolymer include the following resins. Other examples of the graft copolymer include resins described in paragraphs “0072” to “0094” of JP2012-255128A, the content of which is incorporated herein by reference.

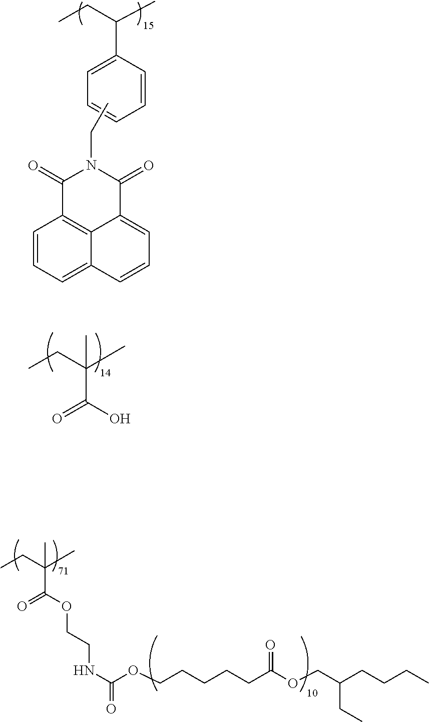

In addition, in the present invention, as the resin (dispersant), an oligoimine dispersant having a nitrogen atom at at least either a main chain or a side chain is also preferably used. As the oligoimine dispersant, a resin, which includes a structural unit having a partial structure X with a functional group (pKa: 14 or lower) and a side chain Y having 40 to 10000 atoms and has a basic nitrogen atom at at least either a main chain or a side chain, is preferable. The basic nitrogen atom is not particularly limited as long as it is a nitrogen atom exhibiting basicity. Examples of the oligoimine dispersant include a dispersant including a structural unit represented by the following Formula (I-1), a structural unit represented by the following Formula (I-2), and/or a structural unit represented by the following Formula (I-2a).

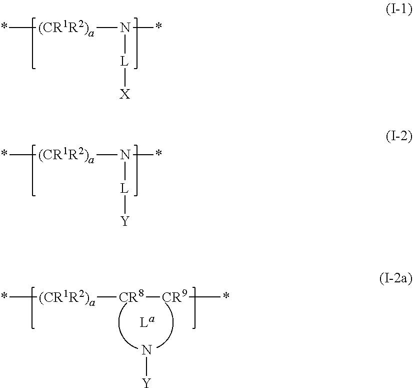

R¹ and R² each independently represent a hydrogen atom, a halogen atom, or an alkyl group (having preferably 1 to 6 carbon atoms). a's each independently represent an integer of 1 to 5. * represents a linking portion between structural units.

R⁸ and R⁹ represent the same group as that of R¹.

L represents a single bond, an alkylene group (having preferably 1 to 6 carbon atoms), an alkenylene group (having preferably 2 to 6 carbon atoms), an arylene group (having preferably 6 to 24 carbon atoms), an heteroarylene group (having preferably 1 to 6 carbon atoms), an imino group (having preferably 0 to 6 carbon atoms), an ether group, a thioether group, a carbonyl group, or a linking group of a combination of the above-described groups. Among these, a single bond or —CR⁵R⁶—NR⁷— (an imino group is present at the X or Y site) is preferable. Here, R⁵ and R⁶ each independently represent a hydrogen atom, a halogen atom, or an alkyl group (having preferably 1 to 6 carbon atoms). R⁷ represents a hydrogen atom or an alkyl group having 1 to 6 carbon atoms.

L^{a} is a structural unit which forms a ring structure with a carbon atom of CR⁸CR⁹ and N, preferably a structural unit which forms a nonaromatic heterocycle having 3 to 7 carbon atoms with a carbon atom of CR⁸CR⁹, more preferably a structural unit which forms a nonaromatic 5- to 7-membered heterocycle with a carbon atom of CR⁸CR⁹ and N (nitrogen atom), still more preferably a structural unit which forms a nonaromatic 5-membered heterocycle with a carbon atom of CR⁸CR⁹ and N, and even still more preferably a structural unit which forms pyrrolidine with a carbon atom of CR⁸CR⁹ and N. This structural unit may have a substituent such as an alkyl group.

X represents a group having a functional group (pKa: 14 or lower).

Y represents a side chain having 40 to 10000 atoms.

The oligoimine dispersant may further include one or more copolymerization components selected from the group consisting of the structural units represented by Formulae (I-3), (I-4), and (I-5). By the oligoimine dispersant including the above-described structural units, the dispersibility of the near infrared absorbing compound or the like can be further improved.

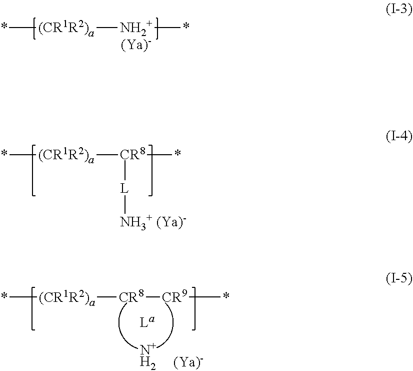

R¹, R², R⁸, R⁹, L, La, a, and * have the same definitions as R¹, R², R⁸, R⁹, L, La, a, and * in Formulae (I-1), (I-2), and (I-2a).

Ya represents a side chain having 40 to 10000 atoms which has an anionic group. The structural unit represented by Formula (I-3) can be formed by adding an oligomer or a polymer having a group, which reacts with amine to form a salt, to a resin having a primary or secondary amino group at a main chain such that they react with each other.

The oligoimine dispersant can be found in the description of paragraphs “0102” to “0166” of JP2012-255128A, the content of which is incorporated herein by reference. Specific examples of the oligoimine dispersant are as follows. In addition, a resin described in paragraphs “0168” to “0174” of JP2012-255128A can be used.

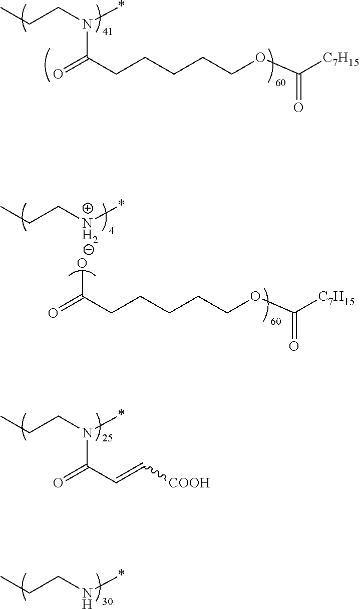

The dispersant is available as a commercially available product, and specific example thereof include Disperbyk-111 (manufactured by BYK Chemie). In addition, a pigment derivative described in paragraphs “0041” to “0130” of JP2014-130338A can also be used, the content of which is incorporated herein by reference. In addition, the resin having an acid group or the like can also be used as a dispersant.

In the composition according to the embodiment of the present invention, the content of the resin is preferably 1 to 80 mass % with respect to the total solid content of the composition according to the embodiment of the present invention. The lower limit is preferably 5 mass % or higher and more preferably 7 mass % or higher. The upper limit is preferably 50 mass % or lower and more preferably 30 mass % or lower.

In addition, in a case where the composition includes a resin having an acid group as the resin, the content of the resin having an acid group is preferably 0.1 to 40 mass % with respect to the total solid content of the composition. The upper limit is preferably 20 mass % or lower, and more preferably 10 mass % or lower. The lower limit is preferably 0.5 mass % or higher and more preferably 1 mass % or higher.

In addition, in a case where the composition includes a dispersant as the resin, the content of the dispersant is preferably 0.1 to 40 mass % with respect to the total solid content of the composition. The upper limit is preferably 20 mass % or lower, and more preferably 10 mass % or lower. The lower limit is preferably 0.5 mass % or higher and more preferably 1 mass % or higher. In addition, the content of the dispersant is preferably 1 to 100 parts by mass with respect to 100 parts by mass of the near infrared absorbing compound A (in a case where the composition further includes pigments other than the near infrared absorbing compound A in addition to the near infrared absorbing compound A, with respect to the total mass of the near infrared absorbing compound A and the other pigments). The upper limit is preferably 80 parts by mass or less and more preferably 60 parts by mass or less. The lower limit is preferably 2.5 parts by mass or more and more preferably 5 parts by mass or more.

<<Curable Compound>>

It is preferable that the composition according to the embodiment of the present invention includes a curable compound. As the curable compound, a well-known compound which is crosslinkable by a radical, an acid, or heat can be used. Examples of the crosslinking compound include a compound which has a group having an ethylenically unsaturated bond, a compound having a cyclic ether group, and a compound having a methylol group. Examples of the group having an ethylenically unsaturated bond include a vinyl group, a (meth)allyl group, and a (meth)acryloyl group. Examples of the cyclic ether group include an epoxy group and an oxetanyl group. As the compound having a cyclic ether group, a compound having an epoxy group is preferable.

In a case where a pattern is formed using the composition according to the embodiment of the present invention with a photolithography method, as the curable compound, a polymerizable compound is preferably used, and a radically polymerizable compound is more preferably used.

In a case where a pattern is formed using the composition according to the embodiment of the present invention with a dry etching method, or in a case where a pattern is not formed, as the curable compound, a compound having a cyclic ether group (preferably a compound having an epoxy group) is preferably used. According to this aspect, properties of the obtained film such as heat resistance r light fastness, or adhesiveness with a support such as a glass substrate can be further improved.

The content of the curable compound is preferably 0.1 to 40 mass % with respect to the total solid content of the composition. For example, the lower limit is preferably 0.5 mass % or higher and more preferably 1 mass % or higher. For example, the upper limit is more preferably 30 mass % or lower and still more preferably 20 mass % or lower. As the curable compound, one kind may be used alone, or two or more kinds may be used in combination. In a case where two or more polymerizable compounds are used in combination, it is preferable that the total content of the two or more polymerizable compounds is in the above-described range.

(Polymerizable Compound)

As the polymerizable compound, a compound that is polymerizable by the action of a radical is preferable. That is, it is preferable that the polymerizable compound is a radically polymerizable compound. As the polymerizable compound, a compound having one or more groups having an ethylenically unsaturated bond is preferable, a compound having two or more groups having an ethylenically unsaturated bond is more preferable, and a compound having three or more groups having an ethylenically unsaturated bond is still more preferable. The upper limit of the number of the groups having an ethylenically unsaturated bond is, for example, preferably 15 or less and more preferably 6 or less. Examples of the group having an ethylenically unsaturated bond include a vinyl group, a styryl group, a (meth)allyl group, and a (meth)acryloyl group. Among these, a (meth)acryloyl group is preferable. The polymerizable compound is preferably a (meth)acrylate compound having 3 to 15 functional groups and more preferably a (meth)acrylate compound having 3 to 6 functional groups.

The polymerizable compound may be in the form of a monomer or a polymer and is preferably a monomer. The molecular weight of the monomer type polymerizable compound is preferably 100 to 3000. The upper limit is preferably 2000 or lower and more preferably 1500 or lower. The lower limit is preferably 150 or higher and more preferably 250 or higher. In addition, it is preferable that the polymerizable compound is a compound substantially not having a molecular weight distribution. Here, the compound substantially not having a molecular weight distribution represents that the dispersity (weight-average molecular weight (Mw)/number-average molecular weight (Mn)) of the compound is preferably 1.0 to 1.5 and more preferably 1.0 to 1.3.

Examples of the polymerizable compound can be found in paragraphs “0033” and “0034” of JP2013-253224A, the content of which is incorporated herein by reference. As the polymerizable compound, ethyleneoxy-modified pentaerythritol tetraacrylate (as a commercially available product, NK ESTER ATM-35E manufactured by Shin-Nakamura Chemical Co., Ltd.), dipentaerythritol triacrylate (as a commercially available product, KAYARAD D-330 manufactured by Nippon Kayaku Co., Ltd.), dipentaerythritol tetraacrylate (as a commercially available product, KAYARAD D-320 manufactured by Nippon Kayaku Co., Ltd.), dipentaerythritol penta(meth)acrylate (as a commercially available product, KAYARAD D-310 manufactured by Nippon Kayaku Co., Ltd.), dipentaerythritol hexa(meth)acrylate (as a commercially available product, KAYARAD DPHA manufactured by Nippon Kayaku Co., Ltd., A-DPH-12E, manufactured by Shin-Nakamura Chemical Co., Ltd.), or a structure in which the (meth)acryloyl group is bonded through an ethylene glycol residue and/or a propylene glycol residue is preferable. In addition, oligomers of the above-described examples can be used. For example, the details of the polymerizable compound can be found in paragraphs “0034” to “0038” of JP2013-253224A, the content of which is incorporated herein by reference. Examples of the compound having an ethylenically unsaturated bond include a polymerizable monomer in paragraph “0477” of JP2012-208494A (corresponding to paragraph “0585” of US2012/0235099A), the content of which is incorporated herein by reference. In addition, diglycerin ethylene oxide (EO)-modified (meth)acrylate (as a commercially available product, M-460 manufactured by Toagosei Co., Ltd.), pentaerythritol tetraacrylate (A-TMMT manufactured by Shin-Nakamura Chemical Co., Ltd.), or 1,6-hexanediol diacrylate (KAYARAD HDDA manufactured by Nippon Kayaku Co., Ltd.) is also preferable. Oligomers of the above-described examples can be used. For examples, RP-1040 (manufactured by Nippon Kayaku Co., Ltd.) is used.

The polymerizable compound may have an acid group such as a carboxyl group, a sulfo group, or a phosphate group. Examples of the polymerizable compound having an acid group include an ester of an aliphatic polyhydroxy compound and an unsaturated carboxylic acid. A polymerizable compound having an acid group obtained by causing a nonaromatic carboxylic anhydride to react with an unreacted hydroxyl group of an aliphatic polyhydroxy compound is preferable. In particular, it is more preferable that, in this ester, the aliphatic polyhydroxy compound is pentaerythritol and/or dipentaerythritol. Examples of a commercially available product of the monomer having an acid group include M-305, M-510, and M-520 of ARONIX series as polybasic acid-modified acrylic oligomer (manufactured by Toagosei Co., Ltd.). The acid value of the polymerizable compound having an acid group is preferably 0.1 to 40 mgKOH/g. The lower limit is preferably 5 mgKOH/g or higher. The upper limit is preferably 30 mgKOH/g or lower.

In addition, it is also preferable that the polymerizable compound is a compound having a caprolactone structure. The polymerizable compound having a caprolactone structure is not particularly limited as long as it has a caprolactone structure in the molecule thereof, and examples thereof include ε-caprolactone-modified polyfunctional (meth)acrylate obtained by esterification of a polyhydric alcohol, (meth)acrylic acid, and ε-caprolactone, the polyhydric alcohol being, for example, trimethylolethane, ditrimethylolethane, trimethylolpropane, ditrimethylolpropane, pentaerythritol, dipentaerythritol, tripentaerythritol, glycerin, diglycerol, or trimethylolmelamine. Examples of the polymerizable compound having a caprolactone structure can be found in paragraphs “0042” to “0045” of JP2013-253224A, the content of which is incorporated herein by reference. Examples of the compound having a caprolactone structure include: DPCA-20, DPCA-30, DPCA-60, and DPCA-120 which are commercially available as KAYARADDPCA series manufactured by Nippon Kayaku Co., Ltd.; SR-494 (manufactured by Sartomer) which is a tetrafunctional acrylate having four ethyleneoxy chains; and TPA-330 which is a trifunctional acrylate having three isobutyleneoxy chains.

As the polymerizable compound, a urethane acrylate described in JP1973-041708B (JP-S48-041708B), JP1976-037193A (JP-S51-037193A), JP1990-032293B (JP-112-032293B), or JP1990-016765B (JP-H2-016765B), or a urethane compound having a ethylene oxide skeleton described in JP1983-049860B (JP-S58-049860B), JP1981-017654B (JP-S56-017654B), JP1987-039417B (JP-S62-039417B), or JP1987-039418B (JP-S62-039418B) is also preferable. In addition, an addition-polymerizable compound having an amino structure or a sulfide structure in the molecules described in JP1988-277653A (JP-S63-277653A), JP1988-260909A (JP-S63-260909A), or JP1989-105238A (JP-H1-105238A) can be used. In addition, a compound described in JP2017-048367A, JP6057891B, or JP6031807B can also be used. Examples of a commercially available product of the polymerizable compound include URETHANE OLIGOMER UAS-10 and UAB-140 (manufactured by Sanyo-Kokusaku Pulp Co., Ltd.), UA-7200 (manufactured by Shin-Nakamura Chemical Co., Ltd.), DPHA-40H (manufactured by Nippon Kayaku Co., Ltd.), and UA-306H, UA-306T, UA-306I, AH-600, T-600 and AI-600 (manufactured by Kyoeisha Chemical Co., Ltd.).

In a case where the composition according to the embodiment of the present invention includes the polymerizable compound, the content of the polymerizable compound is preferably 0.1 to 40 mass % with respect to the total solid content of the composition. For example, the lower limit is preferably 0.5 mass % or higher and more preferably 1 mass % or higher. For example, the upper limit is more preferably 30 mass % or lower and still more preferably 20 mass % or lower. As the polymerizable compound, one kind may be used alone, or two or more kinds may be used in combination. In a case where two or more polymerizable compounds are used in combination, it is preferable that the total content of the two or more polymerizable compounds is in the above-described range.

(Compound Having Cyclic Ether Group)

Examples of the compound having a cyclic ether group include a compound having an epoxy group and/or an oxetanyl group. In particular, a compound having an epoxy group is preferable.

Examples of the compound having an epoxy group include a compound having one or more epoxy groups in one molecule. In particular, a compound having two or more epoxy groups in one molecule is preferable. The number of epoxy groups in one molecule is preferably 1 to 100. The upper limit of the number of epoxy groups is, for example, 10 or less or 5 or less. The lower limit of the number of epoxy groups is preferably 2 or more.

The compound having an epoxy group may be a low molecular weight compound (for example, molecular weight: lower than 2000 or lower than 1000) or a high molecular weight compound (macromolecule; for example, molecular weight: 1000 or higher, and in the case of a polymer, weight-average molecular weight: 1000 or higher). The weight-average molecular weight of the compound having an epoxy group is preferably 200 to 100000 and more preferably 500 to 50000. The upper limit of the weight-average molecular weight is preferably 10000 or lower, more preferably 5000 or lower, and still more preferably 3000 or lower.

As the compound having an epoxy group, an epoxy resin can be preferably used. Examples of the epoxy resin include an epoxy resin which is a glycidyl-etherified product of a phenol compound, an epoxy resin which is a glycidyl-etherified product of various novolac resins, an alicyclic epoxy resin, an aliphatic epoxy resin, a heterocyclic epoxy resin, a glycidyl ester epoxy resin, a glycidyl amine epoxy resin, an epoxy resin which is a glycidylated product of a halogenated phenol, a condensate of a silicon compound having an epoxy group and another silicon compound, and a copolymer of a polymerizable unsaturated compound having an epoxy group and another polymerizable unsaturated compound.

Examples of the epoxy resin which is a glycidyl-etherified product of a phenol compound include: 2-[4-(2,3-epoxypropoxy)phenyl]-2-[4-[1,1-bis[4-(2,3-hydroxy)phenyl]ethyl]phenyl]propane, bisphenol A, bisphenol F, bisphenol S, 4,4′-biphenol, tetramethyl bisphenol A, dimethyl bisphenol A, tetramethyl bisphenol F, dimethyl bisphenol F, tetramethyl bisphenol S, dimethyl bisphenol S, tetramethyl-4,4′-biphenol, dimethyl-4,4′-biphenol, 1-(4-hydroxyphenyl)-2-[4-(1,1-bis-(4-hydroxyphenyl)ethyl)phenyl]propane, 2,2′-methylene-bis(4-methyl-6-t-butylphenol), 4,4′-butylidene-bis(3-methyl-6-t-butylphenol), trishydroxyphenylmethane, resorcinol, hydroquinone, pyrogallol, phloroglucinol, a phenol having a diisopropylidene skeleton; a phenol having a fluorene skeleton such as 1,1-di-4-hydroxyphenyl fluorene; and an epoxy resin which is a glycidyl-etherified product of a polyphenol compound, such as phenolic polybutadiene.

Examples of the epoxy resin which is a glycidyl-etherified product of a novolac resin include glycidyl-etherified products of various novolac resins including: novolac resins which contain various phenols, for example, phenol, cresols, ethyl phenols, butyl phenols, octyl phenols, bisphenols such as bisphenol A, bisphenol F, or bisphenol S, or naphthols; phenol novolac resins having a xylylene skeleton; phenol novolac resins having a dicyclopentadiene skeleton; phenol novolac resins having a biphenyl skeleton; or phenol novolac resins having a fluorene skeleton.

Examples of the alicyclic epoxy resin include an alicyclic epoxy resin having an aliphatic ring skeleton such as 3,4-epoxycyclohexylmethyl-(3,4-epoxy)cyclohexylcarboxylate or bis(3,4-epoxycyclohexylmethyl)adipate.

Examples of the aliphatic epoxy resin include glycidyl ethers of polyhydric alcohols such as 1,4-butanediol, 1,6-hexanediol, polyethylene glycol, or pentaerythritol.

Examples of the heterocyclic epoxy resin include an heterocyclic epoxy resin having a heterocycle such as an isocyanuric ring or a hydantoin ring.

Examples of the glycidyl ester epoxy resin include an epoxy resin including a carboxylic acid ester such as hexahydrophthalic acid diglycidyl ester.

Examples of the glycidyl amine epoxy resin include an epoxy resin which is a glycidylated product of an amine such as aniline or toluidine.

Examples of the epoxy resin which is a glycidylated product of a halogenated phenol include an epoxy resin which is a glycidylated product of a halogenated phenol such as brominated bisphenol A, brominated bisphenol F, brominated bisphenol S, brominated phenol novolac, brominated cresol novolac, chlorinated bisphenol S, or chlorinated bisphenol A.

Examples of a commercially available product of the copolymer of a polymerizable unsaturated compound having an epoxy group and another polymerizable unsaturated compound include MARPROOF G-0150M, G-0105SA, G-0130SP, G-0250SP, G-1005S, G-1005SA, G-1010S, G-2050M, G-01100, and G-01758 (all of which are manufactured by NOF Corporation; epoxy group-containing polymers). Examples of the polymerizable unsaturated compound having an epoxy group include glycidyl acrylate, glycidyl methacrylate, and 4-vinyl-1-cyclohexene-1,2-epoxide. In addition, examples of a copolymer of the other polymerizable unsaturated compound include methyl (meth)acrylate, benzyl (meth)acrylate, cyclohexyl (meth)acrylate, styrene, and vinyl cyclohexane. In particular, methyl (meth)acrylate, benzyl (meth)acrylate, or styrene is preferable.

The epoxy equivalent of the epoxy resin is preferably 310 to 3300 g/eq, more preferably 310 to 1700 g/eq, and still more preferably 310 to 1000 g/eq.

As the epoxy resin, a commercially available product can also be used. Examples of the commercially available product include EPICLON HP-4700 (manufactured by DIC Corporation), JER1031S (manufactured by Mitsubishi Chemical Corporation), EHPE 3150 (manufactured by Daicel Corporation), and EOCN-1020 (manufactured by Nippon Kayaku Co., Ltd.).

In the present invention, as the compound having a cyclic ether group, a compound described in paragraphs “0034” to “0036” of JP2013-011869A, paragraphs “0147” to “0156” of JP2014-043556A, and paragraphs “0085” to “0092” of JP2014-089408A can also be used. The contents of which are incorporated herein by reference.

In a case where the composition according to the embodiment of the present invention includes the compound having a cyclic ether group, the content of the compound having a cyclic ether group is preferably 0.1 to 40 mass % with respect to the total solid content of the composition. For example, the lower limit is preferably 0.5 mass % or higher and more preferably 1 mass % or higher. For example, the upper limit is more preferably 30 mass % or lower and still more preferably 20 mass % or lower. As the compound having a cyclic ether group, one kind may be used alone, or two or more kinds may be used in combination. In a case where two or more compounds having a cyclic ether group are used in combination, it is preferable that the total content of the two or more compounds having a cyclic ether group is in the above-described range.

In addition, in a case where the composition according to the embodiment of the present invention includes the polymerizable compound and the compound having a cyclic ether group, a mass ratio polymerizable compound:compound having a cyclic ether group is preferably 100:1 to 100:400 and more preferably 100:1 to 100:100.

<<Photopolymerization Initiator>>

The composition according to the embodiment of the present invention may include a photopolymerization initiator. In particular, in a case where the composition according to the embodiment of the present invention includes the polymerizable compound (preferably the radically polymerizable compound), it is preferable that the composition includes a photopolymerization initiator. The photopolymerization initiator is not particularly limited and can be appropriately selected from well-known photopolymerization initiators. For example, a compound having photosensitivity to light in a range from the ultraviolet range to the visible range is preferable. It is preferable that the photopolymerization initiator is a photoradical polymerization initiator.

Examples of the photopolymerization initiator include: a halogenated hydrocarbon derivative (For example, a compound having a triazine skeleton or a compound having an oxadiazole skeleton); an acylphosphine compound such as acylphosphine oxide; an oxime compound such as hexaarylbiimidazole or an oxime derivative; an organic peroxide, a thio compound, a ketone compound, an aromatic onium salt, keto oxime ether, an aminoacetophenone compound, and hydroxyacetophenone. Examples of the halogenated hydrocarbon compound having a triazine skeleton include a compound described in Bull. Chem. Soc. Japan, 42, 2924 (1969) by Wakabayshi et al., a compound described in Great Britain Patent No. 1388492, a compound described in JP1978-133428A (JP-S53-133428A), a compound described in German Patent No. 3337024, a compound described in J. Org. Chem.; 29, 1527 (1964) by F. C. Schaefer et al., a compound described in JP1987-058241A (JP-S62-058241A), a compound described in JP1993-281728A (JP-H5-281728A), a compound described in JP1993-034920A (JP-55-034920A), and a compound described in U.S. Pat. No. 4,212,976A.

In addition, from the viewpoint of exposure sensitivity, as the photopolymerization initiator, a compound selected from the group consisting of a trihalomethyltriazine compound, a benzyldimethylketanol compound, an α-hydroxy ketone compound, an α-aminoketone compound, an acylphosphine compound, a phosphine oxide compound, a metallocene compound, an oxime compound, a triarylimidazole dimer, an onium compound, a benzothiazole compound, a benzophenone compound, an acetophenone compound, a cyclopentadiene-benzene-iron complex, a halomethyl oxadiazole compound, or a 3-aryl-substituted coumarin compound is preferable.

As the photopolymerization initiator, an α-hydroxyketone compound, an α-aminoketone compound, or an acylphosphine compound can also be preferably used. For example, an α-aminoketone compound described in JP1998-291969A (JP-H10-291969A) or an acylphosphine compound described in JP4225898B can also be used. As the α-hydroxyketone compound, for example, IRGACURE-184, DAROCUR-1173, IRGACURE-500, IRGACURE-2959, or IRGACURE-127 (all of which are manufactured by BASF SE) can be used. As the α-aminoketone compound, IRGACURE-907, IRGACURE-369, IRGACURE-379, or IRGACURE-379EG (all of which are manufactured by BASF SE) which is a commercially available product can be used. As the α-aminoketone compound, a compound described in JP2009-191179A can be used. As the acylphosphine compound, IRGACURE-819, or DAROCUR-TPO (all of which are manufactured by BASF SE) which is a commercially available product can be used.

As the photopolymerization initiator, an oxime compound can be preferably used. Specific examples of the oxime compound include a compound described in JP2001-233842A, a compound described in JP2000-080068A, a compound described in JP2006-342166A, a compound described in JP2016-021012A, a compound described in JP2017-019766A, a compound described in JP6065596B, a compound described in WO2015/152153A, and a compound described in WO2017/051680A. Examples of the oxime compound which can be preferably used in the present invention include 3-benzoyloxyiminobutane-2-one, 3-acetoxyiminobutane-2-one, 3-propionyloxyiminobutane-2-one, 2-acetoxyiminopentane-3-one, 2-acetoxyimino-1-phenylpropane-1-one, 2-benzoyloxyimino-1-phenylpropane-1-one, 3-(4-toluene sulfonyloxy)iminobutane-2-one, and 2-ethoxycarbonyloxyimino-1-phenylpropane-1-one. In addition, examples of the oxime compound include a compound described in J.C.S. Perkin II (1979), pp. 1653-1660, J.C.S. Perkin II (1979), pp. 156-162 and Journal of Photopolymer Science and Technology (1995), pp. 202-232, JP2000-066385A, JP2000-080068A, JP2004-534797A, or JP2006-342166A.

As a commercially available product of the oxime compound, IRGACURE-OXE01, IRGACURE-OXE02, IRGACURE-OXE03, or IRGACURE-OXE04 (all of which are manufactured by BASF SE) can also be preferably used. In addition, TR-PBG-304 (manufactured by Changzhou Tronly New Electronic Materials Co., Ltd.), ADEKA ARKLS NCI-831 (manufactured by Adeka Corporation), ADEKA ARKLS NCI-930 (manufactured by Adeka Corporation), ADEKA OPTOMER N-1919 (manufactured by Adeka Corporation, a photopolymerization initiator 2 described in JP2012-014052A) can also be used.

In addition, in addition to the above-described oxime compounds, for example, a compound described in JP2009-519904A in which oxime is linked to a N-position of a carbazole ring, a compound described in U.S. Pat. No. 7,626,957B in which a hetero substituent is introduced into the benzophenone site, a compound described in JP2010-015025A or US2009/292039A in which a nitro group is introduced into a colorant site, a ketoxime compound described in WO2009/131189A, a compound described in U.S. Pat. No. 7,556,910B having a triazine skeleton and an oxime skeleton in the same molecule, a compound described in JP2009-221114A having an absorption maximum at 405 nm and having excellent sensitivity to a light source of g-rays may be used.

As the oxime compound, a compound represented by the following Formula (OX-1) can be preferably used. In the oxime compound, an N—O bond of oxime may form an (E) isomer, a (Z) isomer, or a mixture of an (E) isomer and a (Z) isomer.

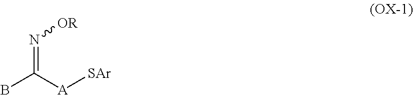

In Formula (OX-1), R and B each independently represent a monovalent substituent, A represents a divalent organic group, and Ar represents an aryl group. The details of Formula (OX-1) can be found in paragraphs “0276” to “0304” of JP2013-029760A, the content of which is incorporated herein by reference.

In the present invention, an oxime compound having a fluorene ring can also be used as the photopolymerization initiator. Specific examples of the oxime compound having a fluorene ring include a compound described in JP2014-137466A. The content is incorporated herein by reference.

In the present invention, an oxime compound having a fluorine atom can also be used as the photopolymerization initiator. Specific examples of the oxime compound having a fluorine atom include a compound described in JP2010-262028A, Compound 24 and 36 to 40 described in JP2014-500852A, and Compound (C-3) described in JP2013-164471A. The content is incorporated herein by reference.

In the present invention, as the photopolymerization initiator, an oxime compound having a nitro group can be used. It is preferable that the oxime compound having a nitro group is a dimer. Specific examples of the oxime compound having a nitro group include a compound described in paragraphs “0031” to “0047” of JP2013-114249A and paragraphs “0008” to “0012” and “0070” to “0079” of JP2014-137466A, a compound described in paragraphs “0007” to 0025” of JP4223071B, and ADEKA ARKLS NCI-831 (manufactured by Adeka Corporation).

Hereinafter, specific examples of the oxime compound which are preferably used in the present invention are shown below, but the present invention is not limited thereto.

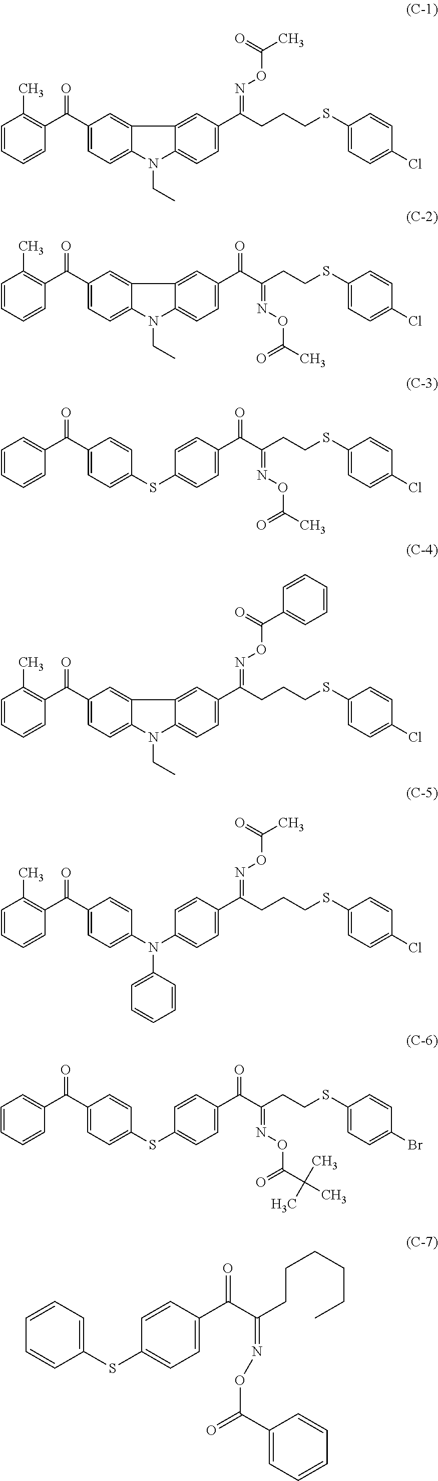

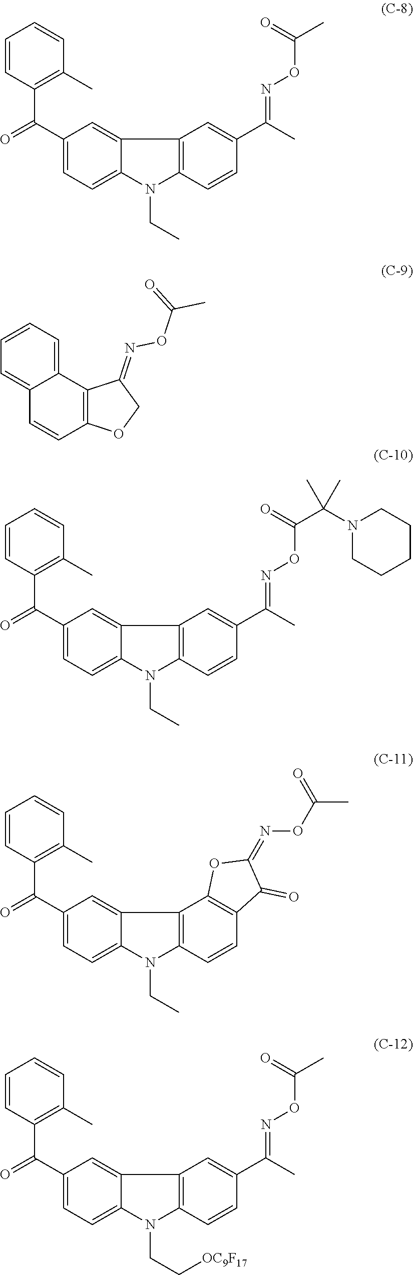

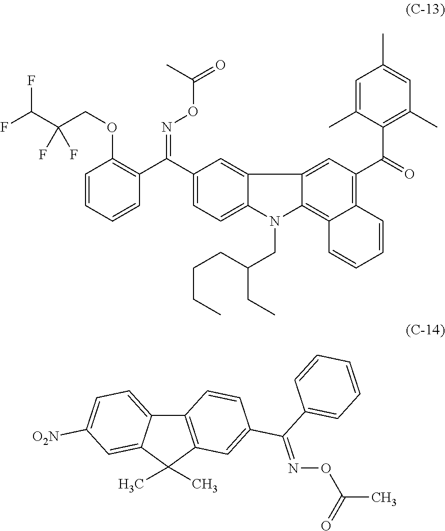 [SMILES: CCCCC(CC)Cn1c2ccc(/C(=N\OC(C)=O)c3ccccc3OCC(F)(F)C(F)F)cc2c2cc(C(=O)c3c(C)cc(C)cc3C)c3ccccc3c21 ; CC(=O)O/N=C(\c1ccccc1)c1ccc2c(c1)C(C)(C)c1cc([N+](=O)[O-])ccc1-2]

The oxime compound is preferably a compound having an absorption maximum in a wavelength range of 350 nm to 500 nm and more preferably a compound having an absorption maximum in a wavelength range of 360 nm to 480 nm. In addition, the oxime compound is preferably a compound having a high absorbance at 365 nm and 405 nm.

The molar absorption coefficient of the oxime compound at 365 nm or 405 nm is preferably 1000 to 300000, more preferably 2000 to 300000, and still more preferably 5000 to 200000 from the viewpoint of sensitivity.

The molar absorption coefficient of the compound can be measured using a well-known method. For example, it is preferable that the absorption coefficient can be measured using an ultraviolet-visible spectrophotometer (Cary-5 spectrophotometer, manufactured by Varian Medical Systems, Inc.) and ethyl acetate as a solvent at a concentration of 0.01 g/L.

It is preferable that the photopolymerization initiator includes an oxime compound and an α-aminoketone compound. By using the oxime compound and the α-aminoketone compound in combination, the developability is improved, and a pattern having excellent rectangularity is likely to be formed. In a case where the oxime compound and the α-aminoketone compound are used in combination, the content of the α-aminoketone compound is preferably 50 to 600 parts by mass and more preferably 150 to 400 parts by mass with respect to 100 parts by mass of the oxime compound.

The content of the photopolymerization initiator is preferably 0.1 to 50 mass %, more preferably 0.5 to 30 mass %, and still more preferably 1 to 20 mass % with respect to the total solid content of the composition. In a case where the content of the photopolymerization initiator is in the above-described range, higher sensitivity and pattern formability can be obtained. The composition according to the embodiment of the present invention may include one photopolymerization initiator or two or more photopolymerization initiators. In a case where the composition includes two or more photopolymerization initiators, it is preferable that the total content of the photopolymerization initiators is in the above-described range.

<<Epoxy Curing Agent>>

In a case where the composition according to the embodiment of the present invention includes the compound having an epoxy group, it is preferable that the composition further includes an epoxy curing agent. Examples of the epoxy curing agent include an amine compound, an acid anhydride compound, an amide compound, a phenol compound, a polycarboxylic acid, and a thiol compound. From the viewpoints of heat resistance and transparency of a cured product, as the epoxy curing agent, a polycarboxylic acid is preferable, and a compound having two or more carboxylic anhydride groups in a molecule is most preferable. Specific examples of the epoxy curing agent include succinic acid, trimellitic acid, pyromellitic acid, N,N-dimethyl-4-aminopyridine, and pentaerythritol tetrakis(3-mercaptopropionate). As the epoxy curing agent, a compound described in paragraphs “0072” to “0078” of JP2016-075720A or a compound described in JP2017-036379A can also be used, the content of which is incorporated herein by reference.

The content of the epoxy curing agent is preferably 0.01 to 20 parts by mass, more preferably 0.01 to 10 parts by mass, and still more preferably 0.1 to 6.0 parts by mass with respect to 100 parts by mass of the compound having an epoxy group.

<<Organic Solvent>>

The composition according to the embodiment of the present invention includes an organic solvent. Basically, the organic solvent is not particularly limited as long as it satisfies the solubility of each component and the coating properties of the composition. However, it is preferable that the organic solvent is selected in consideration of the coating properties and safety of the composition.

Preferable examples of the organic solvent are the following organic solvents:
an ester, for example, ethyl acetate, n-butyl acetate, isobutyl acetate, cyclohexyl acetate, amyl formate, isoamyl acetate, butyl propionate, isopropyl butyrate, ethyl butyrate, butyl butyrate, methyl lactate, ethyl lactate, alkyl alkoxyacetate (for example, methyl alkoxyacetate, ethyl alkoxyacetate, or butyl alkoxyacetate (for example, methyl methoxyacetate, ethyl methoxyacetate, butyl methoxyacetate, methyl ethoxyacetate, or ethyl ethoxyacetate)), alkyl 3-alkoxypropionate (for example, methyl 3-alkoxypropionate or ethyl 3-alkoxypropionate (for example, 3-methyl methoxypropionate, 3-ethyl methoxypropionate, 3-methyl ethoxypropionate, or 3-ethyl ethoxypropionate)), alkyl 2-alkoxypropionate (for example, methyl 2-alkoxypropionate, ethyl 2-alkoxypropionate, or propyl 2-alkoxypropionate, (for example, methyl 2-methoxypropionate, ethyl 2-methoxypropionate, propyl 2-methoxypropionate, methyl 2-ethoxypropionate, or 2-ethyl ethoxypropionate)), methyl 2-alkoxy-2-methylpropionate, ethyl 2-alkoxy-2-methylpropionate (for example, methyl 2-methoxy-2-methylpropionate or ethyl 2-ethoxy-2-methylpropionate), methyl pyruvate, ethyl pyruvate, propyl pyruvate, methyl acetoacetate, ethyl acetoacetate, methyl 2-oxobutanoate, or ethyl 2-oxobutanoate;
an ether, for example, diethylene glycol dimethyl ether, tetrahydrofuran, ethylene glycol monomethyl ether, ethylene glycol monoethyl ether, methyl cellosolve acetate, ethyl cellosolve acetate, diethylene glycol monomethyl ether, diethylene glycol monoethyl ether, diethylene glycol monobutyl ether, diethylene glycol monobutyl ether acetate, propylene glycol monomethyl ether, propylene glycol monomethyl ether acetate, propylene glycol monoethyl ether acetate, or propylene glycol monopropyl ether acetate;
a ketone, for example, methyl ethyl ketone, cyclohexanone, cyclopentanone, 2-heptanone, or 3-heptanone; and
an aromatic hydrocarbon, for example, toluene or xylene. In this case, it may be preferable that the content of the aromatic hydrocarbon (for example, benzene, toluene, xylene, or ethylbenzene) as the organic solvent is low (for example, 50 mass parts per million (ppm) or lower, 10 mass ppm or lower, or 1 mass ppm or lower with respect to the total mass of the organic solvent) in consideration of environmental aspects and the like.

Among these organic solvents, one kind may be used alone, or two or more kinds may be used in combination. In a case where two or more organic solvents are used in combination, a mixed solution is preferable, the mixed solution including two or more organic solvents selected from the group consisting of methyl 3-ethoxypropionate, ethyl 3-ethoxypropionate, ethyl cellosolve acetate, ethyl lactate, diethylene glycol dimethyl ether, butyl acetate, methyl 3-methoxypropionate, 2-heptanone, cyclohexanone, ethyl carbitol acetate, butyl carbitol acetate, propylene glycol methyl ether, and propylene glycol methyl ether acetate.

In the present invention, an organic solvent having a low metal content is preferably used. For example, the metal content in the organic solvent is preferably 10 mass parts per billion (ppb) or lower. Optionally, an organic solvent having a metal content at a mass parts per trillion (ppt) level may be used. For example, such a high-purity organic solvent is available from Toyo Gosei Co., Ltd. (The Chemical Daily, Nov. 13, 2015).

Examples of a method of removing impurities such as metal from the organic solvent include distillation (for example, molecular distillation or thin-film distillation) and filtering using a filter. The pore size of a filter used for the filtering is preferably 10 nm or less, more preferably 5 nm or less, and still more preferably 3 nm or less. As a material of the filter, polytetrafluoroethylene, polyethylene, or nylon is preferable.

The organic solvent may include an isomer (a compound having the same number of atoms and a different structure). In addition, the organic solvent may include only one isomer or a plurality of isomers.

In the present invention, as the organic solvent, an organic solvent containing 0.8 mmol/L or lower of a peroxide is preferable, and an organic solvent containing substantially no peroxide is more preferable.

The content of the organic solvent is preferably 10 to 90 mass %, more preferably 20 to 80 mass %, and still more preferably 25 to 75 mass % with respect to the total mass of the composition.

<<Polymerization Inhibitor>>

The composition according to the embodiment of the present invention may include a polymerization inhibitor. Examples of the polymerization inhibitor include hydroquinone, p-methoxyphenol, di-t-butyl-p-cresol, pyrogallol, t-butylcatechol, benzoquinone, 4,4′-thiobis(3-methyl-6-t-butylphenol), 2,2′-methylenebis(4-methyl-6-t-butylphenol), and N-nitrosophenylhydroxyamine salt (for example, an ammonium salt or a cerium (III) salt). Among these, p-methoxyphenol is preferable. The content of the polymerization inhibitor is preferably 0.01 to 5 mass % with respect to the total solid content of the composition.

<<<Surfactant>>>

The composition according to the present invention may include a surfactant from the viewpoint of further improving coating properties. As the surfactants, various surfactants such as a fluorine surfactant, a nonionic surfactant, a cationic surfactant, an anionic surfactant, or a silicone surfactant can be used.

By the composition according to the embodiment of the present invention containing a fluorine surfactant, liquid characteristics (for example, fluidity) of a coating solution prepared from the coloring composition are further improved, and the uniformity in coating thickness and liquid saving properties can be further improved. In a case where a film is formed using a coating solution prepared using the composition including a fluorine surfactant, the interfacial tension between a coated surface and the coating solution decreases, the wettability on the coated surface is improved, and the coating properties on the coated surface are improved. Therefore, a film having a uniform thickness with reduced unevenness in thickness can be formed more suitably.

The fluorine content in the fluorine surfactant is preferably 3 to 40 mass %, more preferably 5 to 30 mass %, and still more preferably 7 to 25 mass %. The fluorine surfactant in which the fluorine content is in the above-described range is effective from the viewpoints of the uniformity in the thickness of the coating film and liquid saving properties, and the solubility thereof in the composition is also excellent.

Specific examples of the fluorine surfactant include a surfactant described in paragraphs “0060” to “0064” of JP2014-041318A (paragraphs “0060” to “0064” of corresponding WO2014/017669A) and a surfactant described in paragraphs “0117” to “0132” of JP2011-132503A, the content of which is incorporated herein by reference. Examples of a commercially available product of the fluorine surfactant include: MEGAFACE F171, F172, F173, F176, F177, F141, F142, F143, F144, R30, F437, F475, F479, F482, F554, F780, EXP, and MFS-330 (all of which are manufactured by DIC Corporation); FLUORAD FC430, FC431, and FC171 (all of which are manufactured by Sumitomo 3M Ltd.); SURFLON S-382, SC-101, SC-103, SC-104, SC-105, SC-1068, SC-381, SC-383, S-393, and KH-40 (all of which are manufactured by Asahi Glass Co., Ltd.); and POLYFOX PF636, PF656, PF6320, PF6520, and PF7002 (all of which are manufactured by OMNOVA Solutions Inc.).

In addition, as the fluorine surfactant, an acrylic compound in which, in a case where heat is applied to a molecular structure which has a functional group having a fluorine atom, the functional group having a fluorine atom is cut and a fluorine atom is volatilized can also be preferably used. Examples of the fluorine surfactant include MEGAFACE DS series (manufactured by DIC Corporation, The Chemical Daily, Feb. 22, 2016, Nikkei Business Daily, Feb. 23, 2016), for example, MEGAFACE DS-21.

As the fluorine surfactant, a block polymer can also be used. Examples of the block polymer include a compound described in JP2011-089090A. As the fluorine surfactant, a fluorine-containing polymer compound can be preferably used, the fluorine-containing polymer compound including: a repeating unit derived from a (meth)acrylate compound having a fluorine atom; and a repeating unit derived from a (meth)acrylate compound having 2 or more (preferably 5 or more) alkyleneoxy groups (preferably an ethyleneoxy group and a propyleneoxy group). For example, the following compound can also be used as the fluorine surfactant used in the present invention.

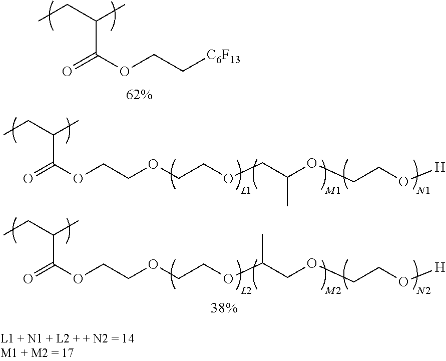

The weight-average molecular weight of the compound is preferably 3000 to 50000 and, for example, 14000. In the compound, “%” representing the proportion of a repeating unit is mass %.

In addition, as the fluorine surfactant, a fluorine-containing polymer having an ethylenically unsaturated group at a side chain can also be used. Specific examples include a compound described in paragraphs “0050” of “0090” and paragraphs “0289” to “0295” of JP2010-164965A, for example, MEGAFACE RS-101, RS-102, RS-718K, and RS-72-K manufactured by DIC Corporation. As the fluorine surfactant, a compound described in paragraphs “0015” to “0158” of JP2015-117327A can also be used.

Examples of the nonionic surfactant include glycerol, trimethylolpropane, trimethylolethane, an ethoxylate and a propoxylate thereof (for example, glycerol propoxylate or glycerol ethoxylate), polyoxyethylene lauryl ether, polyoxyethylene stearyl ether, polyoxyethylene oleyl ether, polyoxyethylene octylphenyl ether, polyoxyethylene nonylphenyl ether, polyethylene glycol dilaurate, polyethylene glycol distearate, and sorbitan fatty acid esters (PLURONIC L10, L31, L61, L62, 10R5, 17R2, and 25R2 (manufactured by BASF SE) and TETRONIC 304, 701, 704, 901, 904, and 150R1 (manufactured by BASF SE)); SOLSPERSE 20000 (manufactured by Lubrication Technology Inc.); NCW-101, NCW-1001, and NCW-1002 (all of which are manufactured by Wako Pure Chemical Industries, Ltd.); PIONIN D-6112, D-6112-W, and D-6315 (all of which are manufactured by Takemoto Oil&Fat Co., Ltd.); and OLFINE E1010, SURFYNOL 104, 400, and 440 (all of which are manufactured by Nissin Chemical Co., Ltd.).

Examples of the cationic surfactant include an organosiloxane polymer KP341 (manufactured by Shin-Etsu Chemical Co., Ltd.), a (meth)acrylic acid (co)polymer POLYFLOW No. 75, No. 90, or No. 95 (manufactured by Kyoeisha Chemical Co., Ltd.), and W001 (manufactured by Yusho Co., Ltd.).

Examples of the anionic surfactant include W004, W005, and W017 (manufactured by Yusho Co., Ltd.), and SANDET BL (manufactured by Sanyo Chemical Industries Ltd.).

Examples of the silicone surfactant include: TORAY SILICONE DC3PA, TORAY SILICONE SH7PA, TORAY SILICONE DC11PA, TORAY SILICONE SH21PA, TORAY SILICONE SH28PA, TORAY SILICONE SH29PA, TORAY SILICONE SH30PA, and TORAY SILICONE SH8400 (all of which are manufactured by Dow Corning Corporation); TSF-4440, TSF-4300, TSF-4445, TSF-4460, and TSF-4452 (all of which are manufactured by Momentive Performance Materials Inc.); KP341, KF6001, and KF6002 (all of which are manufactured by Shin-Etsu Chemical Co., Ltd.); and BYK307, BYK323, and BYK330 (all of which are manufactured by BYK-Chemie Japan K.K.).

The content of the surfactant is preferably 0.001 to 2.0 mass % and more preferably 0.005 to 1.0 mass % with respect to the total solid content of the composition. Among these surfactants, one kind may be used alone, or two or more kinds may be used in combination.

<<Ultraviolet Absorber>>

The composition according to the embodiment of the present invention may include an ultraviolet absorber. As the ultraviolet absorber, a conjugated diene compound, an amino diene compound, a salicylate compound, a benzophenone compound, a benzotriazole compound, an acrylonitrile compound, or a hydroxyphenyltriazine compound can be used. The details can be found in paragraphs “0052” to “0072” of JP2012-208374A and paragraphs “0317” to “0334” of JP2013-068814A, the contents of which are incorporated herein by reference. Examples of a commercially available product of the conjugated diene compound include UV-503 (manufactured by Daito Chemical Co., Ltd.). In addition, as the benzotriazole compound, MYUA series (manufactured by Miyoshi Oil&Fat Co., Ltd.; The Chemical Daily, Feb. 1, 2016) may be used.

The content of the ultraviolet absorber is preferably 0.01 to 10 mass % and more preferably 0.01 to 5 mass % with respect to the total solid content of the composition according to the embodiment of the present invention.

<<Silane Coupling Agent>>

The composition according to the embodiment of the present invention may include a silane coupling agent. By adding the silane coupling agent to the composition according to the embodiment of the present invention, in a case where a film is formed on a support using the composition according to the embodiment of the present invention, adhesiveness between the film and the support can be improved. The addition of the silane coupling agent is effective particularly in a case where a laminate in which a film is formed on a support such as a glass substrate using the composition according to the embodiment of the present invention is used as a near infrared cut filter.

In the present invention, the silane coupling agent is a different component from the curable compound. In the present invention, the silane coupling agent refers to a silane compound having a functional group other than a hydrolyzable group. In addition, the hydrolyzable group refers to a substituent directly linked to a silicon atom and capable of forming a siloxane bond due to at least one of a hydrolysis reaction or a condensation reaction. Examples of the hydrolyzable group include a halogen atom, an alkoxy group, and an acyloxy group. Among these, an alkoxy group is preferable. That is, it is preferable that the silane coupling agent is a compound having an alkoxysilyl group. In addition, it is preferable that the functional group other than a hydrolyzable group is a group which interacts with the resin or forms a bond with the resin to exhibit affinity. Examples of the functional group other than a hydrolyzable group include a vinyl group, a styryl group, a (meth)acryloyl group, a mercapto group, an epoxy group, an oxetanyl group, an amino group, an ureido group, a sulfide group, an isocyanate group, and a phenyl group. Among these, a (meth)acryloyl group or an epoxy group is preferable. Specific examples of the silane coupling agent include a compound described in Examples below. In addition, examples of the silane coupling agent include a compound described in paragraphs “0018” to “0036” of JP2009-288703A, a compound described in paragraphs “0056” to “0066” of JP2009-242604A, and a compound described in paragraphs “0139” to “0140” of WO2016/158819A, the contents of which are incorporated herein by reference.

The content of the silane coupling agent is preferably 0.01 to 15.0 mass %, more preferably 0.05 to 10.0 mass %, still more preferably 0.1 to 5.0 mass %, and even still more preferably 0.5 to 3.0 mass % with respect to the total solid content of the composition. As the silane coupling agent, one kind may be used alone, or two or more kinds may be used. In a case where two or more silane coupling agents are used in combination, it is preferable that the total content of the two or more silane coupling agents is in the above-described range.

<<Other Components>>

Optionally, the composition according to the present invention may further include a sensitizer, a curing accelerator, a filler, a thermal curing accelerator, a thermal polymerization inhibitor, a plasticizer, an adhesion accelerator, and other auxiliary agents (for example, conductive particles, a filler, an antifoaming agent, a flame retardant, a leveling agent, a peeling accelerator, an antioxidant, a potential antioxidant, an aromatic chemical, a surface tension adjuster, or a chain transfer agent). The details of these components can be found in paragraphs “0101” to “0104” and “0107” to “0109” of JP2008-250074A, the content of which is incorporated herein by reference. In addition, examples of the antioxidant include a phenol compound, a phosphite compound, and a thioether compound. As the antioxidant, a phenol compound having a molecular weight of 500 or higher, a phosphite compound having a molecular weight of 500 or higher, or a thioether compound having a molecular weight of 500 or higher is more preferable. Among these compounds, a mixture of two or more kinds may be used. As the phenol compound, any phenol compound which is known as a phenol antioxidant can be used. As the phenol compound, for example, a hindered phenol compound is preferable. In particular, a compound having a substituent at a position (ortho-position) adjacent to a phenolic hydroxyl group is preferable. As the substituent, a substituted or unsubstituted alkyl group having 1 to 22 carbon atoms is preferable, and a methyl group, an ethyl group, a propionyl group, an isopropionyl group, a butyl group, an isobutyl group, a t-butyl group, a pentyl group, an isopentyl group, a t-pentyl group, a hexyl group, an octyl group, an isooctyl group, or a 2-ethylhexyl group is more preferable. In addition, as the antioxidant, a compound having a phenol group and a phosphite group in the same molecule is also preferable. In addition, as the antioxidant, a phosphorus antioxidant can also be preferably used. Examples of the phosphorus antioxidant include at least one compound selected from the group consisting of tris[2-[[2,4,8,10-tetrakis(1,1-dimethylethyl)dibenzo[d,f][1,3,2]dioxaphosphepin-6-yl]oxy]ethyl]amine, tris[2-[(4,6,9,11-tetra-t-butyldibenzo[d,f][1,3,2]dioxaphosphepin-2-yl)oxy]ethyl]amine, and ethyl bis(2,4-di-t-butyl-6-methylphenyl)phosphite. These antioxidants are available as a commercially available product. Examples of the commercially available product include ADEKA STAB AO-20, ADEKA STAB AO-30, ADEKA STAB AO-40, ADEKA STAB AO-50, ADEKA STAB AO-50F, ADEKA STAB AO-60, ADEKA STAB AO-60G, ADEKA STAB AO-80, and ADEKA STAB AO-330 (all of which are manufactured by Adeka Corporation). In addition, as the antioxidant, a polyfunctional hindered amine antioxidant described in WO2017/006600A can also be used. The content of the antioxidant is preferably 0.01 to 20 mass % and more preferably 0.3 to 15 mass % with respect to the mass of the total solid content of the composition. As the antioxidant, one kind may be used alone, or two or more kinds may be used. In a case where two or more antioxidants are used in combination, it is preferable that the total content of the two or more antioxidants is in the above-described range.

The potential antioxidant is a compound in which a portion that functions as the antioxidant is protected by a protective group and this protective group is desorbed by heating the compound at 100° C. to 250° C. or by heating the compound at 80° C. to 200° C. in the presence of an acid/a base catalyst. Examples of the potential antioxidant include a compound described in WO2014/021023A, WO2017/030005A, and JP2017-008219A. Examples of a commercially available product of the potential antioxidant include ADEKA ARKLS GPA-5001 (manufactured by Adeka Corporation).

For example, in a case where a film is formed by coating, the viscosity (23° C.) of the composition according to the embodiment of the present invention is preferably in a range of 1 to 3000 mPa·s. The lower limit is preferably 3 mPa·s or higher and more preferably 5 mPa·s or higher. The upper limit is preferably 2000 mPa·s or lower and more preferably 1000 mPa·s or lower.

The composition according to the embodiment of the present invention can be preferably used for forming a near infrared cut filter, an infrared transmitting filter, or the like.

<Method of Preparing Composition>

The composition according to the embodiment of the present invention can be prepared by mixing the above-described components with each other.

During the preparation of the composition, the respective components may be mixed with each other collectively, or may be mixed with each other sequentially after dissolved and dispersed in an organic solvent. In addition, during mixing, the order of addition or working conditions are not particularly limited. For example, all the components may be dissolved or dispersed in an organic solvent at the same time to prepare the composition. Optionally, two or more solutions or dispersions to which the respective components are appropriately added may be prepared, and the solutions or dispersions may be mixed with each other during use (during application) to prepare the composition.

In addition, it is preferable that a method of preparing the composition according to the embodiment of the present invention includes a process of dispersing particles of the near infrared absorbing compound A, the other pigments, and the like. Examples of a mechanical force used for dispersing the particles in the process of dispersing the particles include compression, squeezing, impact, shearing, and cavitation. Specific examples of the process include a beads mill, a sand mill, a roll mill, a ball mill, a paint shaker, a Microfluidizer, a high-speed impeller, a sand grinder, a project mixer, high-pressure wet atomization, and ultrasonic dispersion. During the pulverization of the particles using a sand mill (beads mill), it is preferable that the process is performed under conditions for increasing the pulverization efficiency, for example, by using beads having a small size and increasing the filling rate of the beads. In addition, it is preferable that rough particles are removed by filtering, centrifugal separation, and the like. In addition, as the process and the disperser for dispersing the particles, a process and a disperser described in “Complete Works of Dispersion Technology, Johokiko Co., Ltd., Jul. 15, 2005”, “Dispersion Technique focusing on Suspension (Solid/Liquid Dispersion) and Practical Industrial Application, Comprehensive Reference List, Publishing Department of Management Development Center, Oct. 10, 1978”, and paragraph “0022” JP2015-157893A can be suitably used. In addition, in the process of dispersing the particles, particles may be refined in a salt milling step. A material, a device, process conditions, and the like used in the salt milling step can be found in, for example, JP2015-194521A and JP2012-046629A.

During the preparation of the composition, it is preferable that the composition is filtered through a filter, for example, in order to remove foreign matter or to reduce defects. As the filter, any filter which is used in the related art for filtering or the like can be used without any particular limitation. Examples of a material of the filter include: a fluororesin such as polytetrafluoroethylene (PTFE); a polyamide resin such as nylon (for example, nylon-6 or nylon-6,6); and a polyolefin resin (including a polyolefin resin having a high density and an ultrahigh molecular weight) such as polyethylene or polypropylene (PP). Among these materials, polypropylene (including high-density polypropylene) or nylon is preferable.

The pore size of the filter is suitably about 0.01 to 7.0 μm and is preferably about 0.01 to 3.0 μm and more preferably about 0.05 to 0.5 μm. In a case where the pore size of the filter is in the above-described range, fine foreign matter can be reliably removed. In addition, it is preferable that a fibrous filter material is used. Examples of the fibrous filter material include polypropylene fiber, nylon fiber, and glass fiber. Specific examples include a filter cartridge of SBP type series (for example, SBP008), TPR type series (for example, TPR002 or TPR005), and SHPX type series (for example, SHPX003) all of which are manufactured by Roki Techno Co., Ltd.

In a case where a filter is used, a combination of different filters (for example, a first filter and a second filter) may be used. At this time, the filtering using each of the filters may be performed once, or twice or more.

In addition, a combination of filters having different pore sizes in the above-described range may be used. Here, the pore size of the filter can refer to a nominal value of a manufacturer of the filter. A commercially available filter can be selected from various filters manufactured by Pall Corporation (for example, DFA4201NIEY), Toyo Roshi Kaisha, Ltd., Entegris Japan Co., Ltd. (former Mykrolis Corporation), or Kits Microfilter Corporation.

The second filter may be formed of the same material as that of the first filter.

In addition, the filtering using the first filter may be performed only on the dispersion, and the filtering using the second filter may be performed on a mixture of the dispersion and other components.

<Film>

Next, a film according to the embodiment of the present invention will be described. The film according to the embodiment of the present invention is formed using the above-described composition according to the embodiment of the present invention. The film according to the present invention has excellent infrared shielding properties and visible transparency, and thus can be preferably used as a near infrared cut filter. In addition, the film according to the embodiment of the present invention can also be used as a heat ray shielding filter. In addition, the film according to the embodiment of the present invention can also be used as a filter for an ambient light sensor (examples of the ambient light include sunlight and light emitted from a lighting (for example, a fluorescent lamp, a yellow lamp, an orange lamp, a red lamp, or a device for measuring the illuminance thereof), or as a band pass filter.

The film according to the embodiment of the present invention may be a film having a pattern or a film (flat film) not having a pattern. In addition, the film according to the embodiment of the present invention may be used in a state where it is laminated on a support, or the film according to the present invention may be peeled off from a support.

The thickness of the film according to the embodiment of the present invention can be adjusted according to the purpose. The thickness is preferably 20 μm or less, more preferably 10 μm or less, and still more preferably 5 μm or less. For example, the lower limit of the thickness is preferably 0.1 μm or more, more preferably 0.2 μm or more, and still more preferably 0.3 μm or more.

It is preferable that the film according to the embodiment of the present invention and a near infrared cut filter described below have an absorption maximum in a wavelength range of 650 to 1000 nm. The lower limit is preferably 670 nm or more and more preferably 700 nm or more. The upper limit is preferably 950 nm or less, more preferably 900 nm or less, still more preferably 850 nm or less, and even still more preferably 800 nm or less.

In the film according to the embodiment of the present invention and the near infrared cut filter described below, an average light transmittance in a wavelength range of 400 to 550 nm is preferably 70% or higher, more preferably 80% or higher, still more preferably 85% or higher, and even still more preferably 90% or higher. In addition, a transmittance of in the entire wavelength range of 400 to 550 nm is preferably 70% or higher, more preferably 80% or higher, and still more preferably 90% or higher.

In the film according to the embodiment of the present invention and the near infrared cut filter described below, a transmittance at at least one point in a wavelength range of 650 to 1000 nm (preferably a wavelength range of 650 to 950 nm, more preferably a wavelength range of 650 to 900 nm, still more preferably a wavelength range of 650 to 850 nm, and even still more preferably a wavelength range of 650 to 800 nm) is preferably 20% or lower, more preferably 15% or lower, and still more preferably 10% or lower.

The film according to the present invention can be used in combination with a color filter that includes a chromatic colorant. The color filter can be manufactured using a coloring composition including a chromatic colorant. Examples of the chromatic colorant include the chromatic colorants described regarding the composition according to the embodiment of the present invention. The coloring composition may further include, for example, a resin, a polymerizable compound, a photopolymerization initiator, a surfactant, an organic solvent, a polymerization inhibitor, and an ultraviolet absorber. In more detail, for example, the materials described above regarding the composition according to the embodiment of the present invention can be used. In addition, the film according to the present invention may have not only a function as a near infrared cut filter but also a function as a color filter by including a chromatic colorant.

In the present invention, “near infrared cut filter” refers to a filter that allows transmission of light (visible light) in the visible range and shields at least a part of light (near infrared light) in the near infrared range. The near infrared cut filter may be a filter that allows transmission of light in the entire wavelength range of the visible range, or may be a filter that allows transmission of light in a specific wavelength range of the visible range and shields light in another specific wavelength range of the visible range. In addition, in the present invention, a color filter refers to a filter that allows transmission of light in a specific wavelength range of the visible range and shields light in another specific wavelength range of the visible range.

The film according to the embodiment of the present invention can be used in various devices including a solid image pickup element such as a charge coupled device (CCD) or a complementary metal-oxide semiconductor (CMOS), an infrared sensor, or an image display device.

<Near Infrared Cut Filter>

In addition, a near infrared cut filter according to the embodiment of the present invention will be described. The near infrared cut filter according to the embodiment of the present invention includes the film according to the embodiment of the present invention. It is also preferable that the near infrared cut filter according to the present invention includes a pixel which is formed using the film according to the present invention and a pixel selected from the group consisting of a red pixel, a green pixel, a blue pixel, a magenta pixel, a yellow pixel, a cyan pixel, a black pixel, and an achromatic pixel.

In the near infrared cut filter according to the embodiment of the present invention, the film according to the embodiment of the present invention may be a film having a pattern or a film (flat film) not having a pattern.

In the near infrared cut filter according to the embodiment of the present invention, the film according to the embodiment of the present invention may be laminated on a support. The near infrared cut filter can be preferably used for a solid image pickup element. Examples of the support include a transparent substrate. The transparent substrate is not particularly limited as long as it is formed of a material that can allow transmission of at least visible light. Examples of the transparent substrate include glass, crystal, and a resin. Among these, glass is preferable. That is, it is preferable that the transparent substrate is a glass substrate. Examples of the glass include soda-lime glass, borosilicate glass, non-alkali glass, quartz glass, and copper-containing glass. Examples of the copper-containing glass include a phosphate glass including copper and a fluorophosphate glass including copper. Examples of a commercially available product of the copper-containing glass include NF-50 (manufactured by AGC Techno Glass Co., Ltd.), BG-60 and BG-61 (both of which are manufactured by Schott AG), and CD5000 (manufactured by Hoya Corporation). Examples of the crystal include rock crystal, lithium niobate, and sapphire. Examples of the resin include a polyester resin such as polyethylene terephthalate or polybutylene terephthalate, a polyolefin resin such as polyethylene, polypropylene, or an ethylene vinyl acetate copolymer, a norbornene resin, an acrylic resin such as polyacrylate or polymethyl methacrylate, a urethane resin, a vinyl chloride resin, a fluororesin, a polycarbonate resin, a polyvinyl butyral resin, and a polyvinyl alcohol resin. In addition, in order to improve adhesiveness between the support and the film according to the embodiment of the present invention, a underlayer or the like may be provided on a surface of the support.

In addition, in a case where the film according to the embodiment of the present invention is laminated on a glass substrate for use, it is preferable that the film according to the embodiment of the present invention is a film that is formed using a composition that includes a compound including a silane coupling agent and/or an epoxy group. According to this aspect, adhesiveness between the glass substrate and the film according to the embodiment of the present invention can be more strengthened. The near infrared cut filter according to the embodiment of the present invention can be manufactured using a well-known method of the related art. In addition, the near infrared cut filter according to the embodiment of the present invention can also be manufactured using a method described in WO2017/030174A or WO2017/018419A.

In a case where the near infrared cut filter according to the embodiment of the present invention is laminated on the support for use, it is also preferable that the near infrared cut filter further includes a dielectric multi-layer film in addition to the film according to the embodiment of the present invention. According to this aspect, a near infrared cut filter having a wide viewing angle and excellent infrared shielding properties can be obtained. The dielectric multi-layer film may be provided on a single surface or both surfaces of the transparent substrate. In a case where the dielectric multi-layer film is provided on a single surface of the transparent substrate, the manufacturing costs can be suppressed. In a case where the dielectric multi-layer film is provided on both surfaces of the transparent substrate, a near infrared cut filter having a high strength in which warping is not likely to occur can be obtained. In addition, the dielectric multi-layer film may be or may not be in contact with the transparent substrate. In the near infrared cut filter according to the embodiment of the present invention, it is preferable that the film according to the embodiment of the present invention is provided between the transparent substrate and the dielectric multi-layer film and the film according to the embodiment of the present invention and the dielectric multi-layer film are in contact with each other. With the above-described configuration, in the film according to the embodiment of the present invention, oxygen or humidity is blocked using the dielectric multi-layer film such that the light fastness or moisture resistance of the near infrared cut filter is improved. Further, an infrared cut filter having a wide viewing angle and excellent infrared shielding properties is likely to be obtained. In addition, the film according to the embodiment of the present invention has excellent durability such as heat resistance. Therefore, in a case where the dielectric multi-layer film is formed on the surface of the film according to the embodiment of the present invention, the spectral characteristics of the film itself according to the embodiment of the present invention is not likely to deteriorate. Therefore, this configuration is effective particularly in a case where the dielectric multi-layer film is provided on the surface of the film according to the embodiment of the present invention.

In the present invention, the dielectric multi-layer film is a film that shields infrared light using a light interference effect. Specifically, the dielectric multi-layer film is a film in which two or more dielectric layers (a high refractive index material layer and a low refractive index material layer) having different refractive indices are alternately laminated. As a material for forming the high refractive index material layer, a material having a refractive index of 1.7 or higher (preferably 1.7 to 2.5) is preferably used. Examples of the material include titanium oxide, zirconium oxide, tantalum pentoxide, niobium pentoxide, lanthanum oxide, yttrium oxide, zinc oxide, zinc sulfide, titanium oxide including indium oxide as a major component, and a material including a small amount of tin oxide and/or cerium oxide. As a material for forming the low refractive index material layer, a material having a refractive index of 1.6 or lower (preferably 1.2 to 1.6) is preferably used. Examples of the material include silica, alumina, lanthanum fluoride, magnesium fluoride, and sodium hexafluoroaluminate. The thickness of each of the high refractive index material layer and the low refractive index material layer is preferably 0.1λ to 0.5λ of a wavelength λ (nm) of infrared light to be shielded. In addition, the total number of the high refractive index material layers and the low refractive index material layers laminated in the dielectric multi-layer film is preferably 2 to 100, more preferably 2 to 60, and still more preferably 2 to 40. The details of the dielectric multi-layer film can be found in paragraphs “0255” to “0259” of JP2014-041318A, the content of which is incorporated herein by reference.

In a case where the near infrared cut filter according to the embodiment of the present invention includes the film according to the embodiment of the present invention, the transparent substrate, and the dielectric multi-layer film, the order of lamination of the respective layers is not particularly limited and, examples thereof include the following layer configurations (1) to (10). In the following examples, the transparent substrate is represented by “layer A”, the film according to the embodiment of the present invention is represented by “layer B”, and the dielectric multi-layer film is represented by “layer C”.
(1) Layer A/Layer B/Layer C
(2) Layer A/Layer C/Layer B
(3) Layer C/Layer A/Layer B
(4) Layer B/Layer A/Layer B/Layer C
(5) Layer C/Layer A/Layer B/Layer C
(6) Layer B/Layer A/Layer C/Layer B
(7) Layer C/Layer A/Layer C/Layer B
(8) Layer C/Layer B/Layer A/Layer B/Layer C
(9) Layer C/Layer B/Layer A/Layer C/Layer B
(10) Layer B/Layer C/Layer A/Layer C/Layer B

The near infrared cut filter according to the embodiment of the present invention may further include, for example, a layer containing copper or an ultraviolet absorbing layer in addition to the film according to the embodiment of the present invention. By further including the layer containing copper, the near infrared cut filter according to the embodiment of the present invention having a wide viewing angle and excellent infrared shielding properties can be easily obtained. In addition, by including the ultraviolet absorbing layer, the near infrared cut filter having excellent ultraviolet shielding properties can be obtained. The details of the ultraviolet absorbing layer can be found in the description of an absorbing layer described in paragraphs “0040” to “0070” and paragraphs “0119” to “0145” of WO2015/099060, the content of which is incorporated herein by reference. Examples of the layer containing copper include a layer that is formed using a composition containing a copper complex as a layer including a copper complex (copper complex-containing layer). The copper complex is preferably a compound having an absorption maximum in a wavelength range of 700 to 1200 nm. It is more preferable the absorption maximum of the copper complex is present in a wavelength range of 720 to 1200 nm, and it is still more preferable the absorption maximum of the copper complex is present in a wavelength range of 800 to 1100 nm.

<Laminate>

In addition, a laminate according to the embodiment of the present invention includes: the film according to the embodiment of the present invention; and a color filter that includes a chromatic colorant. In the laminate according to the present invention, the film according to the present invention and the color filter may be or may not be adjacent to the color filter in the thickness direction. In a case where the film according to the embodiment of the present invention is not adjacent to the color filter in the thickness direction, the film according to the embodiment of the present invention may be formed on another substrate other than a substrate on which the color filter is formed, or another member (for example, a microlens or a planarizing layer) constituting a solid image pickup element may be interposed between the film according to the embodiment of the present invention and the color filter.

<Pattern Forming Method>

Next, a pattern forming method using the composition according to the embodiment of the present invention will be described. The pattern forming method includes: a step of forming a composition layer on a support using the composition according to the present invention; and a step of forming a pattern on the composition layer using a photolithography method or a dry etching method.

In a case where a laminate in which the film according to the embodiment of the present invention and a color filter are laminated is manufactured, pattern formation on the film according to the embodiment of the present invention and pattern formation on the color filter may be separately performed. In addition, pattern formation may be performed on the laminate in which the film according to the embodiment of the present invention and the color filter are laminated (that is, pattern formation on the film according to the embodiment of the present invention and pattern formation on the color filter may be simultaneously performed).

The case where pattern formation on the film according to the embodiment of the present invention and pattern formation on the color filter are separately performed denotes the following aspect. Pattern formation is performed on any one of the film according to the embodiment of the present invention or the color filter. Next, the other filter layer is formed on the filter layer on which the pattern is formed. Next, pattern formation is performed on the filter layer on which a pattern is not formed.

A pattern forming method may be a pattern forming method using photolithography or a pattern forming method using dry etching. In the case of the pattern forming method using photolithography, a dry etching step is not necessary, and an effect that the number of steps can be reduced can be obtained. In the case of the pattern forming method using dry etching, a photolithography function is not necessary. Therefore, the concentration of the near infrared absorbing compound or the like can bee increased.

In a case where the pattern formation on the film according to the embodiment of the present invention and the pattern formation on the color filter are separately performed, the pattern formations on the respective filter layers may be performed using only the photolithography method or only the dry etching method. In addition, after performing the pattern formation on one filter layer using the photolithography method, the pattern formation may be performed on the other filter layer using the dry etching method. In a case where the pattern formation is performed using a combination of the dry etching method and the photolithography method, it is preferable that a pattern is formed on a first layer using the dry etching method and a pattern is formed on a second or subsequent layer using the photolithography method.

It is preferable that the pattern formation using the photolithography method includes: a step of forming a composition layer on a support using each composition; a step of exposing the composition layer in a pattern shape; and a step of forming a pattern by removing a non-exposed portion by development. Optionally, the pattern formation further includes: a step (pre-baking step) of baking the composition layer; and a step (post-baking step) of baking the developed pattern.

In addition, It is preferable that the pattern forming method using the dry etching method includes: a step of forming a composition layer on a support using each composition and curing the composition layer to form a cured composition layer; a step of forming a photoresist layer on the cured composition layer; a step of obtaining a resist pattern by patterning the photoresist layer by exposure and development; and a step of forming a pattern by dry-etching the cured composition layer by using the resist pattern as an etching mask. Hereinafter, the respective steps will be described.

<<Step of Forming Composition Layer>>

In the step of forming a composition layer, a composition layer is formed on a support using each of the compositions.

Examples of the support include the above-described transparent substrate. In addition, as the support, for example, a substrate for a solid image pickup element obtained by providing a solid image pickup element (light-receiving element) such as CCD or CMOS on a semiconductor substrate (for example, a silicon substrate) can be used. In a case where the substrate for a solid image pickup element is used, the pattern may be formed on a solid image pickup element-formed surface (front surface) of the substrate for a solid image pickup element, or may be formed on a solid image pickup element non-formed surface (back surface) thereof. Optionally, an undercoat layer may be provided on the support to improve adhesion with a layer above the support, to prevent diffusion of materials, or to make a surface of the substrate flat.

As a method of applying the composition to the support, a well-known method can be used. Examples of the well-known method include: a drop casting method; a slit coating method; a spray coating method; a roll coating method; a spin coating method; a cast coating method; a slit and spin method; a pre-wetting method (for example, a method described in JP2009-145395A); various printing methods including jet printing such as an ink jet method (for example, an on-demand method, a piezoelectric method, or a thermal method) or a nozzle jet method, flexographic printing, screen printing, gravure printing, reverse offset printing, and metal mask printing; a transfer method using metal or the like; and a nanoimprint lithography method. The application method using an ink jet method is not particularly limited, and examples thereof include a method (in particular, pp. 115 to 133) described in “Extension of Use of Ink Jet—Infinite Possibilities in Patent—” (February, 2005, S.B. Research Co., Ltd.) and methods described in JP2003-262716A, JP2003-185831A, JP2003-261827A, JP2012-126830A, and JP2006-169325A.

The composition layer formed on the support may be dried (pre-baked). In a case where a pattern is formed through a low-temperature process, pre-baking is not necessarily performed.

In a case where pre-baking is performed, the pre-baking temperature is preferably 150° C. or lower, more preferably 120° C. or lower, and still more preferably 110° C. or lower. The lower limit is, for example, 50° C. or higher or 80° C. or higher. By setting the pre-baking temperature to be 150° C. or lower, the characteristics can be effectively maintained, for example, even in a case where a photoelectric conversion film of an image sensor is formed of an organic material.

In addition, in a case where a glass substrate having a thickness of 200 μm or less is used as the support, in order to suppress the warping of the support, the upper limit of the pre-baking temperature is preferably 120° C. or lower, more preferably 110° C. or lower, and still more preferably 100° C. or lower.

The pre-baking time is preferably 10 to 3000 seconds, more preferably 40 to 2500 seconds, and still more preferably 80 to 220 seconds. Drying can be performed using a hot plate, an oven, or the like.

(Case where Pattern is Formed Using Photolithography Method)

<<Exposure Step>>

Next, the composition layer is exposed in a pattern shape (exposure step). For example, the composition layer is exposed in a pattern shape using an exposure device such as a stepper through a mask having a predetermined mask pattern, thereby exposing a pattern. As a result, an exposed portion can be cured.

As radiation (light) used during the exposure, in particular, ultraviolet rays such as g-rays or i-rays are preferable, and i-rays are more preferable. The irradiation dose (exposure dose) is preferably 0.03 to 2.5 J/cm², more preferably 0.05 to 1.0 J/cm², and most preferably 0.08 to 0.5 J/cm².

The oxygen concentration during exposure can be appropriately selected. The exposure may be performed not only in air but also in a low-oxygen atmosphere having an oxygen concentration of 19 vol % or lower (for example, 15 vol %, 5 vol %, or substantially 0 vol %) or in a high-oxygen atmosphere having an oxygen concentration of higher than 21 vol % (for example, 22 vol %, 30 vol %, or 50 vol %). In addition, the exposure illuminance can be appropriately set and typically can be selected in a range of 1000 W/m² to 100000 W/m² (for example, 5000 W/m², 15000 W/m², or 35000 W/m²). Conditions of the oxygen concentration and conditions of the exposure illuminance may be appropriately combined. For example, conditions are oxygen concentration: 10 vol % and illuminance: 10000 W/m², or oxygen concentration: 35 vol % and illuminance: 20000 W/m².

<<Development Step>>

Next, a pattern is formed by removing a non-exposed portion by development. The non-exposed portion can be removed by development using a developer. As a result, a non-exposed portion of the composition layer in the exposure step is eluted into the developer, and only the photocured portion remains on the support.

As the developer, an alkali developer which does not cause damages to a solid image pickup element as a substrate, a circuit or the like is desired.

For example, the temperature of the developer is preferably 20° C. to 30° C. The development time is preferably 20 to 180 seconds. In addition, in order to further improve residue removing properties, a step of shaking the developer off per 60 seconds and supplying a new developer may be repeated multiple times.

Examples of the alkaline agent used as the developer include: an organic alkaline compound such as ammonia water, ethylamine, diethylamine, dimethylethanolamine, diglycolamine, diethanolamine, hydroxyamine, ethylenediamine, tetramethylammonium hydroxide, tetraethylammonium hydroxide, tetrapropylammonium hydroxide, tetrabutylammonium hydroxide, benzyltrimethylammonium hydroxide, dimethyl bis(2-hydroxyethyl)ammonium hydroxide, choline, pyrrole, piperidine, or 1,8-diazabicyclo[5.4.0]-7-undecene; and an inorganic alkaline compound such as sodium hydroxide, potassium hydroxide, sodium carbonate, sodium bicarbonate, sodium silicate, or sodium metasilicate. As the developer, an alkaline aqueous solution in which the above alkaline agent is diluted with pure water is preferably used. A concentration of the alkaline agent in the alkaline aqueous solution is preferably 0.001 to 10 mass % and more preferably 0.01 to 1 mass %. In addition, a surfactant may be used as the developer. Examples of the surfactant include the surfactants described above regarding the composition. Among these, a nonionic surfactant is preferable. In a case where a developer including the alkaline aqueous solution is used, it is preferable that the layer is rinsed with pure water after development.

After the development, it is preferable that the film is dried and then heated (post-baking). Post-baking is a heat treatment which is performed after development to completely cure the film. In a case where post-baking is performed, for example, the post-baking temperature is preferably 100° C. to 240° C. From the viewpoint of curing the film, the post-baking temperature is more preferably 200° C. to 230° C. In addition, in a case where an organic electroluminescence (organic EL) element is used as a light-emitting light source, or in a case where a photoelectric conversion film of an image sensor is formed of an organic material, the post-baking temperature is preferably 150° C. or lower, more preferably 120° C. or lower, still more preferably 100° C. or lower, and even still more preferably 90° C. or lower. The lower limit is, for example, 50° C. or higher. The film after the development is post-baked continuously or batchwise using heating means such as a hot plate, a convection oven (hot air circulation dryer), a high-frequency heater under the above-described conditions. In addition, in a case where a pattern is formed through a low-temperature process, post-baking is not necessarily performed.

(Case where Pattern is Formed Using Dry Etching Method)

The pattern formation using the dry etching method can be performed by curing the composition layer formed on the support to form a cured composition layer, and then etching the cured composition layer with etching gas by using a patterned photoresist layer as a mask. It is preferable that pre-baking is further performed in order to form the photoresist layer. In particular, in a preferable aspect, as a process of forming the photoresist layer, baking after exposure or baking after development (post-baking) is performed. The details of the pattern formation using the dry etching method can be found in paragraphs “0010” to “0067” of JP2013-064993A, the content of which is incorporated herein by reference.

<Solid Image Pickup Element and Camera Module>

A solid image pickup element according to the embodiment of the present invention includes the film according to the embodiment of the present invention. In addition, a camera module according to the embodiment of the present invention includes the film according to the embodiment of the present invention. The solid image pickup element and the camera module according to the present invention are not particularly limited as long as they includes the film according to the embodiment of the present invention and they function as a solid image pickup element and a camera module. For example, the following configuration can be adopted.

The solid image pickup element includes plural photodiodes and transfers electrodes on the support, the photodiodes constituting a light receiving area of the solid image pickup element, and the transfer electrode being formed of polysilicon or the like. In the solid image pickup element, a light shielding film formed of tungsten or the like which has openings through only light receiving sections of the photodiodes is provided on the photodiodes and the transfer electrodes, a device protective film formed of silicon nitride or the like is formed on the light shielding film so as to cover the entire surface of the light shielding film and the light receiving sections of the photodiodes, and the film according to the embodiment of the present invention is formed on the device protective film. Further, a configuration in which light collecting means (for example, a microlens; hereinafter, the same shall be applied) is provided above the device protective film and below the film according to the present invention (on a side thereof close the support), or a configuration in which light collecting means is provided on the film according to the present invention may be adopted. In addition, the color filter may have a structure in which a cured film which forms each color pixel is embedded in a space which is partitioned in, for example, a lattice shape by a partition wall. In this case, it is preferable that the partition wall has a low refractive index with respect to each color pixel. Examples of an imaging device having such a structure include a device described in JP2012-227478A and JP2014-179577A.

<Image Display Device>

The film according to the embodiment of the present invention can also be used in an image display device such as a liquid crystal display device or an organic electroluminescence (organic EL) display device. For example, the film according to the embodiment of the present invention can be used for the purpose of shielding infrared light included in light emitted from a backlight (for example, a white light emitting diode (white LED)) of an image display device to prevent a malfunction of a peripheral device, or for the purpose of forming an infrared pixel in addition to the respective color display pixels.

The definition and details of the image display device can be found in, for example, “Electronic Display Device (by Akiya Sasaki, Kogyo Chosakai Publishing Co., Ltd., 1990)” or “Display Device (Sumiaki Ibuki, Sangyo Tosho Co., Ltd.). In addition, the details of a liquid crystal display device can be found in, for example, “Next-Generation Liquid Crystal Display Techniques (Edited by Tatsuo Uchida, Kogyo Chosakai Publishing Co., Ltd., 1994)”. The liquid crystal display device to which the present invention is applicable is not particularly limited. For example, the present invention is applicable to various liquid crystal display devices described in “Next-Generation Liquid Crystal Display Techniques”.

The image display device may include a white organic EL element. It is preferable that the white organic EL element has a tandem structure. The tandem structure of the organic EL element is described in, for example, JP2003-045676A, or pp. 326-328 of “Forefront of Organic EL Technology Development-Know-How Collection of High Brightness, High Precision, and Long Life” (Technical Information Institute, 2008). It is preferable that a spectrum of white light emitted from the organic EL element has high maximum emission peaks in a blue range (430 nm to 485 nm), a green range (530 nm to 580 nm), and a yellow range (580 nm to 620 nm). It is more preferable that the spectrum has a maximum emission peak in a red range (650 nm to 700 nm) in addition to the above-described emission peaks.

<Infrared Sensor>

An infrared sensor according to the embodiment of the present invention includes the film according to the embodiment of the present invention. The configuration of the infrared sensor according to the embodiment of the present invention is not particularly limited as long as it includes the film according to the embodiment of the present invention and functions as an infrared sensor.

Hereinafter, an embodiment of the infrared sensor according to the embodiment of the present invention will be described using the drawings.

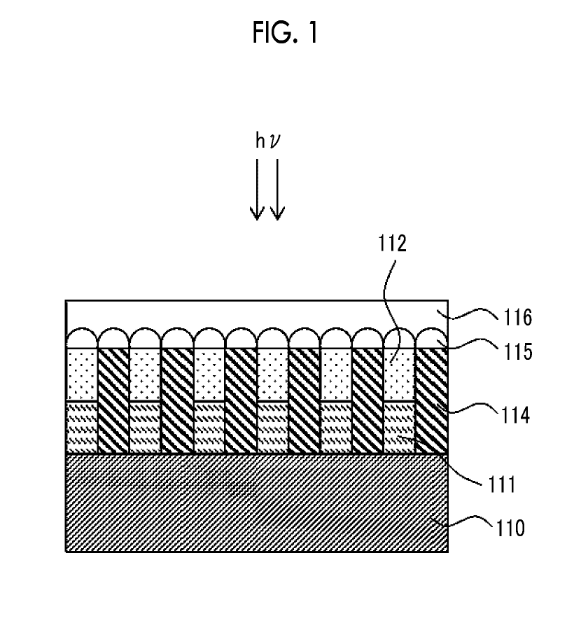

In FIG. 1, reference numeral 110 represents a solid image pickup element. In an imaging region provided on a solid image pickup element 110, near infrared cut filters 111 and infrared transmitting filters 114 are provided. In addition, color filters 112 are laminated on the near infrared cut filters 111. Microlenses 115 are disposed on an incidence ray hν side of the color filters 112 and the infrared transmitting filters 114. A planarizing layer 116 is formed so as to cover the microlenses 115.

The near infrared cut filters 111 are filters that allow transmission of light in a visible range and shield light in a near infrared range. Spectral characteristics of the near infrared cut filters 111 can be selected depending on the emission wavelength of an infrared light emitting diode (infrared LED) to be used. The near infrared cut filter 111 can be formed using the composition according to the embodiment of the present invention.

The color filters 112 is not particularly limited as long as pixels which allow transmission of light having a specific wavelength in the visible range and absorbs the light are formed therein, and well-known color filters of the related art for forming a pixel can be used. For example, pixels of red (R), green (G), and blue (B) are formed in the color filters. For example, the details of the color filters can be found in paragraphs “0214” to “0263” of JP2014-043556A, the content of which is incorporated herein by reference.

Characteristics of the infrared transmitting filters 114 can be selected depending on the emission wavelength of the infrared LED to be used. For example, in a case where the emission wavelength of the infrared LED is 850 nm, a maximum value of a light transmittance of the infrared transmitting filter 114 in the thickness direction of the film in a wavelength range of 400 to 650 nm is preferably 30% or lower, more preferably 20% or lower, still more preferably 10% or lower and even still more preferably 0.1% or lower. It is preferable that the transmittance satisfies the above-described conditions in the entire wavelength range of 400 to 650 nm. The maximum value of the light transmittance in a wavelength range of 400 to 650 nm is typically 0.1% or higher.

A minimum value of a light transmittance of the infrared transmitting filter 114 in the thickness direction of the film in a wavelength range of 800 nm or longer (preferably 800 to 1300 nm) is preferably 70% or higher, more preferably 80% or higher, and still more preferably 90% or higher. It is preferable that the transmittance satisfies the above-described conditions in at least a part of a wavelength range of 800 nm or longer, and it is more preferable that the transmittance satisfies the above-described conditions at a wavelength corresponding to the emission wavelength of the infrared LED. The minimum value of the light transmittance in a wavelength range of 900 to 1300 nm is typically 99.9% or lower.

The thickness of the infrared transmitting filter 114 is preferably 100 μm or less, more preferably 15 μm or less, still more preferably 5 μm or less, and even still more preferably 1 μm or less. The lower limit value is preferably 0.1 In a case where the thickness is in the above-described range, the film can satisfy the above-described spectral characteristics.

A method of measuring the spectral characteristics, the thickness, and the like of the infrared transmitting filter 114 is as follows.

The thickness is obtained by measuring the thickness of the dried substrate including the film using a stylus surface profilometer (DEKTAK 150, manufactured by ULVAC Inc.).

The spectral characteristics of the film are values obtained by measuring the transmittance in a wavelength range of 300 to 1300 nm using an ultraviolet-visible-near infrared spectrophotometer (U-4100, manufactured by Hitachi High-Technologies Corporation).

In addition, for example, in a case where the emission wavelength of the infrared LED is 940 nm, it is preferable that a maximum value of a light transmittance of the infrared transmitting filter 114 in a thickness direction in a wavelength range of 450 to 650 nm is 20% or lower, that a light transmittance of the infrared transmitting filter 114 in the thickness direction at a wavelength of 835 nm is 20% or lower, and that a minimum value of a light transmittance of the infrared transmitting filter 114 in the thickness direction in a wavelength range of 1000 to 1300 nm is 70% or higher.

### EXAMPLES

Hereinafter, the present invention will be described in detail using examples. Materials, used amounts, ratios, treatment details, treatment procedures, and the like shown in the following examples can be appropriately changed within a range not departing from the scope of the present invention. Accordingly, the scope of the present invention is not limited to the following specific examples. Unless specified otherwise, “part(s)” and “%” represent “part(s) by mass” and “mass %”.

### Synthesis Example 1

(Synthesis of Near Infrared Absorbing Compound A-7)

A near infrared absorbing compound A-7 was synthesized according to the following scheme.

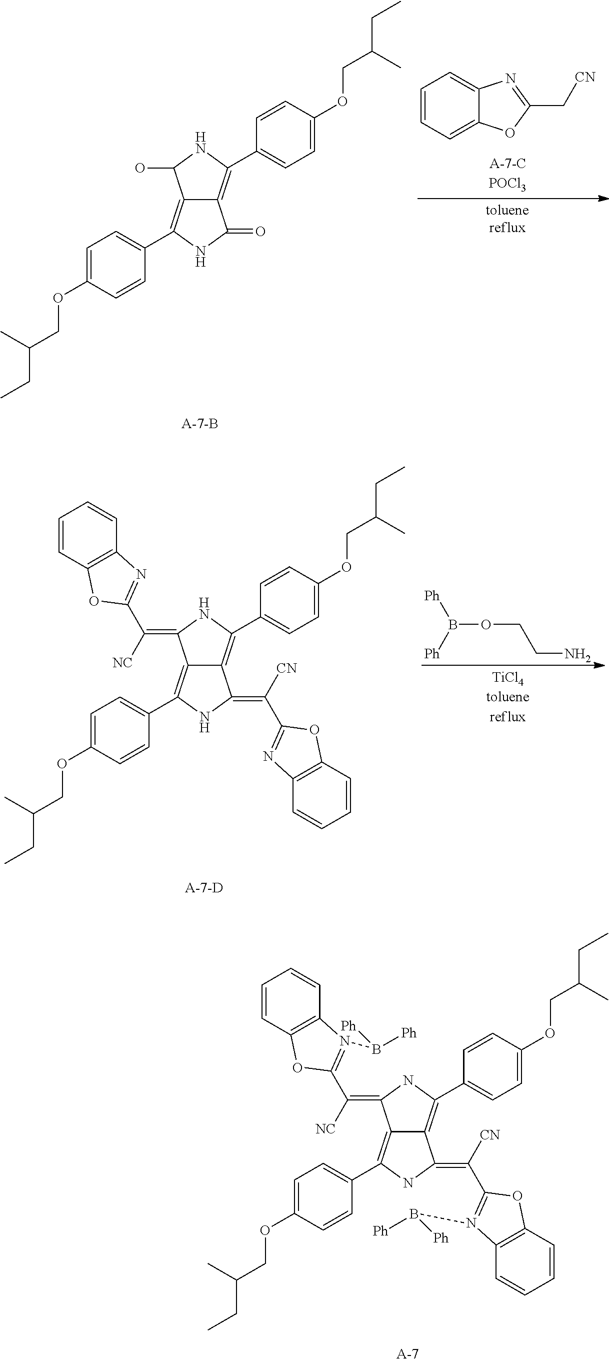

[Synthesis of Compound A-7-D] 120 parts by mass of a compound A-7-B and 198 parts by mass of a compound A-7-C were suspended in 1350 mL of toluene, and 240 parts by mass of phosphorus oxychloride was added dropwise at 90° C. to 100° C. This reaction solution was stirred for 2 hours while being heated to reflux, and was cooled to 30° C. or lower. This reaction solution was added dropwise to 1350 mL of methanol under ice cooling such that the internal temperature was 20° C. to 30° C., and was stirred at 20° C. to 30° C. for 30 minutes. This reaction solution was filtered, and the filtrate was cleaned with 670 mL of methanol. As a result, 77.5 parts by mass of a compound A-7-D was obtained.

¹H-NMR (400 MHz, CDCl₃) δ 0.96-1.03 (t, 6H, J=7.5 Hz), 1.04-1.10 (d, 6H, J=6.7 Hz), 1.29-1.41 (m, 2H), 1.56-1.71 (m, 2H), 1.83-2.06 (m, 2H), 3.82-4.01 (m, 4H), 7.09-7.20 (m, 4H), 7.26-7.37 (m, 4H), 7.46-7.56 (m, 2H), 7.56-7.65 (m, 2H), 7.70-7.80 (m, 4H), 12.4 (s, 2H)

[Synthesis of Near Infrared Absorbing Compound A-7]

100 parts by mass of the compound A-7-D and 76 parts by mass of 2-aminoethyl diphenylborinate were suspended in 1600 mL of toluene, and 61.5 parts by mass of titanium tetrachloride was added dropwise at 20° C. to 40° C. This reaction solution was stirred at 40° C. for 30 minutes and was stirred for 3 hours while being heated to reflux. This reaction solution was cooled to 30° C., was added dropwise to 800 mL of methanol under ice cooling such that the internal temperature was 20° C. to 30° C., and was stirred at 20° C. to 30° C. for 30 minutes. This reaction solution was filtered, and the filtrate was cleaned with 800 mL of methanol. As a result, 143 parts by mass of a near infrared absorbing compound A-7 was obtained.

¹H-NMR (400 MHz, CDCl₃) δ 0.94-1.05 (t, 6H, J=7.5 Hz), 1.00-1.05 (d, 6H, J=6.8 Hz), 1.56-2.27 (m, 6H), 3.60-3.84 (m, 4H), 6.37-6.52 (m, 6H), 6.61-6.70 (m, 4H), 6.97-7.04 (m, 2H), 7.06-7.39 (m, 24H)

### Synthesis Example 2

(Synthesis of Near Infrared Absorbing Compound A-9)

A compound A-9 was synthesized according to the following scheme.

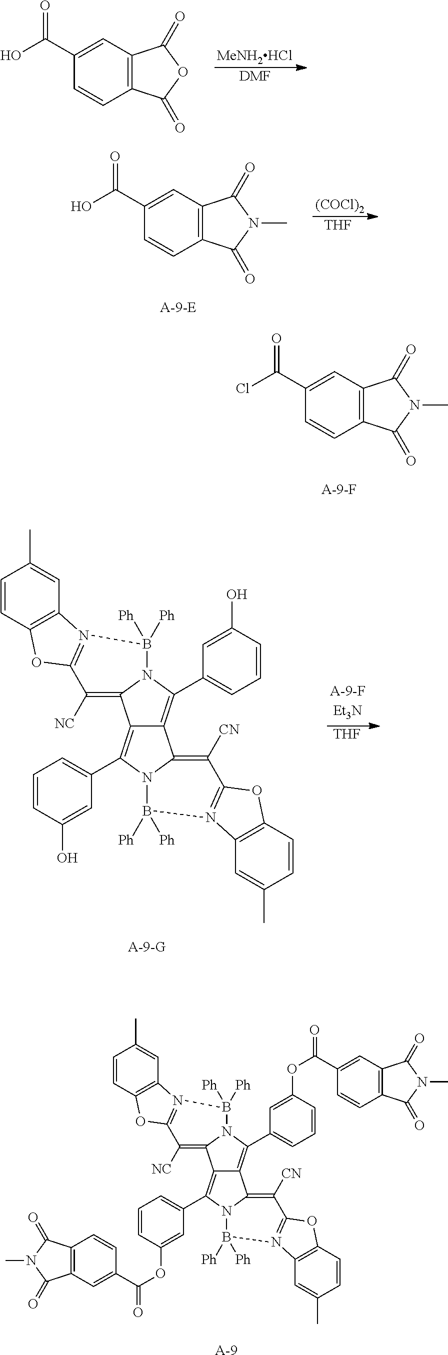

[Synthesis of Compound A-9-E]

100 parts by mass of trimellitic anhydride was dissolved in 700 parts by mass of dimethylformamide (DMF), and 38.7 parts by mass of methylamine hydrochloride was added dropwise under ice cooling such that the internal temperature was 30° C. or lower. This reaction solution was stirred at 20° C. to 30° C. for 20 minutes, was heated to 155° C., and was heated to reflux for 3 hours. This reaction solution was allowed to cool to 30° C., 350 mL of ethyl acetate and 350 mL of distilled water were added, and 200 mL of 1 mol/L hydrochloric acid water was added dropwise under ice cooling such that the internal temperature was 30° C. or lower. After stirring the solution at 20° C. to 30° C. for 30 minutes, a liquid separation operation was performed, the water layer was wasted, magnesium sulfate was added to the organic layer, and the organic layer was stirred at 20° C. to 30° C. for 10 minutes. This organic layer was filtered, and the filtrate was concentrated under a reduced pressure at 60° C. As a result 69.2 parts by mass of a compound A-9-E was obtained.

¹H-NMR (400 MHz, CDCl₃) δ 3.22 (s, 3H), 7.88-7.98 (m, 1H), 8.47-8.51 (m, 1H), 8.55 (s, 1H)

[Synthesis of Compound A-9-F]

20 parts by mass of the compound A-9-E was dissolved in 80 parts by mass of tetrahydrofuran (THF), and 18.6 parts by mass of oxalyl chloride and 0.09 parts by mass of DMF were added dropwise under ice cooling such that the internal temperature was 30° C. or lower. This reaction solution was stirred at 40° C. for 60 minutes and then was concentrated under a reduced pressure at 40° C. As a result, 21.7 parts by mass of a compound A-9-F was obtained.

[Synthesis of Near Infrared Absorbing Compound A-9]

2.0 parts by mass of a compound A-9-G was dissolved in 40 mL of THF, and 2.6 parts by mass of triethylamine and 4.0 parts by mass of the compound A-9-F were added dropwise under ice cooling such that the internal temperature was 30° C. or lower. This reaction solution was stirred at 20° C. to 30° C. for 1 hour and was stirred for 1 hour while being heated to reflux. This reaction solution was filtered, and the filtrate was cleaned with 100 mL of THF. This filtrate was suspended in 100 mL of methanol, was stirred for 30 minutes while being heated to reflux, and was cooled to 30° C. This reaction solution was filtered. The filtrate was cleaned with 100 mL of methanol. As a result, 2.1 parts by mass of a near infrared absorbing compound A-9 was obtained.

¹H-NMR (400 MHz, CDCl₃) δ 2.15-2.27 (s, 6H), 3.19-3.36 (m, 6H), 6.52-6.84 (m, 6H), 6.88-7.49 (m, 28H), 7.93-8.08 (m, 211), 8.42-8.68 (m, 4H)

<Synthesis of Pigment Derivatives B-9 and B-10>

Pigment derivatives B-9 and B-10 were synthesized using the same method as in the synthesis example of the near infrared absorbing compound A-9. A compound B-9-E used as an intermediate of the pigment derivatives B-9 and B-10 was synthesized as follows.

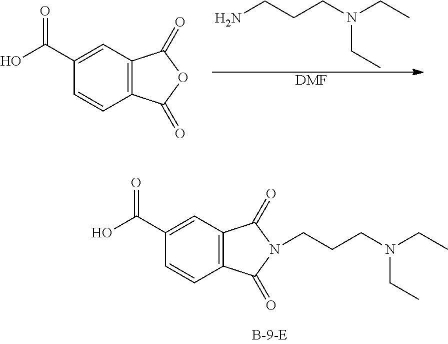

60 parts by mass of trimellitic anhydride was dissolved in 420 parts by mass of DMF, and 42.7 parts by mass of 3-diethylaminopropylamine was added dropwise under ice cooling such that the internal temperature was 30° C. or lower. This reaction solution was stirred at 20° C. to 30° C. for 20 minutes, was heated to 155° C., and was heated to reflux for 3 hours. This reaction solution was allowed to cool to 30° C., 420 mL of ethyl acetate was added, and the reaction solution was stirred at 20° C. to 30° C. for 20 minutes. This reaction solution was filtered, and the filtrate was cleaned with 420 mL of ethyl acetate. As a result, 90 parts by mass of a compound B-9-E was obtained.

¹H-NMR (400 MHz, D₂O) δ 1.22 (t, 6H), 1.98-2.12 (m, 2H), 3.11-3.25 (m, 6H), 3.71 (t, 2H), 7.77-7.82 (m, 1H), 8.10 (s, 1H), 8.13-8.18 (m, 1H)

<Measurement of Solubility of Near Infrared Absorbing Compound>

Under the atmospheric pressure, about 100 mg (a precisely weighed value is represented by X mg) of the near infrared absorbing compound is added to 1 L of propylene glycol methyl ether acetate at 25° C., and the components are stirred for 30 minutes. Next, the solution is left to stand for 5 minutes and then is filtered, and the filtrate is dried under reduced pressure at 80° C. for 2 hours is precisely weighed (a precisely weighed value is represented by Y mg). The solubility of the near infrared absorbing compound dissolved in propylene glycol methyl ether acetate is calculated from the following expression.

Solubility (mg/L)=X−Y

<Measurement of Absorption Maximum of Near Infrared Absorbing Compound>

A near infrared absorbing compound shown in the following tables was dissolved in a measurement solvent shown in the following tables to prepare a sample solution. Using a spectrophotometer U-4100 (manufactured by Hitachi High-Technologies Corporation), an absorbance of the sample solution in a wavelength range of 300 to 1300 nm was measured to obtain an absorption maximum.

TABLE 1

| Near Infrared | | Absorption | Measurement Solvent |
|---|---|---|---|
| Absorbing | | Maximum | for Absorption |
| Compound | Solubility [mg/L] | [nm] | Maximum |
| A-1 | 0.12 | 717 | Chloroform |
| A-2 | 0.64 | 765 | Methylene Chloride |
| A-3 | 0.33 | 775 | Chloroform |
| A-4 | 5.82 | 740 | Dimethylformamide |
| A-5 | 22.4 | 794 | Chloroform |
| A-6 | 15.5 | 744 | Chloroform |
| A-7 | 0.13 | 740 | Chloroform |
| AR-1 | 100 | 780 | Chloroform |
| AR-2 | 100 | 750 | Chloroform |
| AR-3 | 100 | 808 | Chloroform |
| AR-4 | 32.1 | 765 | Chloroform |
| AR-5 | 0.00 | 700 | Chloroform |
| A-8 | 0.03 | 750 | Chloroform |
| A-9 | 1.63 | 750 | Chloroform |
| A-10 | 0.05 | 745 | Chloroform |
| A-11 | 12.4 | 740 | Chloroform |
| A-12 | 1.27 | 869 | Chloroform |
| A-13 | 0.08 | 746 | Chloroform |
| A-14 | 0.01 | 750 | Chloroform |
| A-15 | 14.4 | 748 | Chloroform |
| A-16 | 22.3 | 740 | Chloroform |
| A-17 | 0.57 | 732 | Chloroform |
| A-18 | 2.05 | 726 | Chloroform |
| A-19 | 1.25 | 726 | Chloroform |
| A-20 | 0.02 | 718 | Chloroform |
| A-21 | 5.47 | 710 | Chloroform |
| A-22 | 0.03 | 757 | Chloroform |
| A-23 | 5.62 | 708 | Chloroform |
| A-24 | 7.88 | 711 | Chloroform |
| A-25 | 2.51 | 680 | Chloroform |
| A-26 | 11.2 | 665 | Chloroform |
| A-27 | 6.74 | 810 | Chloroform |
| A-28 | 1.92 | 737 | Chloroform |
| A-29 | 0.57 | 810 | Chloroform |
| A-30 | 3.58 | 737 | Chloroform |
| A-31 | 7.69 | 823 | Chloroform |
| A-32 | 0.42 | 705 | Chloroform |
| A-33 | 10.7 | 709 | Chloroform |
| A-34 | 7.72 | 680 | Chloroform |
| A-35 | 5.11 | 700 | Chloroform |
| A-36 | 4.29 | 715 | Chloroform |
| A-37 | 0.65 | 675 | Chloroform |
| A-38 | 0.88 | 750 | Chloroform |
| A-39 | 2.68 | 698 | Chloroform |
| A-40 | 11.2 | 706 | Chloroform |
| A-41 | 0.94 | 710 | Chloroform |
| A-42 | 0.33 | 703 | Chloroform |
| A-43 | 2.22 | 848 | Chloroform |
| A-44 | 11.3 | 854 | Chloroform |
| A-45 | 11.6 | 724 | Chloroform |
| A-46 | 13.9 | 782 | Chloroform |
| A-47 | 15.2 | 740 | Tetrahydrofuran |
| A-48 | 10.1 | 798 | Methylene Chloride |
| A-49 | 6.4 | 752 | Methylene Chloride |
| A-50 | 29.4 | 725 | Methylene Chloride |
| A-51 | 28.3 | 751 | Chloroform |
| A-52 | 27.5 | 762 | Chloroform |

A-1 to A-7 and AR-2 to AR-5: compounds having the following structures. In AR-2, a wave line of R¹ represents a direct bond. Four R¹'s represent “—H”. In AR-5, a wave line of R² represents a direct bond. Eight R²'s represent “—Cl”.

A-8 to A-52: Compounds A-8 to A-52 described in the specific examples of the near infrared absorbing compound

AR-1: 4,5-octakis(phenylthio)-3,6-{tetrakis(2,6-dimethylphenoxy)-tetrakis(n-hexyamino)}copper phthalocyanine ((A-1) described in paragraph “0092” of JP2010-160380A)

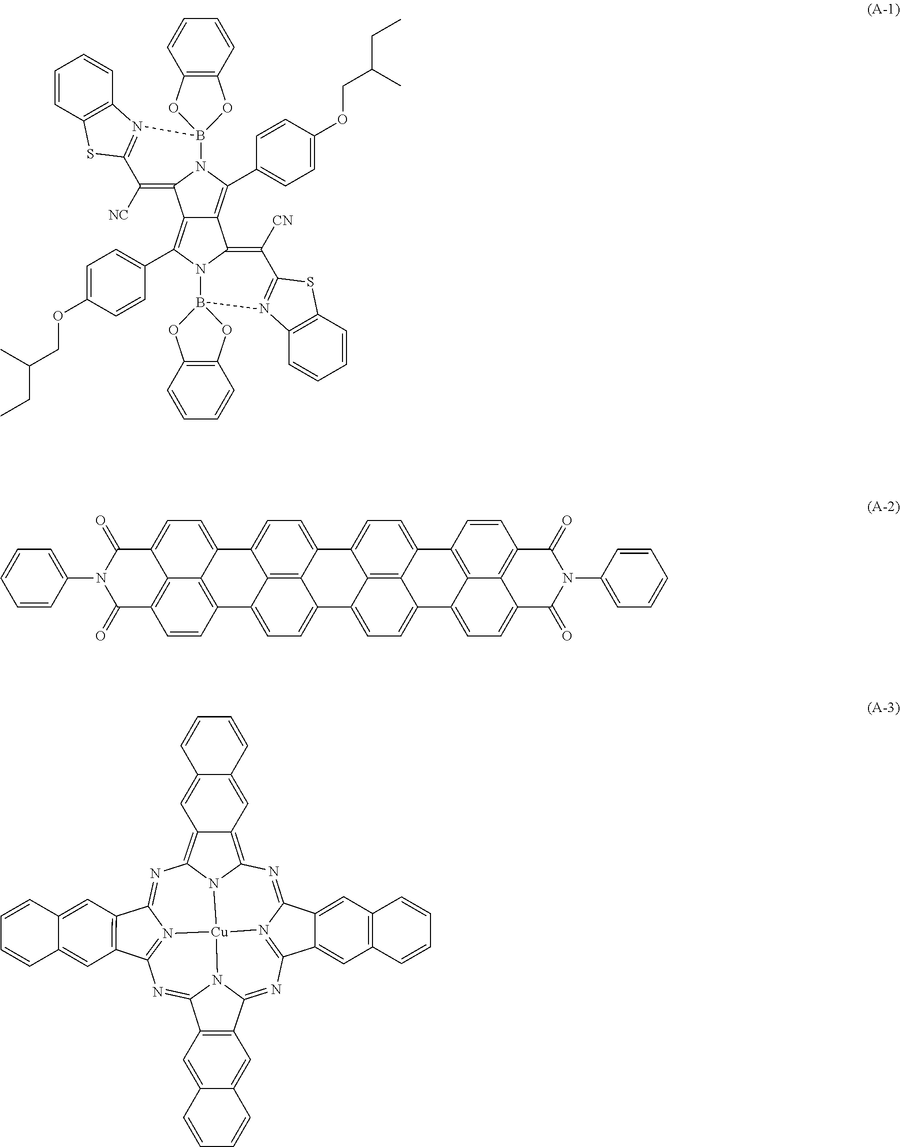

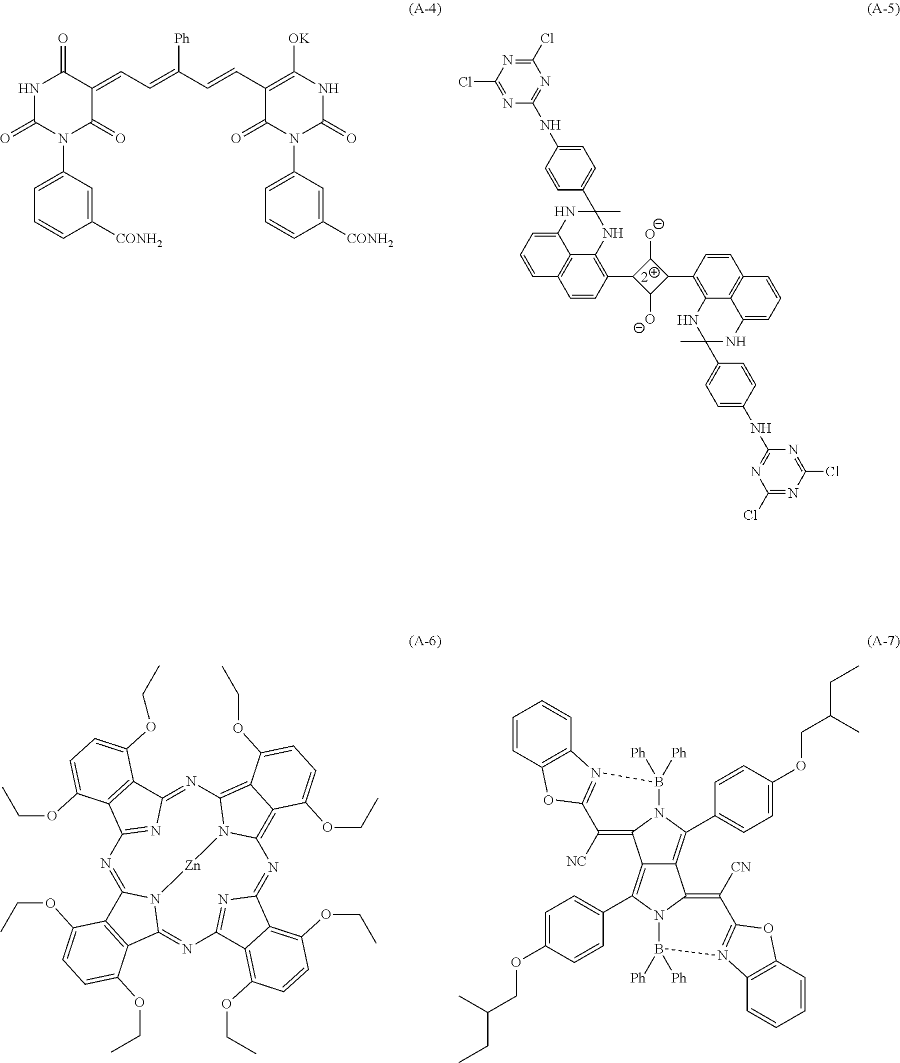

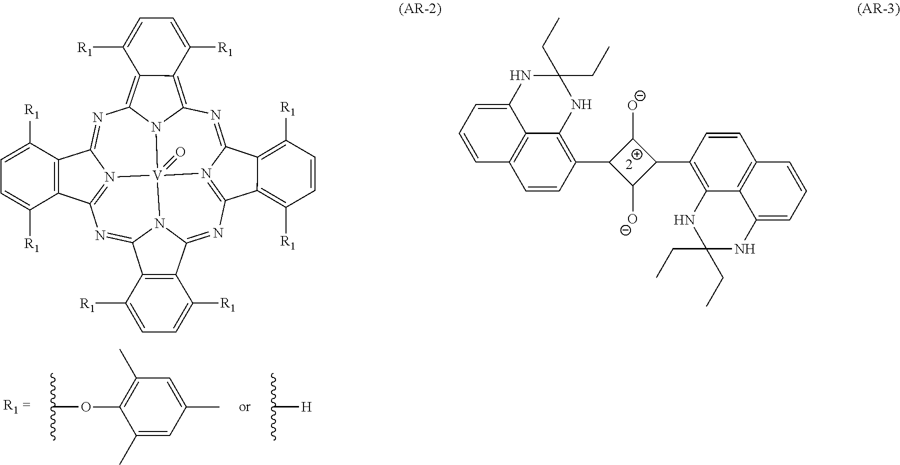

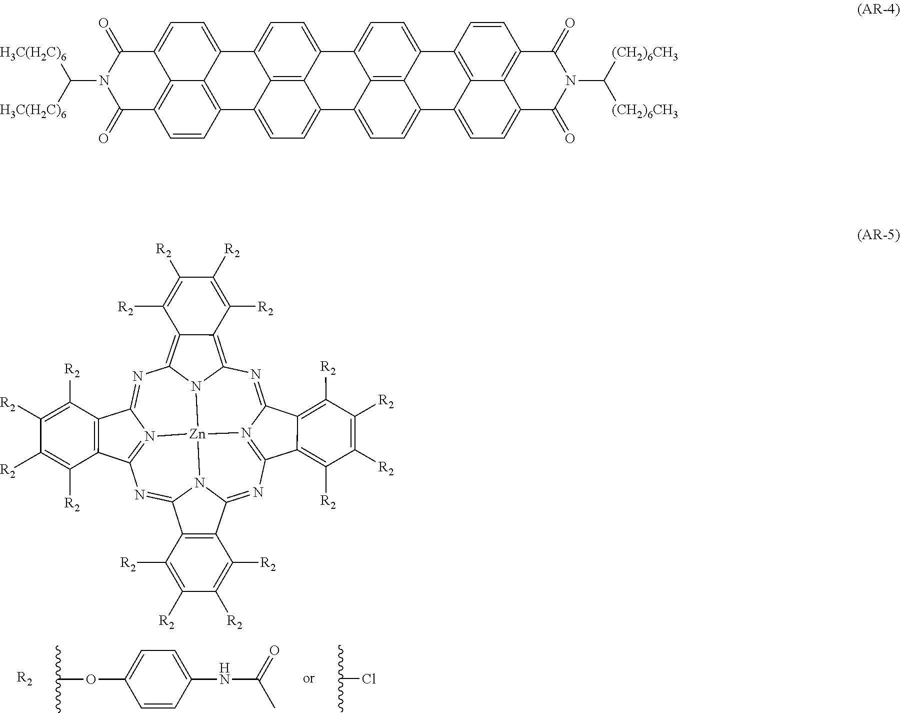

<Preparation of Dispersion>

10 parts by mass of a near infrared absorbing compound shown in the following tables, 3 parts by mass of a pigment derivative shown in the following tables, 7.8 parts by mass of a dispersant shown in the following tables, 150 parts by mass of propylene glycol methyl ether acetate (PGMEA), and 230 parts by mass of zirconia beads having a diameter of 0.3 mm were dispersed using a paint shaker for 5 hours, and the beads were separated by filtration. As a result, a dispersion was manufactured.

In a dispersion 8, as a near infrared absorbing compound, a mixture obtained by mixing A-1 and A-2 at a mass ratio A-1/A-2 of 1/5 was used. In addition, in a dispersion 9, as a near infrared absorbing compound, a mixture obtained by mixing A-4 and A-5 at a mass ratio A-4/A-5 of 3/1 was used. In addition, in a dispersion 69, as a near infrared absorbing compound, a mixture obtained by mixing A-8 and A-9 at a mass ratio A-8/A-9 of 1/2 was used. In addition, in a dispersion 70, as a near infrared absorbing compound, a mixture obtained by mixing A-9 and A-18 at a mass ratio A-9/A-18 of 1/4 was used. In addition, in a dispersion 71, as a near infrared absorbing compound, a mixture obtained by mixing A-9 and A-23 at a mass ratio A-9/A-23 of 3/1 was used. In addition, in a dispersion 72, as a near infrared absorbing compound, a mixture obtained by mixing A-32 and A-38 at a mass ratio A-32/A-38 of 1/1 was used.

<Evaluation of Dispersibility>

Using the following method, a viscosity of the dispersion and an average particle size of the near infrared absorbing compound in the dispersion were measured to evaluate dispersibility. In each of the dispersions 10 to 12, the near infrared absorbing compound was dissolved in the solvent, and thus the dispersibility was not evaluated.

(Viscosity)

Using an E-type viscometer, the viscosity of the dispersion at 25° C. was measured at a rotation speed of 1000 rpm and was evaluated based on the following criteria.

A: 1 mPa·s to 15 mPa·s

B: higher than 15 mPa·s and 30 mPa·s or lower

C: higher than 30 mPa·s and 100 mPa·s or lower

D: higher than 100 mPa·s

The volume average particle size of the near infrared absorbing compound in the dispersion was measured using MICROTRAC UPA 150 (manufactured by Nikkiso Co., Ltd.).

A: the average particle size of the near infrared absorbing compound was 5 nm to 50

B: the average particle size of the near infrared absorbing compound was more than 50 nm and 100 nm or less

C: the average particle size of the near infrared absorbing compound was more than 100 nm and 500 nm or less

D: the average particle size of the near infrared absorbing compound was more than 500 nm

TABLE 2

| | Near Infrared | | | Dispersibility | |
|---|---|---|---|---|---|
| | Absorbing | Pigment | | | Average Particle |
| | Compound | Derivative | Dispersant | Viscosity | Size |
| Dispersion 1 | A-1 | B-1 | D-2 | A | A |
| Dispersion 2 | A-2 | B-1 | D-2 | A | A |
| Dispersion 3 | A-3 | B-2 | D-1 | A | A |
| Dispersion 4 | A-4 | B-2 | D-1 | A | A |
| Dispersion 5 | A-5 | B-1 | D-2 | A | A |
| Dispersion 6 | A-6 | B-1 | D-2 | A | A |
| Dispersion 7 | A-7 | B-3 | D-2 | A | A |
| Dispersion 8 | A-1/A-2 = 1/5 | B-1 | D-2 | A | A |
| Dispersion 9 | A-4/A-5 = 3/1 | B-1 | D-2 | A | A |
| Dispersion 10 | AR-1 | B-1 | D-2 | — | — |
| Dispersion 11 | AR-2 | B-2 | D-1 | — | — |
| Dispersion 12 | AR-3 | B-1 | D-2 | — | — |
| Dispersion 13 | AR-4 | B-1 | D-2 | C | C |
| Dispersion 14 | AR-5 | B-2 | D-1 | C | C |

TABLE 3

| | Near Infrared | | | Dispersibility | |
|---|---|---|---|---|---|
| | Absorbing | Pigment | | | Average |
| | Compound | Derivative | Dispersant | Viscosity | Particle Size |
| Dispersion 15 | A-8 | B-4 | D-2 | A | A |
| Dispersion 16 | A-9 | B-4 | D-2 | A | A |
| Dispersion 17 | A-9 | B-5 | D-2 | A | A |
| Dispersion 18 | A-9 | B-6 | D-2 | A | A |
| Dispersion 19 | A-9 | B-7 | D-2 | A | A |
| Dispersion 20 | A-9 | B-8 | D-2 | A | A |
| Dispersion 21 | A-9 | B-9 | D-3 | A | A |
| Dispersion 22 | A-9 | B-10 | D-3 | A | A |
| Dispersion 23 | A-10 | B-5 | D-2 | A | A |
| Dispersion 24 | A-11 | B-3 | D-2 | A | A |
| Dispersion 25 | A-12 | B-5 | D-2 | A | A |
| Dispersion 26 | A-13 | B-6 | D-2 | A | A |
| Dispersion 27 | A-13 | B-7 | D-2 | A | A |
| Dispersion 28 | A-13 | B-9 | D-3 | A | A |
| Dispersion 29 | A-13 | B-10 | D-3 | A | A |
| Dispersion 30 | A-14 | B-6 | D-2 | A | A |
| Dispersion 31 | A-15 | B-6 | D-2 | A | A |
| Dispersion 32 | A-16 | B-6 | D-2 | B | A |
| Dispersion 33 | A-17 | B-7 | D-2 | A | A |
| Dispersion 34 | A-18 | B-5 | D-2 | A | A |
| Dispersion 35 | A-19 | B-5 | D-2 | A | A |
| Dispersion 36 | A-20 | B-4 | D-2 | A | A |
| Dispersion 37 | A-21 | B-1 | D-2 | A | A |
| Dispersion 38 | A-22 | B-8 | D-2 | A | A |
| Dispersion 39 | A-23 | B-13 | D-2 | A | A |
| Dispersion 40 | A-24 | B-13 | D-2 | A | A |
| Dispersion 41 | A-25 | B-13 | D-2 | A | A |
| Dispersion 42 | A-26 | B-14 | D-2 | A | A |
| Dispersion 43 | A-27 | B-11 | D-2 | A | A |
| Dispersion 44 | A-28 | B-14 | D-2 | B | A |
| Dispersion 45 | A-29 | B-11 | D-2 | A | A |
| Dispersion 46 | A-30 | B-13 | D-2 | A | A |
| Dispersion 47 | A-31 | B-11 | D-2 | A | A |
| Dispersion 48 | A-32 | B-14 | D-2 | A | A |
| Dispersion 49 | A-33 | B-14 | D-2 | A | A |
| Dispersion 50 | A-34 | B-12 | D-2 | B | A |
| Dispersion 51 | A-35 | B-13 | D-2 | A | A |
| Dispersion 52 | A-36 | B-12 | D-2 | B | A |
| Dispersion 53 | A-37 | B-13 | D-2 | A | A |
| Dispersion 54 | A-38 | B-13 | D-2 | A | A |
| Dispersion 55 | A-39 | B-13 | D-2 | A | A |
| Dispersion 56 | A-40 | B-13 | D-2 | A | A |
| Dispersion 57 | A-41 | B-13 | D-2 | A | A |
| Dispersion 58 | A-42 | B-13 | D-2 | A | A |
| Dispersion 59 | A-43 | B-14 | D-2 | A | A |
| Dispersion 60 | A-44 | B-14 | D-2 | A | A |
| Dispersion 61 | A-45 | B-2 | D-1 | B | A |
| Dispersion 62 | A-46 | B-2 | D-1 | B | A |
| Dispersion 63 | A-47 | B-2 | D-1 | B | A |
| Dispersion 64 | A-48 | B-2 | D-1 | A | A |
| Dispersion 65 | A-49 | B-2 | D-1 | A | A |
| Dispersion 66 | A-50 | B-2 | D-1 | B | B |
| Dispersion 67 | A-51 | B-2 | D-1 | B | B |
| Dispersion 68 | A-52 | B-2 | D-1 | B | B |
| Dispersion 69 | A-8/A-9 = 1/2 | B-8 | D-2 | A | A |
| Dispersion 70 | A-9/A-18 = 1/4 | B-8 | D-2 | A | A |
| Dispersion 71 | A-9/A-23 = 3/1 | B-8 | D-2 | A | A |
| Dispersion 72 | A-32/A-38 = 1/1 | B-13 | D-2 | A | A |

The materials shown above in the tables are as follows.

(Near Infrared Absorbing Compound)

A-1 to A-52 and AR-1 to AR-5: the above-described compounds

(Pigment Derivative)

B-1 to B-14: compounds having the following structures

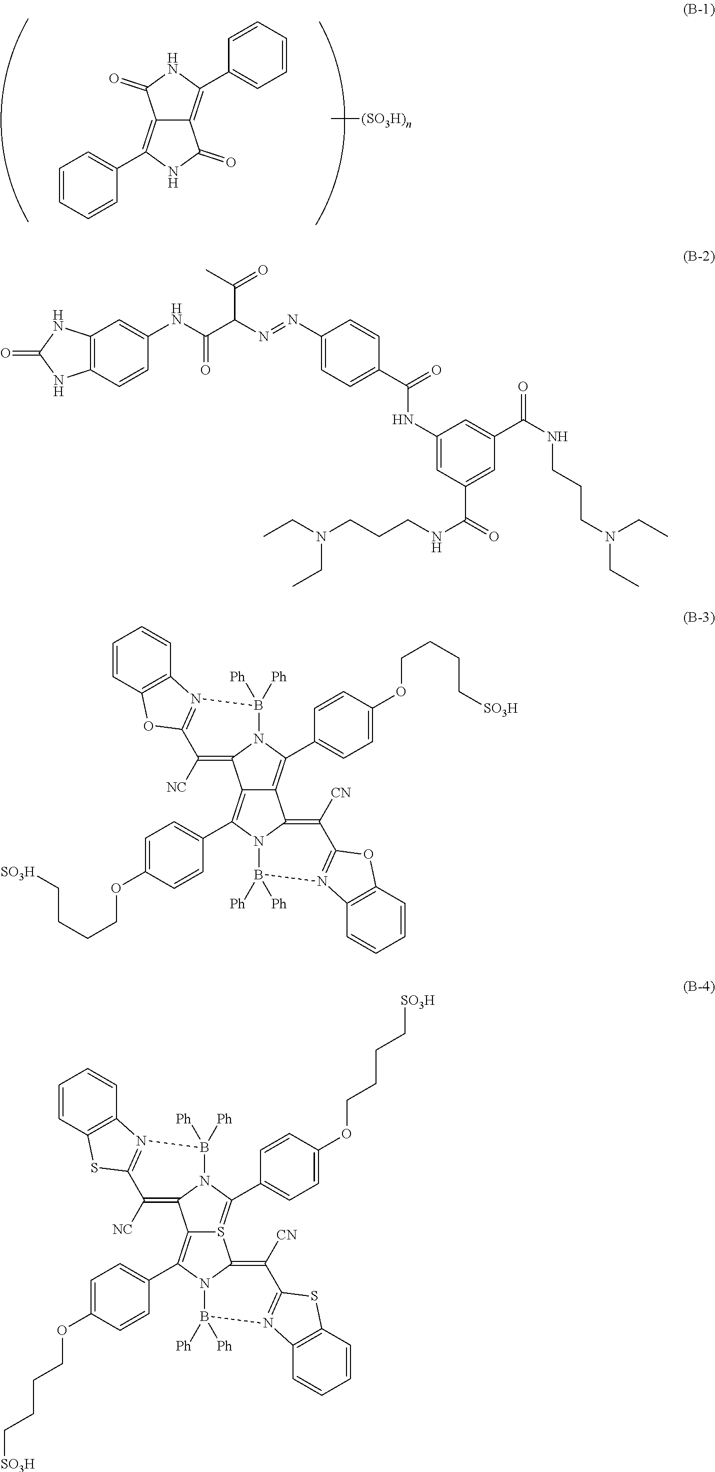

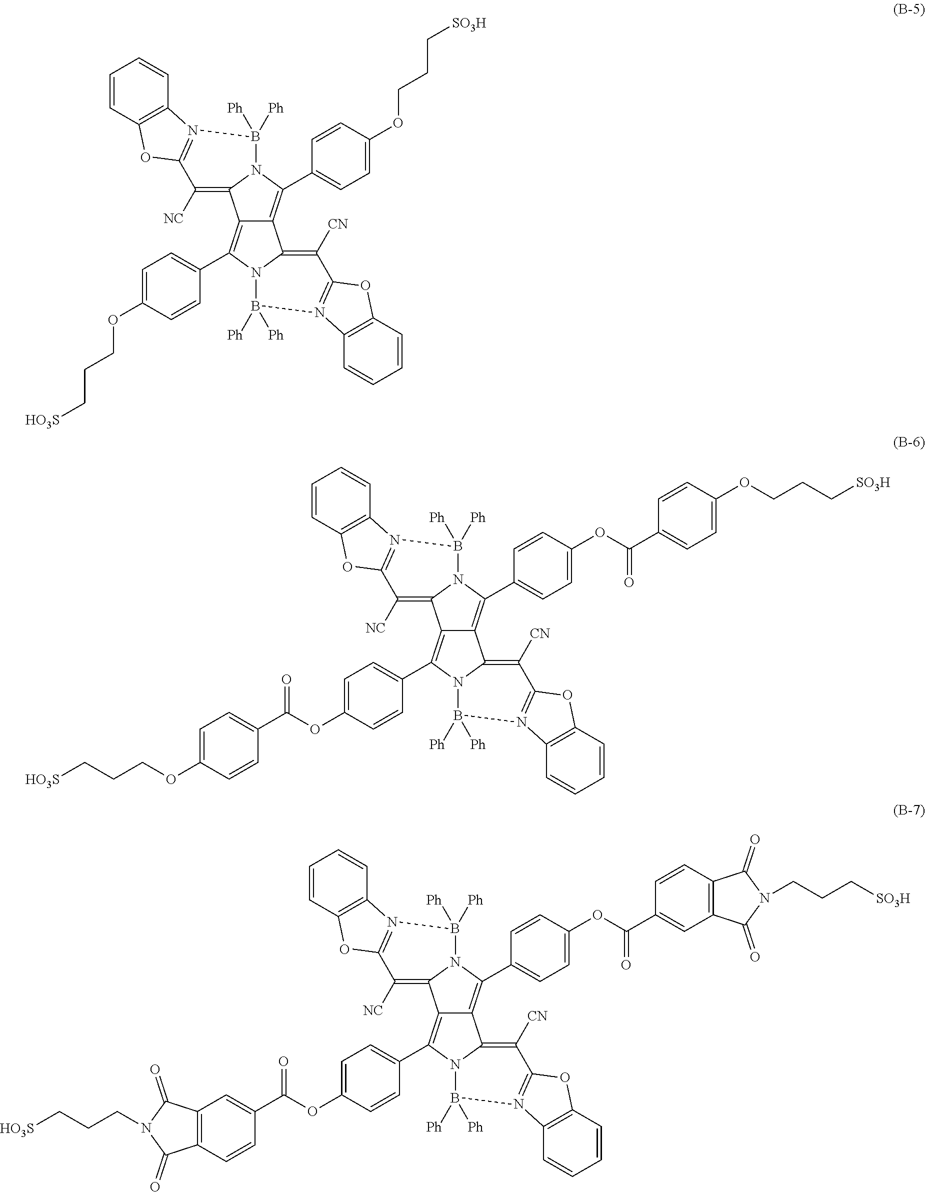

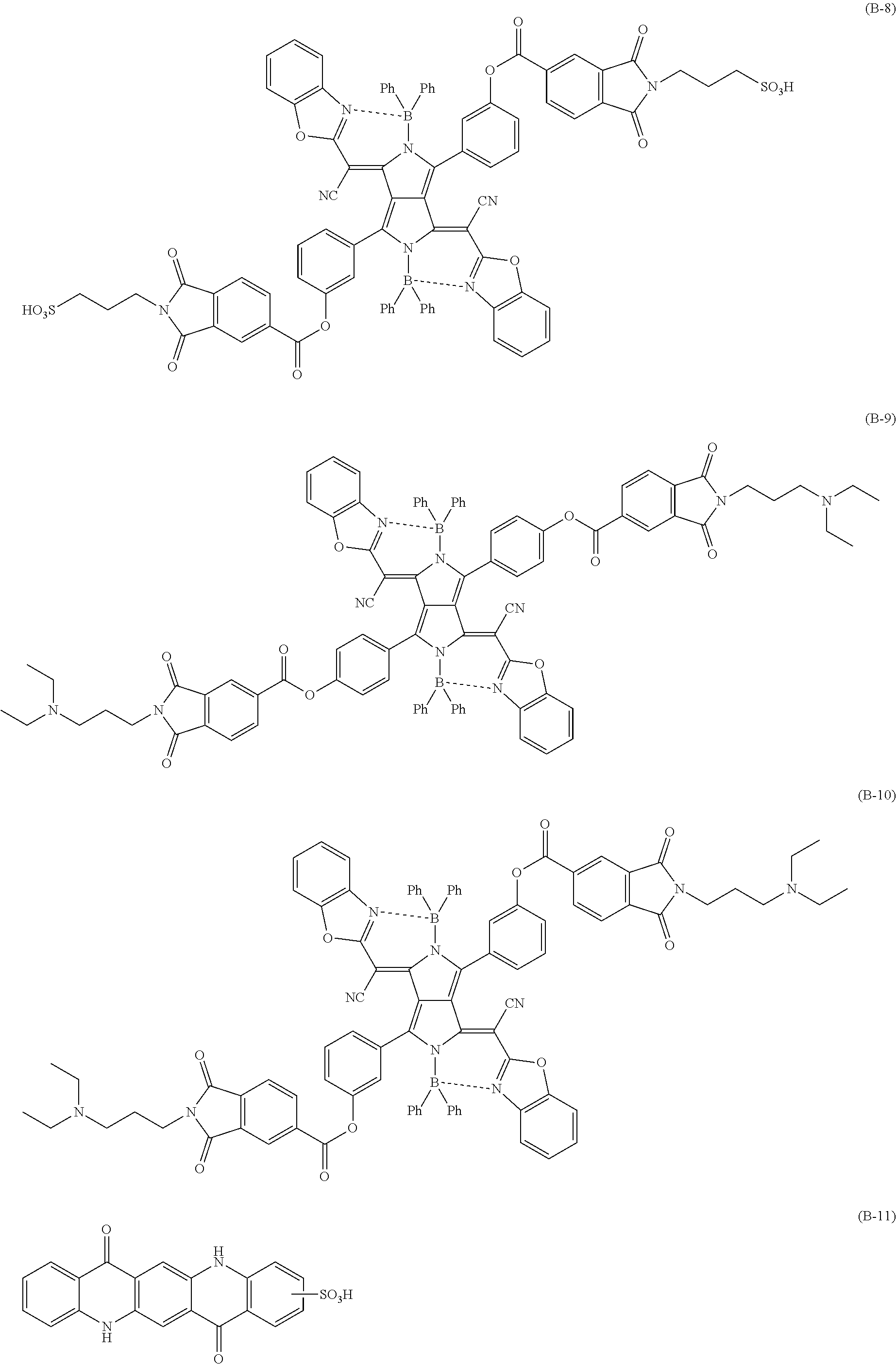

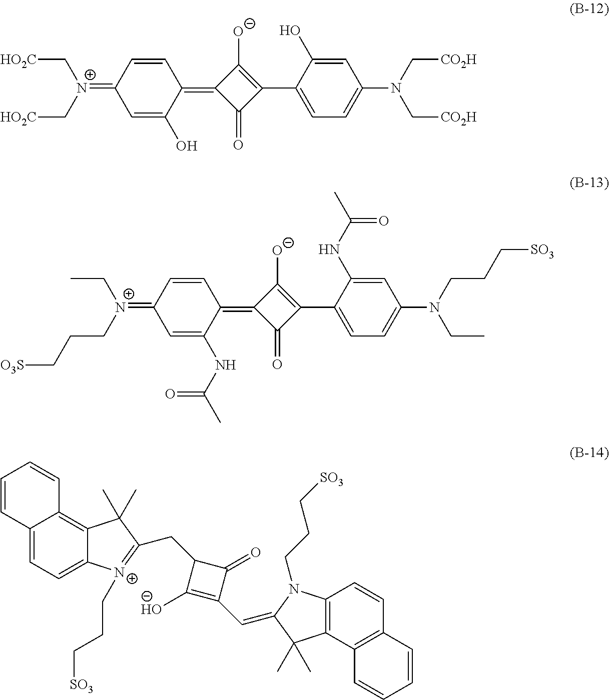

(Dispersant)

D-1: a resin having the following structure (acid value=105 mgKOH/g, weight-average molecular weight=8000), A numerical value added to a main chain represents a mass ratio of a repeating unit, and a numerical value added to a side chain represents the number of repeating units

D-2: a resin having the following structure (acid value=32.3 mgKOH/g, amine value=45.0 mgKOH/g, weight-average molecular weight=22900), A numerical value added to a main chain represents a mass ratio of a repeating unit, and a numerical value added to a side chain represents the number of repeating units

D-3: a resin having the following structure (acid value=99.1 mgKOH/g, weight-average molecular weight=38000), A numerical value added to a main chain represents a mass ratio of a repeating unit, and a numerical value added to a side chain represents the number of repeating units

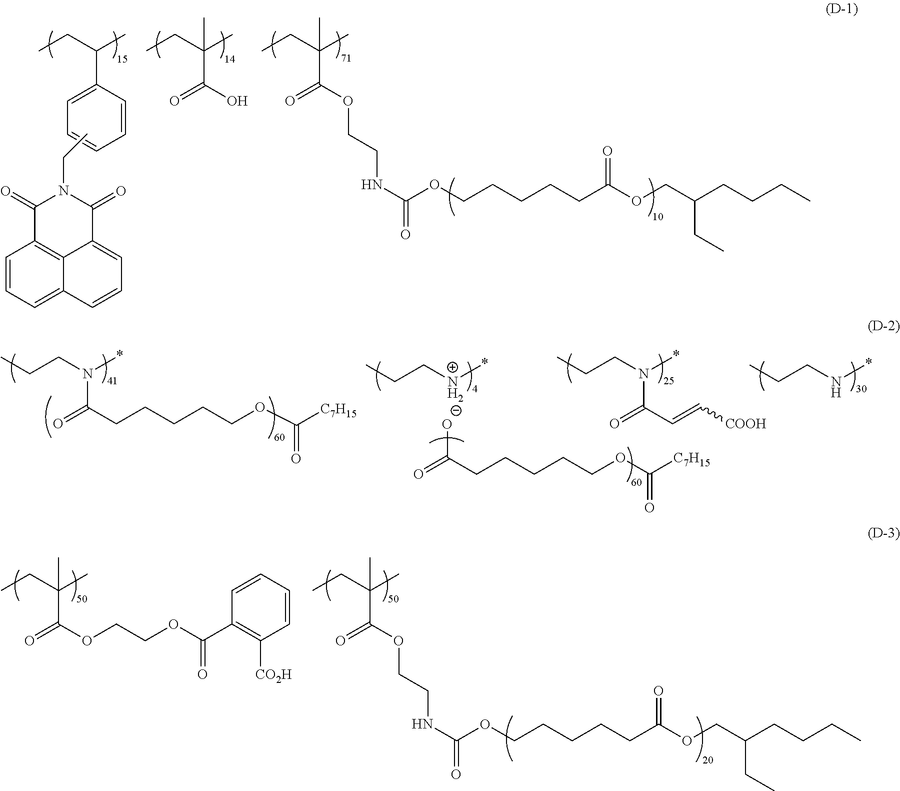

### Test Example 1

<Preparation of Curable Composition>

The following components were mixed with each other to prepare a curable composition. In Example 3, as a resin, a mixture obtained by mixing E-1 and E-3 at a mass ratio E-1/E-3 of 2/1 was used. In addition, in Example 5, as a resin, a mixture obtained by mixing E-1 and E-2 at a mass ratio E-1/E-2 of 4/1 was used. In addition, in each of Examples 14, 21, 24, 30, 38, 44, 56, and 63, as a resin, a mixture obtained by mixing resins shown in the following tables at a ratio shown in the following tables was used.

(Composition of Curable Composition)
Dispersion obtained as described above: 55 parts by mass
Resin: 7.0 parts by mass
Polymerizable compound: 4.5 parts by mass
Photopolymerization initiator: 0.8 parts by mass
Polymerization inhibitor (p-methoxyphenol): 0.001 parts by mass
Surfactant (the following mixture (Mw=14000); in the following formula, “%” representing the proportion of a repeating unit is mass %): 0.03 parts by mass

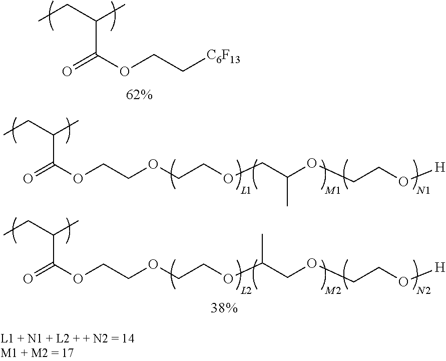

Ultraviolet absorber (UV-503, manufactured by Daito Chemical Co., Ltd.): 1.3 parts by mass
Solvent (propylene glycol monomethyl ether acetate): 31 parts by mass

TABLE 4

| | | | Photopolymerization | Polymerizable |
|---|---|---|---|---|
| | Dispersion | Resin | Initiator | Compound |
| Example 1 | Dispersion 1 | E-1 | C-7 | M-1 |
| Example 2 | Dispersion 2 | E-1 | C-7 | M-1 |
| Example 3 | Dispersion 3 | E-1/E-3 = 2/1 | C-8 | M-1 |
| Example 4 | Dispersion 4 | E-1 | C-8 | M-1 |
| Example 5 | Dispersion 5 | E-1/E-2 = 4/1 | C-7 | M-1 |
| Example 6 | Dispersion 6 | E-1 | C-7 | M-1 |
| Example 7 | Dispersion 7 | E-1 | C-7 | M-1 |
| Example 8 | Dispersion 8 | E-1 | C-7 | M-1 |
| Example 9 | Dispersion 9 | E-1 | C-8 | M-1 |
| Comparative Example 1 | Dispersion 10 | E-1 | C-7 | M-1 |
| Comparative Example 2 | Dispersion 11 | E-1 | C-8 | M-1 |
| Comparative Example 3 | Dispersion 12 | E-1 | C-8 | M-1 |
| Comparative Example 4 | Dispersion 13 | E-1 | C-7 | M-1 |
| Comparative Example 5 | Dispersion 14 | E-1 | C-7 | M-1 |

TABLE 5

| | | | Photopolymerization | Polymerizable |
|---|---|---|---|---|
| | Dispersion | Resin | Initiator | Compound |
| Example 10 | Dispersion 15 | E-1 | C-7 | M-1 |
| Example 11 | Dispersion 16 | E-1 | C-7 | M-1 |
| Example 12 | Dispersion 17 | E-1 | C-7 | M-1 |
| Example 13 | Dispersion 18 | E-1 | C-7 | M-1 |
| Example 14 | Dispersion 19 | E-1/E-3 = 5/1 | C-7 | M-1 |
| Example 15 | Dispersion 20 | E-1 | C-8 | M-1 |
| Example 16 | Dispersion 21 | E-1 | C-7 | M-1 |
| Example 17 | Dispersion 22 | E-1 | C-7 | M-1 |
| Example 18 | Dispersion 23 | E-1 | C-7 | M-1 |
| Example 19 | Dispersion 24 | E-1 | C-7 | M-1 |
| Example 20 | Dispersion 25 | E-1 | C-7 | M-1 |
| Example 21 | Dispersion 26 | E-1/E-3 = 3/1 | C-8 | M-1 |
| Example 22 | Dispersion 27 | E-1 | C-7 | M-1 |
| Example 23 | Dispersion 28 | E-1 | C-7 | M-1 |
| Example 24 | Dispersion 29 | E-1/E-2 = 3/1 | C-7 | M-1 |
| Example 25 | Dispersion 30 | E-1 | C-7 | M-1 |
| Example 26 | Dispersion 31 | E-1 | C-7 | M-1 |
| Example 27 | Dispersion 32 | E-1 | C-8 | M-1 |
| Example 28 | Dispersion 33 | E-1 | C-7 | M-1 |
| Example 29 | Dispersion 34 | E-1 | C-7 | M-1 |
| Example 30 | Dispersion 35 | E-1/E-3 = 4/1 | C-7 | M-1 |
| Example 31 | Dispersion 36 | E-1 | C-7 | M-1 |
| Example 32 | Dispersion 37 | E-1 | C-7 | M-1 |
| Example 33 | Dispersion 38 | E-1 | C-7 | M-1 |
| Example 34 | Dispersion 39 | E-1 | C-7 | M-1 |
| Example 35 | Dispersion 40 | E-1 | C-8 | M-1 |
| Example 36 | Dispersion 41 | E-1 | C-7 | M-1 |
| Example 37 | Dispersion 42 | E-1 | C-7 | M-1 |
| Example 38 | Dispersion 43 | E-1/E-2 = 5/1 | C-7 | M-1 |
| Example 39 | Dispersion 44 | E-1 | C-7 | M-1 |
| Example 40 | Dispersion 45 | E-1 | C-7 | M-1 |
| Example 41 | Dispersion 46 | E-1 | C-7 | M-1 |
| Example 42 | Dispersion 47 | E-1 | C-7 | M-1 |
| Example 43 | Dispersion 48 | E-1 | C-7 | M-1 |
| Example 44 | Dispersion 49 | E-1/E-2 = 5/1 | C-8 | M-1 |
| Example 45 | Dispersion 50 | E-1 | C-7 | M-1 |
| Example 46 | Dispersion 51 | E-1 | C-7 | M-1 |
| Example 47 | Dispersion 52 | E-1 | C-7 | M-1 |
| Example 48 | Dispersion 53 | E-1 | C-7 | M-1 |
| Example 49 | Dispersion 54 | E-1 | C-7 | M-1 |
| Example 50 | Dispersion 55 | E-1 | C-8 | M-1 |
| Example 51 | Dispersion 56 | E-1 | C-7 | M-1 |
| Example 52 | Dispersion 57 | E-1 | C-7 | M-1 |
| Example 53 | Dispersion 58 | E-1 | C-7 | M-1 |
| Example 54 | Dispersion 59 | E-1 | C-7 | M-1 |
| Example 55 | Dispersion 60 | E-1 | C-7 | M-1 |
| Example 56 | Dispersion 61 | E-1/E-3 = 2/1 | C-7 | M-1 |
| Example 57 | Dispersion 62 | E-1 | C-7 | M-1 |
| Example 58 | Dispersion 63 | E-1 | C-7 | M-1 |
| Example 59 | Dispersion 64 | E-1 | C-7 | M-1 |
| Example 60 | Dispersion 65 | E-1 | C-8 | M-1 |
| Example 61 | Dispersion 66 | E-1 | C-7 | M-1 |
| Example 62 | Dispersion 67 | E-1 | C-7 | M-1 |
| Example 63 | Dispersion 68 | E-1/E-2 = 2/1 | C-7 | M-1 |
| Example 64 | Dispersion 69 | E-1 | C-8 | M-1 |
| Example 65 | Dispersion 70 | E-1 | C-7 | M-1 |
| Example 66 | Dispersion 71 | E-1 | C-7 | M-1 |
| Example 67 | Dispersion 72 | E-1 | C-7 | M-1 |

The components shown above in the tables are as follows.

(Resin)
E-1: ACRYBASE FF-426 (manufactured by Fujikura Kasei Co., Ltd., alkali-soluble resin)
E-2: ARTON F4520 (manufactured by JSR Corporation)
E-3: ARTON D4540 (manufactured by JSR Corporation)

(Photopolymerization Initiator)
C-7 and C-8: compounds having the following structures

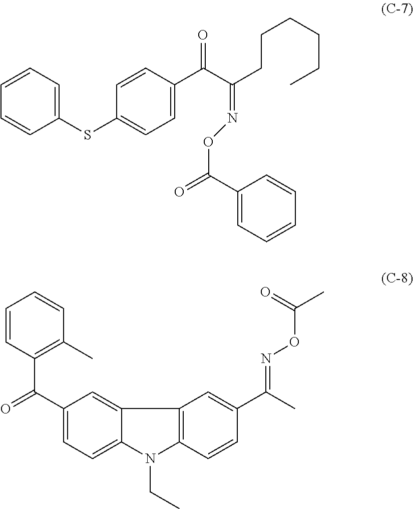 [SMILES: CCCCCC/C(=N/OC(=O)c1ccccc1)C(=O)c1ccc(Sc2ccccc2)cc1 ; CCn1c2ccc(C(=O)c3ccccc3C)cc2c2cc(/C(C)=N/OC(C)=O)ccc21]

(Polymerizable Compound)
M-1: ARONIX M-305 (manufactured by Toagosei Co., Ltd.; a mixture of the following compounds; content of triacrylate: 55 to 63 mass %)

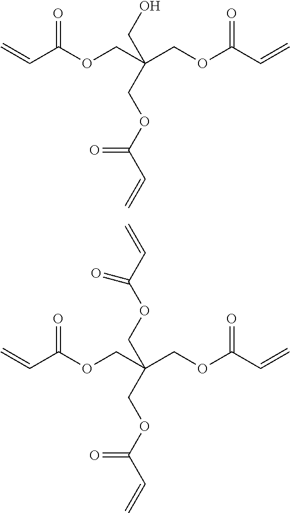

<Preparation of Film>

The curable composition was applied to a glass substrate using a spin coating method and then was heated using a hot plate at 100° C. for 2 minutes. As a result, a composition layer was obtained. The obtained composition layer was exposed using an i-ray stepper or an aligner at an exposure dose of 500 mJ/cm². Next, a curing treatment was further performed on the exposed composition layer using a hot plate at 220° C. for 5 minutes. As a result, a film having a thickness of 0.7 μm was obtained.

<Evaluation of Heat Resistance>

The obtained film was heated using a hot plate at 260° C. for 300 seconds. The transmittance of the film in a wavelength range of 400 to 1200 nm was measured before and after heating using a spectrophotometer U-4100 (manufactured by Hitachi High-Technologies Corporation). At a wavelength at which a change in transmittance before and after heating was the largest in a wavelength range of 400 to 1200 nm, the change in transmittance was calculated from the following expression and was evaluated based on the following criteria.

Change in transmittance=|(Transmittance after Heating−Transmittance before Heating|

A: the change in transmittance was lower than 3%

B: the change in transmittance was 3% or higher and lower than 5%

C: the change in transmittance was 5% or higher

In addition, regarding absorbances at an absorption maximum before and after heating, a residual rate was calculated from the following expression and was evaluated based on the following criteria.

Residual Rate (%)={(Absorbance after Heating)÷(Absorbance before Heating)}×100

A: the residual rate was higher than 95% and 100% or lower

B: the residual rate was higher than 80% and 95% or lower

C: the residual rate was 80% or lower

<Evaluation of Light Fastness>

The obtained film was set in a fading tester (100000 lux) equipped with a super xenon lamp and was irradiated with light at 100000 lux for 50 hours under conditions where an ultraviolet cut filter was not used. Next, the transmission spectrum of the film after the light irradiation was measured using a spectrophotometer U-4100 (manufactured by Hitachi High-Technologies Corporation). At a wavelength at which a change in transmittance before and after light irradiation was the largest in a wavelength range of 400 to 1200 nm, the change in transmittance was calculated from the following expression, and heat resistance was evaluated based on the following criteria.

Change in transmittance=|(Transmittance after Light Irradiation−Transmittance before Light Irradiation)|

A: the change in transmittance was lower than 3%

B: the change in transmittance was 3% or higher and lower than 5%

C: the change in transmittance was 5% or higher

In addition, regarding absorbances at an absorption maximum before and after light irradiation, a residual rate was calculated from the following expression and was evaluated based on the following criteria.

Residual Rate (%)={(Absorbance after Light Irradiation)÷(Absorbance before Light Irradiation)}×100

A: the residual rate was higher than 95% and 100% or lower

B: the residual rate was higher than 80% and 95% or lower

C: the residual rate was 80% or lower

<Evaluation of Photolithographic Properties>

The curable composition was applied to a silicon wafer with an undercoat layer using a spin coating method such that the thickness after the application was 0.7 μm, and then was heated using a hot plate at 100° C. for 2 minutes. As a result, a composition layer was obtained. Next, using an i-ray stepper exposure device FPA-3000 i5+(manufactured by Canon Corporation), the obtained composition layer was exposed (an optimum exposure dose was selected such that the line width was 1.1 μm) through a mask having a 1.1 μm×1.1 Bayer pattern. Next, puddle development was performed on the exposed composition layer at 23° C. for 60 seconds using a tetramethylammonium hydroxide (TMAH) 0.3 mass % aqueous solution. Next, the silicon wafer was rinsed by spin showering and was cleaned with pure water. As a result, a pattern was obtained. The amount of residues remaining on the underlayer of the obtained pattern was evaluated by binarization of the image based on the following criteria.

A: the amount of the residues was 1% or lower with respect to the total area of the underlayer

B: the amount of the residues was higher than 1% and 3% or lower with respect to the total area of the underlayer

C: the amount of the residues was higher than 3% with respect to the total area of the underlayer

TABLE 6

| | Heat Resistance | | Light Fastness | | |
|---|---|---|---|---|---|
| | Change in | Residual | Change in | Residual | Photolithographic |
| | Transmittance | Rate | Transmittance | Rate | Properties |
| Example 1 | A | A | A | A | A |
| Example 2 | A | A | A | A | A |
| Example 3 | A | A | A | A | A |
| Example 4 | A | A | A | A | A |
| Example 5 | A | A | A | A | A |
| Example 6 | A | A | A | A | A |
| Example 7 | A | A | A | A | A |
| Example 8 | A | A | A | A | A |
| Example 9 | A | A | A | A | A |
| Comparative | B | B | B | B | C |
| Example 1 | | | | | |
| Comparative | C | C | B | B | C |
| Example 2 | | | | | |
| Comparative | C | C | C | C | C |
| Example 3 | | | | | |
| Comparative | C | C | B | B | C |
| Example 4 | | | | | |
| Comparative | B | B | B | B | C |
| Example 5 | | | | | |

TABLE 7

| | Heat Resistance | | Light Fastness | | |
|---|---|---|---|---|---|
| | Change in | Residual | Change in | Residual | Photolithographic |
| | Transmittance | Rate | Transmittance | Rate | Properties |
| Example 10 | A | A | A | A | A |
| Example 11 | A | A | A | A | A |
| Example 12 | A | A | A | A | A |
| Example 13 | A | A | A | A | A |
| Example 14 | A | A | A | A | A |
| Example 15 | A | A | A | A | A |
| Example 16 | A | A | A | A | A |
| Example 17 | A | A | A | A | A |
| Example 18 | A | A | A | A | A |
| Example 19 | A | A | A | A | A |
| Example 20 | A | A | A | A | A |
| Example 21 | A | A | A | A | A |
| Example 22 | A | A | A | A | A |
| Example 23 | A | A | A | A | A |
| Example 24 | A | A | A | A | A |
| Example 25 | A | A | A | A | A |
| Example 26 | A | A | A | A | A |
| Example 27 | A | A | A | A | B |
| Example 28 | A | A | A | A | A |
| Example 29 | A | A | A | A | A |
| Example 30 | A | A | A | A | A |
| Example 31 | A | A | A | A | A |
| Example 32 | A | A | A | A | A |
| Example 33 | A | A | A | A | A |
| Example 34 | A | A | A | A | A |
| Example 35 | A | A | A | A | A |
| Example 36 | A | A | A | A | A |
| Example 37 | A | A | A | A | A |
| Example 38 | A | A | A | A | A |
| Example 39 | A | A | A | A | B |
| Example 40 | A | A | A | A | A |
| Example 41 | A | A | A | A | A |
| Example 42 | A | A | A | A | A |
| Example 43 | A | A | A | A | A |
| Example 44 | A | A | A | A | A |
| Example 45 | A | A | A | A | B |
| Example 46 | A | A | A | A | A |
| Example 47 | A | A | A | A | B |
| Example 48 | A | A | A | A | A |
| Example 49 | A | A | A | A | A |
| Example 50 | A | A | A | A | A |
| Example 51 | A | A | A | A | A |
| Example 52 | A | A | A | A | A |
| Example 53 | A | A | A | A | A |
| Example 54 | A | A | A | A | A |
| Example 55 | A | A | A | A | A |
| Example 56 | A | A | B | B | A |
| Example 57 | A | A | B | B | A |
| Example 58 | A | A | B | B | A |
| Example 59 | A | A | A | A | A |
| Example 60 | A | A | A | A | A |
| Example 61 | A | A | B | B | B |
| Example 62 | A | A | B | B | B |
| Example 63 | A | A | B | B | B |
| Example 64 | A | A | A | A | A |
| Example 65 | A | A | A | A | A |
| Example 66 | A | A | A | A | A |
| Example 67 | A | A | A | A | A |

As shown in the above tables, in the films formed of the compositions according to Examples, heat resistance and light fastness were excellent. Further, in the compositions according to Examples, photolithographic properties were also excellent.

### Test Example 2

<Preparation of Curable Composition>

50.0 parts by mass of a compound having an epoxy group shown in the following tables and 100 parts by mass of methyl ethyl ketone were put into a container and were stirred at a temperature of 20° C. to 35° C. for 2 hours such that the compound having an epoxy group was dissolved in methyl ethyl ketone. Next, 6.20 parts by mass of a dispersion shown in the following tables was added to this mixed solution, and the solution was stirred at a temperature of 20° C. to 35° C. so as to be uniform. Next, 0.500 parts by mass (1.00 mass % with respect to the compound having an epoxy group) of an epoxy curing agent shown in the following tables was added, and the solution was stirred at a temperature of 20° C. to 35° C. for 1 hour. As a result, a curable composition was prepared.

TABLE 8

| | | Compound | Epoxy |
|---|---|---|---|
| | | having | Curing |
| | Dispersion | Epoxy Group | Agent |
| Example 101 | Dispersion 1 | F-1 | G-1 |
| Example 102 | Dispersion 2 | F-2 | G-4 |
| Example 103 | Dispersion 3 | F-3 | G-2 |
| Example 104 | Dispersion 4 | F-4 | G-3 |
| Example 105 | Dispersion 5 | F-5 | G-5 |
| Example 106 | Dispersion 6 | F-4 | G-4 |
| Example 107 | Dispersion 7 | F-1 | G-3 |
| Example 108 | Dispersion 8 | F-3 | G-2 |
| Example 109 | Dispersion 9 | F-1 | G-1 |
| Comparative Example 101 | Dispersion 10 | F-1 | G-1 |
| Comparative Example 102 | Dispersion 11 | F-2 | G-4 |
| Comparative Example 103 | Dispersion 12 | F-1 | G-1 |
| Comparative Example 104 | Dispersion 13 | F-5 | G-5 |
| Comparative Example 105 | Dispersion 14 | F-3 | G-2 |

TABLE 9

| | | Compound having | |
|---|---|---|---|
| | Dispersion | Epoxy Group | Epoxy Curing Agent |
| Example 110 | Dispersion 15 | F-3 | G-1 |
| Example 111 | Dispersion 16 | F-3 | G-1 |
| Example 112 | Dispersion 17 | F-3 | G-1 |
| Example 113 | Dispersion 18 | F-3 | G-2 |
| Example 114 | Dispersion 19 | F-3 | G-1 |
| Example 115 | Dispersion 20 | F-3 | G-3 |
| Example 116 | Dispersion 21 | F-3 | G-1 |
| Example 117 | Dispersion 22 | F-3 | G-3 |
| Example 118 | Dispersion 23 | F-3 | G-1 |
| Example 119 | Dispersion 24 | F-3 | G-5 |
| Example 120 | Dispersion 25 | F-3 | G-1 |
| Example 121 | Dispersion 26 | F-3 | G-1 |
| Example 122 | Dispersion 27 | F-3 | G-1 |
| Example 123 | Dispersion 28 | F-3 | G-1 |
| Example 124 | Dispersion 29 | F-3 | G-2 |
| Example 125 | Dispersion 30 | F-3 | G-1 |
| Example 126 | Dispersion 31 | F-3 | G-5 |
| Example 127 | Dispersion 32 | F-3 | G-1 |
| Example 128 | Dispersion 33 | F-2 | G-1 |
| Example 129 | Dispersion 34 | F-3 | G-3 |
| Example 130 | Dispersion 35 | F-3 | G-1 |
| Example 131 | Dispersion 36 | F-3 | G-2 |
| Example 132 | Dispersion 37 | F-1 | G-1 |
| Example 133 | Dispersion 38 | F-3 | G-1 |
| Example 134 | Dispersion 39 | F-2 | G-3 |
| Example 135 | Dispersion 40 | F-3 | G-1 |
| Example 136 | Dispersion 41 | F-3 | G-1 |
| Example 137 | Dispersion 42 | F-2 | G-1 |
| Example 138 | Dispersion 43 | F-3 | G-1 |
| Example 139 | Dispersion 44 | F-3 | G-2 |
| Example 140 | Dispersion 45 | F-3 | G-1 |
| Example 141 | Dispersion 46 | F-3 | G-5 |
| Example 142 | Dispersion 47 | F-1 | G-1 |
| Example 143 | Dispersion 48 | F-3 | G-1 |
| Example 144 | Dispersion 49 | F-5 | G-3 |
| Example 145 | Dispersion 50 | F-3 | G-1 |
| Example 146 | Dispersion 51 | F-3 | G-1 |
| Example 147 | Dispersion 52 | F-3 | G-1 |
| Example 148 | Dispersion 53 | F-3 | G-2 |
| Example 149 | Dispersion 54 | F-3 | G-1 |
| Example 150 | Dispersion 55 | F-1 | G-1 |
| Example 151 | Dispersion 56 | F-3 | G-2 |
| Example 152 | Dispersion 57 | F-5 | G-1 |
| Example 153 | Dispersion 58 | F-2 | G-3 |
| Example 154 | Dispersion 59 | F-1 | G-2 |
| Example 155 | Dispersion 60 | F-3 | G-1 |
| Example 156 | Dispersion 61 | F-4 | G-1 |
| Example 157 | Dispersion 62 | F-3 | G-1 |
| Example 158 | Dispersion 63 | F-4 | G-1 |
| Example 159 | Dispersion 64 | F-3 | G-5 |
| Example 160 | Dispersion 65 | F-3 | G-1 |
| Example 161 | Dispersion 66 | F-1 | G-1 |
| Example 162 | Dispersion 67 | F-3 | G-3 |
| Example 163 | Dispersion 68 | F-1 | G-1 |
| Example 164 | Dispersion 69 | F-3 | G-5 |
| Example 165 | Dispersion 70 | F-2 | G-2 |
| Example 166 | Dispersion 71 | F-3 | G-1 |
| Example 167 | Dispersion 72 | F-3 | G-1 |

The components shown above in the tables are as follows.

### (Compound Having Epoxy Group)

F-1: a random polymer having a glycidyl methacrylate skeleton (MARPROOF G-0150M, manufactured by NOF Corporation, weight-average molecular weight: 10000)
F-2: EPICLON HP-4700 (manufactured by DIC Corporation)
F-3: JER1031S (manufactured by Mitsubishi Chemical Corporation)
F-4: EHPE 3150 (manufactured by Daicel Corporation)
F-5: EOCN-1020 (manufactured by Nippon Kayaku Co., Ltd.)

—Epoxy Curing Agent—
G-1: succinic acid
G-2: trimellitic acid
G-3: pyromellitic anhydride
G-4: N,N-dimethyl-4-aminopyridine
G-5: pentaerythritol tetrakis(3-mercaptopropionate)

<Preparation of Film>

Each of the curable compositions prepared as described above was applied to a glass substrate using a spin coating method, was heated (pre-baked) using a hot plate at 80° C. for 10 minutes, and then was heated at 150° C. for 3 hours. As a result, a film having a thickness of 0.7 μm was obtained.

<Evaluation of Heat Resistance and Light Fastness>

Using the same method as in Test Example 1, heat resistance and light fastness were evaluated.

TABLE 10

| | Heat Resistance | | Light Fastness | |
|---|---|---|---|---|
| | Change | Residual | Change in | Residual |
| | in Transmittance | Rate | Transmittance | Rate |
| Example 101 | A | A | A | A |
| Example 102 | A | A | A | A |
| Example 103 | A | A | A | A |
| Example 104 | A | A | A | A |
| Example 105 | A | A | A | A |
| Example 106 | A | A | A | A |
| Example 107 | A | A | A | A |
| Example 108 | A | A | A | A |
| Example 109 | A | A | A | A |
| Comparative | B | B | B | B |
| Example 101 | | | | |
| Comparative | C | C | B | B |
| Example 102 | | | | |
| Comparative | C | C | C | C |
| Example 103 | | | | |
| Comparative | C | C | B | B |
| Example 104 | | | | |
| Comparative | B | B | B | B |
| Example 105 | | | | |

TABLE 11

| | Heat Resistance | | Light Fastness | |
|---|---|---|---|---|
| | Change | Residual | Change in | Residual |
| | in Transmittance | Rate | Transmittance | Rate |
| Example 110 | A | A | A | A |
| Example 111 | A | A | A | A |
| Example 112 | A | A | A | A |
| Example 113 | A | A | A | A |
| Example 114 | A | A | A | A |
| Example 115 | A | A | A | A |
| Example 116 | A | A | A | A |
| Example 117 | A | A | A | A |
| Example 118 | A | A | A | A |
| Example 119 | A | A | A | A |
| Example 120 | A | A | A | A |
| Example 121 | A | A | A | A |
| Example 122 | A | A | A | A |
| Example 123 | A | A | A | A |
| Example 124 | A | A | A | A |
| Example 125 | A | A | A | A |
| Example 126 | A | A | A | A |
| Example 127 | A | A | A | A |
| Example 128 | A | A | A | A |
| Example 129 | A | A | A | A |
| Example 130 | A | A | A | A |
| Example 131 | A | A | A | A |
| Example 132 | A | A | A | A |
| Example 133 | A | A | A | A |
| Example 134 | A | A | A | A |
| Example 135 | A | A | A | A |
| Example 136 | A | A | A | A |
| Example 137 | A | A | A | A |
| Example 138 | A | A | A | A |
| Example 139 | A | A | A | A |
| Example 140 | A | A | A | A |
| Example 141 | A | A | A | A |
| Example 142 | A | A | A | A |
| Example 143 | A | A | A | A |
| Example 144 | A | A | A | A |
| Example 145 | A | A | A | A |
| Example 146 | A | A | A | A |
| Example 147 | A | A | A | A |
| Example 148 | A | A | A | A |
| Example 149 | A | A | A | A |
| Example 150 | A | A | A | A |
| Example 151 | A | A | A | A |
| Example 152 | A | A | A | A |
| Example 153 | A | A | A | A |
| Example 154 | A | A | A | A |
| Example 155 | A | A | A | A |
| Example 156 | A | A | B | B |
| Example 157 | A | A | B | B |
| Example 158 | A | A | B | B |
| Example 159 | A | A | A | A |
| Example 160 | A | A | A | A |
| Example 161 | A | A | B | B |
| Example 162 | A | A | B | B |
| Example 163 | A | A | B | B |
| Example 164 | A | A | A | A |
| Example 165 | A | A | A | A |
| Example 166 | A | A | A | A |
| Example 167 | A | A | A | A |

As shown in the above tables, in the films formed of the compositions according to Examples, heat resistance and light fastness were excellent.

In Examples 101 to 167, even in a case where two compounds having an epoxy group were used in combination, the same effects were obtained. In Examples 101 to 167, even in a case where two epoxy curing agents were used in combination, the same effects were obtained.

### Test Example 3

<Preparation of Curable Composition>

The following components were mixed with each other to prepare a curable composition.

(Composition of Curable Composition)
Dispersion obtained as described above: 55 parts by mass
Resin having the following structure (acid value: 70 mgKOH/g, Mw=11000; a ratio in a structural unit is a molar ratio): 7.0 parts by mass

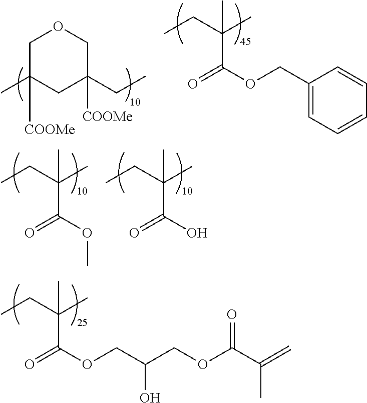

Compound having an epoxy group (EHPE 3150, manufactured by Daicel Corporation): 0.42 parts by mass
Silane coupling agent (a compound having the following structure): 0.14 parts by mass
Solvent (propylene glycol monomethyl ether acetate): 31 parts by mass

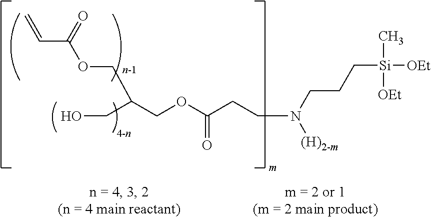

<Preparation of Infrared Cut Filter>

Each of the curable compositions prepared as described above was applied to a substrate shown in the following tables using a spin coating method, was heated (pre-baked) using a hot plate at 100° C. for 2 minutes, and then was heated at 220° C. for 5 minutes. As a result, a film having a thickness of 0.7 μm was obtained. As a substrate 1, a fluorophosphate glass substrate (NF-50, manufactured by AGC Techno Glass Co., Ltd., thickness: 0.5 mm) was used. In addition, as a substrate 2, a glass substrate (EAGLE XG, manufactured by Corning Inc., thickness: 0.5 mm) was used.

Next, ten TiO₂ films as high refractive index material layers and ten SiO₂ films as low refractive index material layers were alternately laminated by vapor deposition on the obtained film and the back surface (surface where the film was not formed) of the substrate. As a result, a dielectric multi-layer film (the total number of the TiO₂ films and the SiO₂ films laminated on each surface was 20 layers, and the total number thereof laminated on both surfaces was 40) was formed, and a near infrared cut filter was prepared.

<Evaluation of Heat Resistance and Light Fastness>

Using the same method as in Test Example 1, heat resistance and light fastness were evaluated.

<Evaluation of Viewing Angle Dependence>

At different incidence angles including a vertical angle (angle: 0 degrees) and 40 degrees with respect to the infrared cut filter surface, the shift amount of a wavelength at which a transmittance of a slope formed by a decrease in spectral transmittance was 50% in a wavelength range from a visible range of a wavelength of 600 nm or longer to a near infrared range was evaluated based on the following criteria.

A: the shift amount of the wavelength was shorter than 5 nm

B: the shift amount of the wavelength was 5 nm or longer and shorter than 20 nm

C: the shift amount of the wavelength was 20 nm or longer

TABLE 12

| | | | Heat Resistance | | Light Fastness | | |
|---|---|---|---|---|---|---|---|
| | | | Change in | Residual | Change in | Residual | Viewing Angle |
| | Dispersion | Substrate | Transmittance | Rate | Transmittance | Rate | Dependence |
| Example 201 | Dispersion 1 | Substrate 1 | A | A | A | A | A |
| Example 202 | Dispersion 2 | Substrate 1 | A | A | A | A | A |
| Example 203 | Dispersion 3 | Substrate 1 | A | A | A | A | A |
| Example 204 | Dispersion 4 | Substrate 1 | A | A | A | A | A |
| Example 205 | Dispersion 5 | Substrate 1 | A | A | A | A | A |
| Example 206 | Dispersion 6 | Substrate 1 | A | A | A | A | A |
| Example 207 | Dispersion 7 | Substrate 1 | A | A | A | A | A |
| Example 208 | Dispersion 8 | Substrate 1 | A | A | A | A | A |
| Example 209 | Dispersion 9 | Substrate 1 | A | A | A | A | A |
| Example 210 | Dispersion 1 | Substrate 2 | A | A | A | A | B |
| Example 211 | Dispersion 2 | Substrate 2 | A | A | A | A | B |
| Example 212 | Dispersion 3 | Substrate 2 | A | A | A | A | B |
| Example 213 | Dispersion 4 | Substrate 2 | A | A | A | A | B |
| Example 214 | Dispersion 5 | Substrate 2 | A | A | A | A | B |
| Example 215 | Dispersion 6 | Substrate 2 | A | A | A | A | B |
| Example 216 | Dispersion 7 | Substrate 2 | A | A | A | A | B |
| Example 217 | Dispersion 8 | Substrate 2 | A | A | A | A | B |
| Example 218 | Dispersion 9 | Substrate 2 | A | A | A | A | B |

TABLE 13

| | | | Heat Resistance | | Light Fastness | | |
|---|---|---|---|---|---|---|---|
| | | | Change in | | Change in | | Viewing Angle |
| | Dispersion | Substrate | Transmittance | Residual Rate | Transmittance | Residual Rate | Dependence |
| Example 219 | Dispersion 15 | Substrate 1 | A | A | A | A | A |
| Example 220 | Dispersion 16 | Substrate 1 | A | A | A | A | A |
| Example 221 | Dispersion 17 | Substrate 1 | A | A | A | A | A |
| Example 222 | Dispersion 18 | Substrate 1 | A | A | A | A | A |
| Example 223 | Dispersion 19 | Substrate 1 | A | A | A | A | A |
| Example 224 | Dispersion 20 | Substrate 1 | A | A | A | A | A |
| Example 225 | Dispersion 21 | Substrate 1 | A | A | A | A | A |
| Example 226 | Dispersion 22 | Substrate 1 | A | A | A | A | A |
| Example 227 | Dispersion 23 | Substrate 1 | A | A | A | A | A |
| Example 228 | Dispersion 24 | Substrate 1 | A | A | A | A | A |
| Example 229 | Dispersion 25 | Substrate 1 | A | A | A | A | A |
| Example 230 | Dispersion 26 | Substrate 1 | A | A | A | A | A |
| Example 231 | Dispersion 27 | Substrate 1 | A | A | A | A | A |
| Example 232 | Dispersion 28 | Substrate 1 | A | A | A | A | A |
| Example 233 | Dispersion 29 | Substrate 1 | A | A | A | A | A |
| Example 234 | Dispersion 30 | Substrate 1 | A | A | A | A | A |
| Example 235 | Dispersion 31 | Substrate 1 | A | A | A | A | A |
| Example 236 | Dispersion 32 | Substrate 1 | A | A | A | A | A |
| Example 237 | Dispersion 33 | Substrate 1 | A | A | A | A | A |
| Example 238 | Dispersion 34 | Substrate 1 | A | A | A | A | A |
| Example 239 | Dispersion 35 | Substrate 1 | A | A | A | A | A |
| Example 240 | Dispersion 36 | Substrate 1 | A | A | A | A | A |
| Example 241 | Dispersion 37 | Substrate 1 | A | A | A | A | A |
| Example 242 | Dispersion 38 | Substrate 1 | A | A | A | A | A |
| Example 243 | Dispersion 39 | Substrate 1 | A | A | A | A | A |
| Example 244 | Dispersion 40 | Substrate 1 | A | A | A | A | A |
| Example 245 | Dispersion 41 | Substrate 1 | A | A | A | A | A |
| Example 246 | Dispersion 42 | Substrate 1 | A | A | A | A | A |
| Example 247 | Dispersion 43 | Substrate 1 | A | A | A | A | A |
| Example 248 | Dispersion 44 | Substrate 1 | A | A | A | A | A |
| Example 249 | Dispersion 45 | Substrate 1 | A | A | A | A | A |
| Example 250 | Dispersion 46 | Substrate 1 | A | A | A | A | A |
| Example 251 | Dispersion 47 | Substrate 1 | A | A | A | A | A |
| Example 252 | Dispersion 48 | Substrate 1 | A | A | A | A | A |
| Example 253 | Dispersion 49 | Substrate 1 | A | A | A | A | A |
| Example 254 | Dispersion 50 | Substrate 1 | A | A | A | A | A |
| Example 255 | Dispersion 51 | Substrate 1 | A | A | A | A | A |
| Example 256 | Dispersion 52 | Substrate 1 | A | A | A | A | A |
| Example 257 | Dispersion 53 | Substrate 1 | A | A | A | A | A |
| Example 258 | Dispersion 54 | Substrate 1 | A | A | A | A | A |
| Example 259 | Dispersion 55 | Substrate 1 | A | A | A | A | A |
| Example 260 | Dispersion 56 | Substrate 1 | A | A | A | A | A |
| Example 261 | Dispersion 57 | Substrate 1 | A | A | A | A | A |
| Example 262 | Dispersion 58 | Substrate 1 | A | A | A | A | A |
| Example 263 | Dispersion 59 | Substrate 1 | A | A | A | A | A |
| Example 264 | Dispersion 60 | Substrate 1 | A | A | A | A | A |
| Example 265 | Dispersion 61 | Substrate 1 | A | A | B | B | A |
| Example 266 | Dispersion 62 | Substrate 1 | A | A | B | B | A |
| Example 267 | Dispersion 63 | Substrate 1 | A | A | B | B | A |
| Example 268 | Dispersion 64 | Substrate 1 | A | A | A | A | A |
| Example 269 | Dispersion 65 | Substrate 1 | A | A | A | A | A |
| Example 270 | Dispersion 66 | Substrate 1 | A | A | B | B | A |
| Example 271 | Dispersion 67 | Substrate 1 | A | A | B | B | A |
| Example 272 | Dispersion 68 | Substrate 1 | A | A | B | B | A |
| Example 273 | Dispersion 69 | Substrate 1 | A | A | A | A | A |
| Example 274 | Dispersion 70 | Substrate 1 | A | A | A | A | A |
| Example 275 | Dispersion 71 | Substrate 1 | A | A | A | A | A |
| Example 276 | Dispersion 72 | Substrate 1 | A | A | A | A | A |

TABLE 14

| | | | Heat Resistance | | Light Fastness | | |
|---|---|---|---|---|---|---|---|
| | | | Change in | | Change in | | Viewing Angle |
| | Dispersion | Substrate | Transmittance | Residual Rate | Transmittance | Residual Rate | Dependence |
| Example 277 | Dispersion 15 | Substrate 2 | A | A | A | A | B |
| Example 278 | Dispersion 16 | Substrate 2 | A | A | A | A | B |
| Example 279 | Dispersion 17 | Substrate 2 | A | A | A | A | B |
| Example 280 | Dispersion 18 | Substrate 2 | A | A | A | A | B |
| Example 281 | Dispersion 19 | Substrate 2 | A | A | A | A | B |
| Example 282 | Dispersion 20 | Substrate 2 | A | A | A | A | B |
| Example 283 | Dispersion 21 | Substrate 2 | A | A | A | A | B |
| Example 284 | Dispersion 22 | Substrate 2 | A | A | A | A | B |
| Example 285 | Dispersion 23 | Substrate 2 | A | A | A | A | B |
| Example 286 | Dispersion 24 | Substrate 2 | A | A | A | A | B |
| Example 287 | Dispersion 25 | Substrate 2 | A | A | A | A | B |
| Example 288 | Dispersion 26 | Substrate 2 | A | A | A | A | B |
| Example 289 | Dispersion 27 | Substrate 2 | A | A | A | A | B |
| Example 290 | Dispersion 28 | Substrate 2 | A | A | A | A | B |
| Example 291 | Dispersion 29 | Substrate 2 | A | A | A | A | B |
| Example 292 | Dispersion 30 | Substrate 2 | A | A | A | A | B |
| Example 293 | Dispersion 31 | Substrate 2 | A | A | A | A | B |
| Example 294 | Dispersion 32 | Substrate 2 | A | A | A | A | B |
| Example 295 | Dispersion 33 | Substrate 2 | A | A | A | A | B |
| Example 296 | Dispersion 34 | Substrate 2 | A | A | A | A | B |
| Example 297 | Dispersion 35 | Substrate 2 | A | A | A | A | B |
| Example 298 | Dispersion 36 | Substrate 2 | A | A | A | A | B |
| Example 299 | Dispersion 37 | Substrate 2 | A | A | A | A | B |
| Example 300 | Dispersion 38 | Substrate 2 | A | A | A | A | B |
| Example 301 | Dispersion 39 | Substrate 2 | A | A | A | A | B |
| Example 302 | Dispersion 40 | Substrate 2 | A | A | A | A | B |
| Example 303 | Dispersion 41 | Substrate 2 | A | A | A | A | B |
| Example 304 | Dispersion 42 | Substrate 2 | A | A | A | A | B |
| Example 305 | Dispersion 43 | Substrate 2 | A | A | A | A | B |
| Example 306 | Dispersion 44 | Substrate 2 | A | A | A | A | B |
| Example 307 | Dispersion 45 | Substrate 2 | A | A | A | A | B |
| Example 308 | Dispersion 46 | Substrate 2 | A | A | A | A | B |
| Example 309 | Dispersion 47 | Substrate 2 | A | A | A | A | B |
| Example 310 | Dispersion 48 | Substrate 2 | A | A | A | A | B |
| Example 311 | Dispersion 49 | Substrate 2 | A | A | A | A | B |
| Example 312 | Dispersion 50 | Substrate 2 | A | A | A | A | B |
| Example 313 | Dispersion 51 | Substrate 2 | A | A | A | A | B |
| Example 314 | Dispersion 52 | Substrate 2 | A | A | A | A | B |
| Example 315 | Dispersion 53 | Substrate 2 | A | A | A | A | B |
| Example 316 | Dispersion 54 | Substrate 2 | A | A | A | A | B |
| Example 317 | Dispersion 55 | Substrate 2 | A | A | A | A | B |
| Example 318 | Dispersion 56 | Substrate 2 | A | A | A | A | B |
| Example 319 | Dispersion 57 | Substrate 2 | A | A | A | A | B |
| Example 320 | Dispersion 58 | Substrate 2 | A | A | A | A | B |
| Example 321 | Dispersion 59 | Substrate 2 | A | A | A | A | B |
| Example 322 | Dispersion 60 | Substrate 2 | A | A | A | A | B |
| Example 323 | Dispersion 61 | Substrate 2 | A | A | B | B | B |
| Example 324 | Dispersion 62 | Substrate 2 | A | A | B | B | B |
| Example 325 | Dispersion 63 | Substrate 2 | A | A | B | B | B |
| Example 326 | Dispersion 64 | Substrate 2 | A | A | A | A | B |
| Example 327 | Dispersion 65 | Substrate 2 | A | A | A | A | B |
| Example 328 | Dispersion 66 | Substrate 2 | A | A | B | B | B |
| Example 329 | Dispersion 67 | Substrate 2 | A | A | B | B | B |
| Example 330 | Dispersion 68 | Substrate 2 | A | A | B | B | B |
| Example 331 | Dispersion 69 | Substrate 2 | A | A | A | A | B |
| Example 332 | Dispersion 70 | Substrate 2 | A | A | A | A | B |
| Example 333 | Dispersion 71 | Substrate 2 | A | A | A | A | B |
| Example 334 | Dispersion 72 | Substrate 2 | A | A | A | A | B |

As shown in the above tables, in the films formed of the compositions according to Examples, heat resistance and light fastness were excellent. In addition, in the near infrared cut filter that was prepared using the composition according to any one of Examples, viewing angle dependence was excellent.

### Test Example 4

The composition according to Example 1 was applied to a silicon wafer using a spin coating method such that the thickness of the formed film was 1.0 μm. Next, the silicon wafer was heated using a hot plate at 100° C. for 2 minutes. Next, the silicon wafer was heated using a hot plate at 200° C. for 5 minutes. Next, a 2 μmx2 μm Bayer pattern (near infrared cut filter) was formed using a dry etching method.

Next, a Red composition was applied to the Bayer pattern of the near infrared cut filter using a spin coating method such that the thickness of the formed film was 1.0 μm Next, the silicon wafer was heated using a hot plate at 100° C. for 2 minutes. Next, using an i-ray stepper exposure device FPA-3000 i5+(manufactured by Canon Corporation) at 1000 mJ/cm², a 2 μm×2 μm Bayer pattern was exposed through a mask at an exposure dose of 1000 mJ/cm².

Next, puddle development was performed at 23° C. for 60 seconds using a tetramethylammonium hydroxide (TMAH) 0.3 mass % aqueous solution. Next, the silicon wafer was rinsed by spin showering and was cleaned with pure water. Next, the silicon wafer was heated using a hot plate at 200° C. for 5 minutes. As a result, the Red composition was patterned on the Bayer pattern of the near infrared cut filter. Likewise, a Green composition and a Blue composition were sequentially patterned to form red, green, and blue color patterns.

Next, the composition for forming an infrared transmitting filter was applied to the pattern-formed film using a spin coating method such that the thickness of the formed film was 2.0 μm. Next, the silicon wafer was heated using a hot plate at 100° C. for 2 minutes. Next, using an i-ray stepper exposure device FPA-3000 i5+(manufactured by Canon Corporation) at 1000 mJ/cm², a 2 μmx2 μm Bayer pattern was exposed through a mask at an exposure dose of 1000 mJ/cm². Next, puddle development was performed at 23° C. for 60 seconds using a tetramethylammonium hydroxide (TMAH) 0.3 mass % aqueous solution. Next, the silicon wafer was rinsed by spin showering and was cleaned with pure water. Next, the silicon wafer was heated using a hot plate at 200° C. for 5 minutes. As a result, the infrared transmitting filter was patterned on a portion where the Bayer pattern of the near infrared cut filter was not formed. This filter was incorporated into a solid image pickup element using a well-known method.

Using the obtained solid image pickup element, an object was irradiated with a infrared light emitting diode (infrared LED) as a light source in a low-illuminance environment (0.001 Lux) to acquire images. Next, the imaging performances of the solid image pickup elements were evaluated. A subject was able to be clearly recognized on the image.

The Red composition, the Green composition, the Blue composition, and the composition for forming an infrared transmitting filter used in Test Example 4 are as follows.

(Red Composition)

The following components were mixed and stirred, and the obtained mixture was filtered through a nylon filter (manufactured by Pall Corporation) having a pore size of 0.45 μm to prepare a Red composition.

Red Pigment Dispersion . . . 51.7 parts by mass

Resin 4 (40 mass % PGMEA solution) . . . 0.6 parts by mass

Curable Compound 4 . . . 0.6 parts by mass

Photopolymerization Initiator 1 . . . 0.3 parts by mass

Surfactant 1 . . . 4.2 parts by mass

PGMEA . . . 42.6 parts by mass

(Green Composition)

The following components were mixed and stirred, and the obtained mixture was filtered through a nylon filter (manufactured by Pall Corporation) having a pore size of 0.45 μm to prepare a Green composition.
Green Pigment Dispersion . . . 73.7 parts by mass
Resin 4 (40 mass % PGMEA solution) . . . 0.3 parts by mass
Curable Compound 1 . . . 1.2 parts by mass
Photopolymerization Initiator 1 . . . 0.6 parts by mass
Surfactant 1 . . . 4.2 parts by mass
Ultraviolet absorber (UV-503, manufactured by Daito Chemical Co., Ltd.) . . . 0.5 parts by mass
PGMEA . . . 19.5 parts by mass

(Blue Composition)

The following components were mixed and stirred, and the obtained mixture was filtered through a nylon filter (manufactured by Pall Corporation) having a pore size of 0.45 to prepare a Blue composition.

Blue Pigment Dispersion . . . 44.9 parts by mass

Resin 4 (40 mass % PGMEA solution) . . . 2.1 parts by mass

Curable Compound 1 . . . 1.5 parts by mass

Curable Compound 4 . . . 0.7 parts by mass

Photopolymerization Initiator 1 . . . 0.8 parts by mass

Surfactant 1 . . . 4.2 parts by mass

PGMEA . . . 45.8 parts by mass

(Preparation of Composition for Forming Infrared Transmitting Filter)

The components having the following compositions were mixed and stirred, and the obtained mixture was filtered through a nylon filter (manufactured by Pall Corporation) having a pore size of 0.45 μm to prepare a composition for forming an infrared transmitting filter.

### (Composition 100)

Pigment Dispersion 1-1 . . . 46.5 parts by mass

Pigment Dispersion 1-2 . . . 37.1 parts by mass

Curable Compound 5 . . . 1.8 parts by mass

Resin 4 . . . 1.1 parts by mass

Photopolymerization Initiator 2 . . . 0.9 parts by mass

Surfactant 1 . . . 4.2 parts by mass

Polymerization inhibitor (p-methoxyphenol) . . . 0.001 parts by mass

Silane coupling agent . . . 0.6 parts by mass

PGMEA . . . 7.8 parts by mass

Materials used in the Red composition, the Green composition, the Blue composition, and the composition for forming an infrared transmitting filter are as follows.

Red Pigment Dispersion

9.6 parts by mass of C.I. Pigment Red 254, 4.3 parts by mass of C.I. Pigment Yellow 139, 6.8 parts by mass of a dispersant (Disperbyk-161, manufactured by BYK Chemie), and 79.3 parts by mass of PGMEA were mixed with each other to obtain a mixed solution, and the mixed solution was mixed and dispersed using a beads mill (zirconia beads; diameter: 0.3 mm) for 3 hours. As a result, a pigment dispersion was prepared. Next, using a high-pressure disperser NANO-3000-10 (manufactured by Nippon BEE Chemical Co., Ltd.) equipped with a pressure reducing mechanism, the pigment dispersion was further dispersed under a pressure of 2000 kg/cm³ at a flow rate of 500 g/min. This dispersing treatment was repeated 10 times. As a result, a Red pigment dispersion was obtained.

Green Pigment Dispersion

6.4 parts by mass of C.I. Pigment Green 36, 5.3 parts by mass of C.I. Pigment Yellow 150, 5.2 parts by mass of a dispersant (Disperbyk-161, manufactured by BYK Chemie), and 83.1 parts by mass of PGMEA were mixed with each other to obtain a mixed solution, and the mixed solution was mixed and dispersed using a beads mill (zirconia beads; diameter: 0.3 mm) for 3 hours. As a result, a pigment dispersion was prepared. Next, using a high-pressure disperser NANO-3000-10 (manufactured by Nippon BEE Chemical Co., Ltd.) equipped with a pressure reducing mechanism, the pigment dispersion was further dispersed under a pressure of 2000 kg/cm³ at a flow rate of 500 g/min. This dispersing treatment was repeated 10 times. As a result, a Green pigment dispersion was obtained.

Blue Pigment Dispersion

9.7 parts by mass of C.I. Pigment Blue 15:6, 2.4 parts by mass of C.I. Pigment Violet 23, 5.5 parts by mass of a dispersant (Disperbyk-161, manufactured by BYK Chemie), 82.4 parts by mass of PGMEA were mixed with each other to obtain a mixed solution, and the mixed solution was mixed and dispersed using a beads mill (zirconia beads; diameter: 0.3 mm) for 3 hours. As a result, a pigment dispersion was prepared. Next, using a high-pressure disperser NANO-3000-10 (manufactured by Nippon BEE Chemical Co., Ltd.) equipped with a pressure reducing mechanism, the pigment dispersion was further dispersed under a pressure of 2000 kg/cm³ at a flow rate of 500 g/min. This dispersing treatment was repeated 10 times. As a result, a Blue pigment dispersion was obtained.

Pigment Dispersion 1-1

A mixed solution having a composition shown below was mixed and dispersed for 3 hours using a beads mill (a high-pressure disperser with a pressure reducing mechanism, NANO-3000-10 (manufactured by Nippon BEE Chemical Co., Ltd.)) in which zirconia beads having a diameter of 0.3 mm were used. As a result, Pigment Dispersion 1-1 was prepared.
Mixed pigment including a red pigment (C.I. Pigment Red 254) and a yellow pigment (C.I. Pigment Yellow 139) . . . 11.8 parts by mass
Resin (Disperbyk-111, manufactured by BYK Chemie) . . . 9.1 parts by mass
PGMEA . . . 79.1 parts by mass
Pigment Dispersion 1-2

A mixed solution having a composition shown below was mixed and dispersed for 3 hours using a beads mill (a high-pressure disperser with a pressure reducing mechanism, NANO-3000-10 (manufactured by Nippon BEE Chemical Co., Ltd.)) in which zirconia beads having a diameter of 0.3 mm were used. As a result, Pigment Dispersion 1-2 was prepared.
Mixed pigment including a blue pigment (C.I. Pigment Blue 15:6) and a violet pigment (C.I. Pigment Violet 23) . . . 12.6 parts by mass
Resin (Disperbyk-111, manufactured by BYK Chemie) . . . 2.0 parts by mass
Resin A . . . 3.3 parts by mass
Cyclohexanone . . . 31.2 parts by mass
PGMEA . . . 50.9 parts by mass
Resin A: the following structure (Mw=14000, a ratio in a structural unit is a molar ratio)

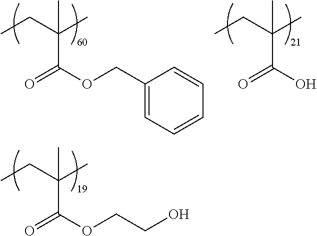

Curable Compound 1: KAYARAD DPHA (manufactured by Nippon Kayaku Co., Ltd.)
Curable Compound 4 . . . the following structure

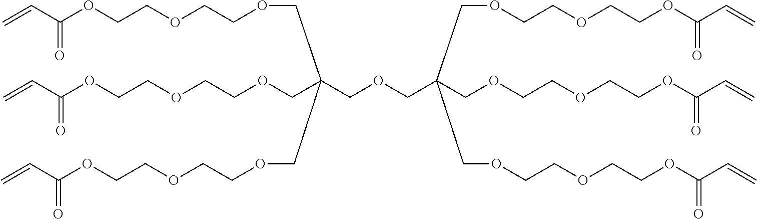 [SMILES: C=CC(=O)OCCOCCOCC(COCCOCCOC(=O)C=C)(COCCOCCOC(=O)C=C)COCC(COCCOCCOC(=O)C=C)(COCCOCCOC(=O)C=C)COCCOCCOC(=O)C=C]

Curable Compound 5: the following structures (a mixture in which a molar ratio between a left compound and a right compound is 7:3)

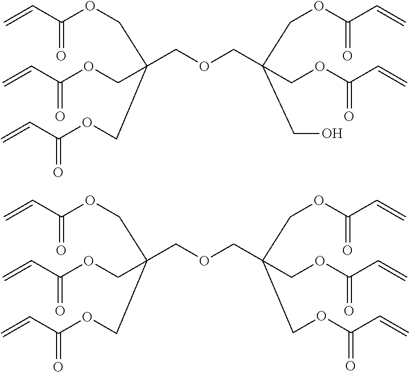

Resin 4: the following structure (acid value: 70 mgKOH/g, Mw=11000; a ratio in a structural unit is a molar ratio)

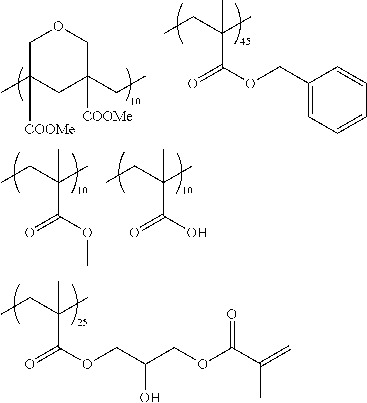

Photopolymerization Initiator 1: IRGACURE-OXE 01 (manufactured by BASF SE)
   Photopolymerization initiator 2: the following structure

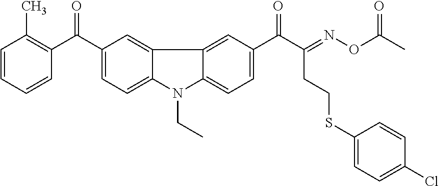 [SMILES: CCn1c2ccc(C(=O)/C(CCSc3ccc(Cl)cc3)=N/OC(C)=O)cc2c2cc(C(=O)c3ccccc3C)ccc21]

Surfactant 1: 1 mass % PGMEA solution of the following mixture (Mw: 14000) In the following expression, “%” representing the proportion of a repeating unit is mass %.

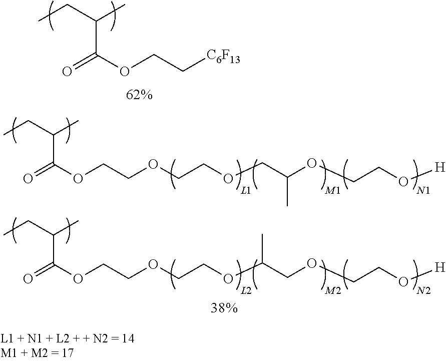

Silane coupling agent: a compound having the following structure In the following structural formulae, Et represents an ethyl group.

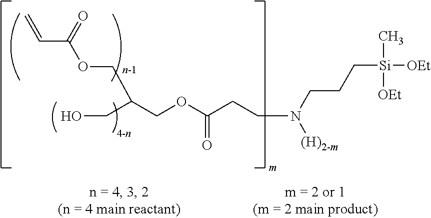

### EXPLANATION OF REFERENCES

110: solid image pickup element
111: near infrared cut filter
112: color filter
114: infrared transmitting filter
115: microlens
116: planarizing layer

What is claimed is:

1. A composition comprising:
a near infrared absorbing compound having an absorption maximum in a wavelength range of 650 to 1000 nm;
an organic solvent; and
a resin,
wherein the near infrared absorbing compound is at least one selected from the group consisting of a pyrrolopyrrole compound, a rylene compound, an oxonol compound, a squarylium compound, a croconium compound, a zinc phthalocyanine compound, a cobalt phthalocyanine compound, a vanadium phthalocyanine compound, a copper phthalocyanine compound, a magnesium phthalocyanine compound, a naphthalocyanine compound, a pyrylium compound, an azulenium compound, an indigo compound, and a pyrromethene compound, and
a solubility of the near infrared absorbing compound in propylene glycol methyl ether acetate at 25° C. is 0.01 to 30 mg/L.

2. The composition according to claim 1, further comprising:
a pigment derivative.

3. The composition according to claim 1, further comprising:
a curable compound.

4. The composition according to claim 3,
wherein the curable compound is a polymerizable compound, and
the composition further comprises a photopolymerization initiator.

5. The composition according to claim 3,
wherein the curable compound is a compound having an epoxy group.

6. The composition according to claim 1, further comprising:
an alkali-soluble resin.

7. The composition according to claim 1, further comprising:
a silane coupling agent.

8. The composition according to claim 3,
wherein the curable compound is a compound having an epoxy group, and
the composition further comprises a silane coupling agent.

9. A film which is formed using the composition according to claim 1.

10. A near infrared cut filter comprising:
a film that is formed using the composition according to claim 1.

11. The near infrared cut filter according to claim 10, further comprising:
a glass substrate.

12. A pattern forming method comprising:
forming a composition layer on a support using the composition according to claim 1; and
forming a pattern on the composition layer using a photolithography method or a dry etching method.

13. A laminate comprising:
the film according to claim 9; and
a color filter that includes a chromatic colorant.

14. A solid image pickup element comprising:
the film according to claim 9.

15. An image display device comprising:
the film according to claim 9.

16. A camera module comprising:
the film according to claim 9.

17. An infrared sensor comprising:
the film according to claim 9.
